(19) United States
(12) Patent Application Publication
(10) Pub. No.: US 2024/0332387 A1
(43) Pub. Date: Oct. 3, 2024

(54) GATE ISOLATION AND CONNECTION OF MULTIGATE DEVICES

(71) Applicant: Taiwan Semiconductor Manufacturing Company, Ltd., Hsin-Chu (TW)

(72) Inventors: Kuo-Cheng Chiang, Hsinchu County (TW); Guan-Lin Chen, Hsinchu County (TW); Jung-Chien Cheng, Tainan City (TW); Shi Ning Ju, Hsinchu City (TW); Chih-Hao Wang, Hsinchu County (TW)

(21) Appl. No.: 18/481,642

(22) Filed: Oct. 5, 2023

Related U.S. Application Data
(60) Provisional application No. 63/493,399, filed on Mar. 31, 2023.

(51) Int. Cl. H01L 29/423; H01L 21/8238; H01L 27/092; H01L 29/06; H01L 29/66; H01L 29/775; H01L 29/786

(52) U.S. Cl. CPC H01L 29/42392; H01L 21/823807; H01L 21/823878; H01L 27/092; H01L 29/0673; H01L 29/66545; H01L 29/775; H01L 29/78696

(57) ABSTRACT

Self-aligned gate isolation/cutting techniques for multigate devices are disclosed herein. An exemplary multigate device includes a first gate having a gate stack that surrounds a semiconductor layer. The first gate is disposed between a first gate isolation wall and a second gate isolation wall. The gate stack has a gate dielectric and a gate electrode, the gate stack has a first sidewall and a second sidewall, and the first sidewall is formed by the gate dielectric and the gate electrode. A gate endcap is disposed on the first sidewall. A gate helmet is disposed over the gate stack, and a portion of the gate dielectric is disposed between the gate electrode and the gate helmet. A gate contact is disposed on the first gate. The gate contact extends over the first gate isolation wall and connects the first gate to a second gate.

This application is a non-provisional application of and claims benefit of U.S. Provisional Patent Application Ser. No. 63/493,399, filed Mar. 31, 2023, the entire disclosure of which is incorporated herein by reference.

### BACKGROUND

Multigate devices have been introduced to improve gate control and may increase gate-channel coupling, reduce off-state current, reduce short-channel effects (SCEs), or a combination thereof. One such multigate device is a gate-all around (GAA) device, which includes a gate structure that extends, partially or fully, around a channel region to provide access to the channel region on at least two sides. GAA devices enable aggressive scaling down of integrated circuit (IC) technologies, maintaining gate control and mitigating SCEs, while seamlessly integrating with conventional IC manufacturing processes. However, as GAA devices continue to scale, non-self-aligned gate cutting techniques typically implemented to isolate gates of different GAA devices from one another, such as a first gate of a first GAA transistor from a second gate of a second GAA transistor, are hindering the dense packing of device/semiconductor features needed for advanced IC technology nodes. Accordingly, although existing GAA devices and methods for fabricating such have been generally adequate for their intended purposes, they have not been entirely satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 is a flow chart of a method for fabricating a multigate device, in portion or entirety, according to various aspects of the present disclosure.

FIGS. 2-15 are perspective views of a multigate device, in portion or entirety, at various fabrication stages, such as those associated with the method in FIG. 1, according to various aspects of the present disclosure.

FIGS. 16A-16C are cross-sectional views of the multigate device of FIG. 15, in portion or entirety, according to various aspects of the present disclosure.

FIG. 17 is a cross-sectional view of a multigate device, in portion or entirety, according to various aspects of the present disclosure.

FIGS. 18-20 are perspective views of a multigate device, in portion or entirety, at fabrication stages directed to forming gate helmets and inner spacers thereof (such as those associated with the method in FIG. 1) according to various aspects of the present disclosure.

FIGS. 21-25 are perspective views of another multigate device, in portion or entirety, at various fabrication stages (such as those associated with the method in FIG. 1) according to various aspects of the present disclosure.

FIGS. 26A-26C are cross-sectional views of the multigate device of FIG. 25, in portion or entirety, according to various aspects of the present disclosure.

FIGS. 27-31 are perspective views of yet another multigate device, in portion or entirety, at various fabrication stages (such as those associated with the method in FIG. 1) according to various aspects of the present disclosure.

FIGS. 32A-32C are cross-sectional views of the multigate device of FIG. 31, in portion or entirety, according to various aspects of the present disclosure.

FIG. 33 is a flow chart of another method for fabricating a multigate device, in portion or entirety, according to various aspects of the present disclosure.

FIGS. 34-52 are perspective views of a multigate device, in portion or entirety, at various fabrication stages, such as those associated with the method in FIG. 33, according to various aspects of the present disclosure.

FIGS. 53A-53C are cross-sectional views of the multigate device of FIG. 52, in portion or entirety, according to various aspects of the present disclosure.

FIG. 54 is a cross-sectional view of the multigate device of FIG. 52, in portion or entirety, according to various aspects of the present disclosure.

FIGS. 55-58 are perspective views of a multigate device, in portion or entirety, at fabrication stages directed to forming gate helmets and inner spacers thereof (such as those associated with the method in FIG. 33) according to various aspects of the present disclosure.

FIGS. 59-64 are fragmentary perspective views of another multigate device at various fabrication stages (such as those associated with the method in FIG. 33) according to various aspects of the present disclosure.

FIGS. 65A-65C are cross-sectional views of the multigate device of FIG. 64, in portion or entirety, according to various aspects of the present disclosure.

FIG. 66A and FIG. 66B are cross-sectional views of the multigate device of FIG. 64, in portion or entirety, at a fabrication stage associated with FIG. 61 and a fabrication stage associated with FIG. 64, respectively, according to various aspects of the present disclosure.

FIGS. 67-70 are perspective views of yet another multigate device, in portion or entirety, at various fabrication stages (such as those associated with the method in FIG. 33) according to various aspects of the present disclosure.

FIGS. 71A-71C are cross-sectional views of the multigate device of FIG. 70, in portion or entirety, according to various aspects of the present disclosure.

FIG. 72 is a perspective view of the multigate device of FIG. 52, in portion or entirety, when a trimming process, such as that associated with FIG. 47, is omitted from fabrication thereof according to various aspects of the present disclosure.

FIG. 73 is a perspective view of the multigate device of FIG. 64, in portion or entirety, when a trimming process, such as that associated with FIG. 47, is omitted from fabrication thereof according to various aspects of the present disclosure.

FIG. 74 is a perspective view of the multigate device of FIG. 70, in portion or entirety, when a trimming process, such as that associated with FIG. 47, is omitted from fabrication thereof according to various aspects of the present disclosure.

### DETAILED DESCRIPTION

The present disclosure relates generally to multigate devices, and more particularly, to metal gate isolation and cutting techniques for multigate devices.

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, spatially relative terms, for example, “lower,” “upper.” “horizontal,” “vertical,” “above,” “over.” “below,” “beneath,” “up,” “down,” “top,” “bottom,” etc. as well as derivatives thereof (e.g., “horizontally,” “downwardly.” “upwardly.” etc.) are used for ease of the present disclosure of one features relationship to another feature. The spatially relative terms are intended to cover different orientations of the device including the features. Furthermore, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” may encompass a dimension range from 4.5 nm to 5.5 nm where manufacturing tolerances associated with depositing the material layer are known to be +/−10% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

An exemplary non-self-aligned gate cutting technique may involve forming a mask layer over a gate stack, where the mask layer covers a first portion of the gate stack, covers a second portion of the gate stack, and exposes a third portion of the gate stack via an opening formed in the mask layer. The third portion of the gate stack is disposed between the first portion of the gate stack and the second portion of the gate stack. An etching process is then performed that removes the exposed third portion of the gate stack (including, for example, at least one gate electrode layer and at least one gate dielectric layer), thereby forming a gate cut opening between and separating the first portion of the gate stack from the second portion of the gate stack. A gate isolation structure, such as a dielectric layer (for example, a silicon nitride layer), may then be formed in the gate cut opening to provide electrical isolation between the first portion of the gate stack, which may be over a first channel layer of a first GAA device (i.e., first active device area), and the second portion of the gate stack, which may be over a second channel layer of a second GAA device (i.e., second active device area).

A spacing between active device areas, such as the first channel layer and the second channel layer, is often intentionally designed larger than necessary to compensate for process variations that arise during the non-self-aligned gate cutting technique. For example, etch loading effects and/or other loading effects may reduce critical dimension uniformity (CDU) across a wafer, such that in some locations, a width of the opening in the mask layer and/or a width of the gate cut opening may be larger than a target width, which may lead to unintentional exposure and/or damage of the first channel layer, the second channel layer, the first portion of the gate stack, the second portion of the gate stack, or a combination thereof. In another example, overlay shift arising from lithography processes used to form the mask layer may result in the opening in the mask layer shifted left or right of its intended position, which may also lead to unintentional exposure and/or damage of the first channel layer, the second channel layer, the first portion of the gate stack, the second portion of the gate stack, or a combination thereof. The increased spacing required between the active device areas to adequately compensate for such process variations prevents compact packing of active device areas needed for advanced IC technology nodes, thereby undesirably reducing pattern density. The increased spacing between active device areas also leads to larger gate stack areas, and thus larger parasitic capacitance.

The present disclosure thus proposes various self-aligned gate cutting (isolation) techniques for GAA devices that allow for smaller spacing between active device areas (and thus smaller cell heights) compared to spacing needed between active device areas for non-self-aligned gate cutting techniques. The self-aligned gate cutting techniques described herein reduce area consumed by gates of active device areas, which may improve GAA device performance, for example, by reducing capacitance. Details of the proposed self-aligned gate isolation and cutting techniques for multigate devices and resulting multigate devices are described herein.

In some embodiments, a self-aligned gate cutting technique includes replacing a top semiconductor layer of a semiconductor layer stack in a channel region with a hard mask (also referred to as a gate helmet), such as a dielectric layer that includes silicon and nitrogen, carbon, oxygen, or a combination thereof. The self-aligned gate cutting technique further includes, in the channel region, removing second semiconductor layers of the semiconductor layer stack, such that first semiconductor layers and the hard mask are suspended over a substrate; forming a gate dielectric over the second semiconductor layers and the hard mask; forming a gate electrode over the gate dielectric, where the gate dielectric and the gate electrode are formed to provide a gate stack having a first sidewall and a second sidewall formed by the gate dielectric and the gate electrode; forming a first dielectric wall along the first sidewall of the gate stack and a second dielectric wall along the second sidewall of the gate stack, where the hard mask is disposed between the first dielectric wall and the second dielectric wall; and forming a gate contact over the first dielectric wall that extends through the hard mask to the gate stack. The first dielectric wall may separate the gate stack from another gate stack of a same cell (e.g., memory cell), and the gate contact may be connected the another gate stack. The second dielectric wall may separate the gate stack from another gate stack of a different cell. In some embodiments, a gate endcap is formed along the first sidewall and/or the second sidewall of the gate stack before forming the first dielectric wall and the second dielectric sidewall.

In some embodiments, a gate cutting technique includes replacing a top semiconductor layer of a semiconductor layer stack in a channel region with a hard mask (also referred to as a gate helmet), such as a dielectric layer that includes silicon and nitrogen, carbon, oxygen, or a combination thereof. The gate cutting technique further includes, in the channel region, removing second semiconductor layers of the semiconductor layer stack, such that first semiconductor layers and the hard mask are suspended over a substrate; forming a gate dielectric over the second semiconductor layers and the hard mask; and forming a gate electrode over the gate dielectric. The gate dielectric and the gate electrode are formed to provide a gate stack having a first sidewall and a second sidewall, where the first sidewall is formed by the gate dielectric and the second sidewall is formed by the gate electrode. A first gate isolation wall (e.g., a first dielectric wall) is formed along the first sidewall, and a second gate isolation wall (e.g., a second dielectric wall) is formed along the second sidewall. The first gate isolation wall is formed before removing the second semiconductor layers, and the second gate isolation wall is formed after forming the gate electrode. A gate contact may be formed over the first gate isolation wall that extends through the hard mask to the gate stack. The first gate isolation wall may separate the gate stack from another gate stack of a same cell (e.g., a memory cell), and the gate contact may be connected the other gate stack. The second gate isolation wall may separate the gate stack from another gate stack of a different cell. In some embodiments, a gate endcap is formed along the second sidewall of the gate stack before forming the second gate isolation wall. In some embodiments, the second gate isolation wall fills a remainder of a gate opening. In some embodiments, a gate cut process is performed to form a gate cut opening, and the second gate isolation wall is formed in the gate cut opening.

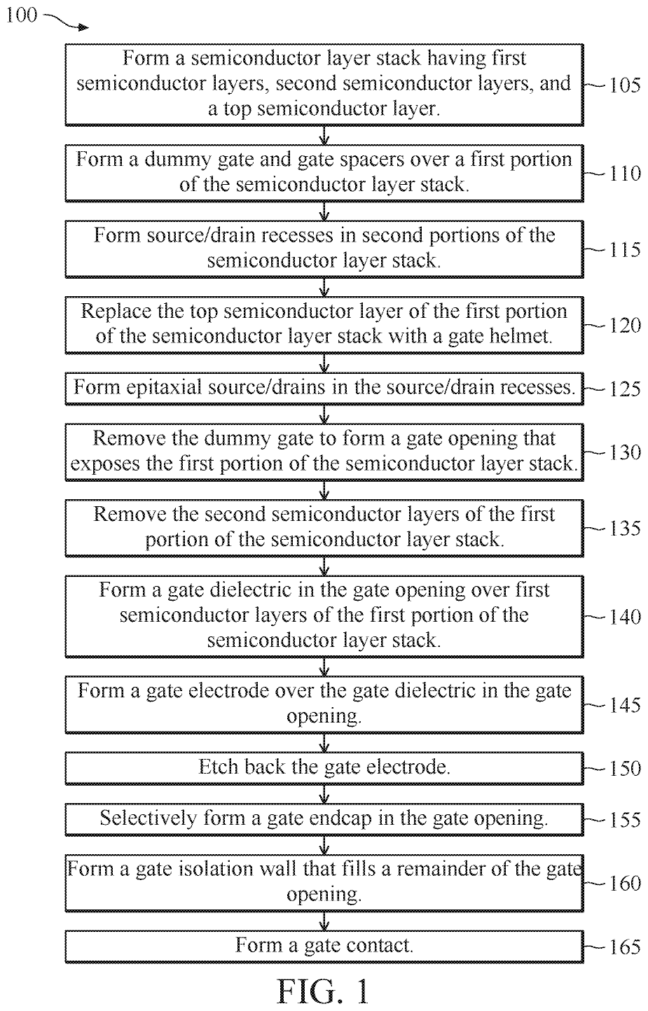

FIG. 1 is a flow chart of a method 100 for fabricating a multigate device, in portion or entirety, according to various aspects of the present disclosure. At block 105, method 100 includes forming a semiconductor layer stack over a semiconductor substrate. The semiconductor layer stack has first semiconductor layers, second semiconductor layers, and a top semiconductor layer. The first semiconductor layers, the second semiconductor layers, and the top semiconductor layer have different compositions. At block 110 and block 115, method 100 includes forming a dummy gate and gate spacers over a first portion of the semiconductor layer stack and forming source/drain recesses in second portions of the semiconductor layer stack, respectively. At block 120, method 100 includes replacing the top semiconductor layer of the first portion of the semiconductor layer stack with a gate helmet. In some embodiments, portions of the second semiconductor layers of the first portion of the semiconductor layer stack (e.g., those portions underneath the gate spacers) may be replaced with inner spacers. The gate helmet may be formed before, after, or simultaneously with the inner spacers. At block 125, method 100 includes forming epitaxial source/drains in the source/drain recesses. In some embodiments, a dielectric layer, such as an interlayer dielectric layer and/or a contact etch stop layer, is formed after forming epitaxial source/drains at block 125 and before performing a gate replacement process (i.e., replacing the dummy gate with a metal gate) as described herein.

At block 130, method 100 includes removing the dummy gate to form a gate opening that exposes the first portion of the semiconductor layer stack. The gate opening may further expose the gate helmet and/or the inner spacers. At block 135, method 100 includes removing the second semiconductor layers of the first portion of the semiconductor layer stack, thereby suspending the first semiconductor layers over the semiconductor substrate (e.g., a channel release process is performed at block 135). Removing the second semiconductor layers may further suspend the gate helmet over the first semiconductor layers. At block 140, method 100 includes forming a gate dielectric in the gate opening over the first semiconductor layers of the first portion of the semiconductor layer stack. The gate dielectric may surround the first semiconductor layers. The gate dielectric may further surround the gate helmet. At block 145 and block 150, method 100 includes forming a gate electrode over the gate dielectric in the gate opening and etching back the gate electrode, respectively. A gate stack that includes the gate dielectric and the gate electrode may surround the first semiconductor layers, and sidewalls of the gate stack may be formed by both the gate dielectric and the gate electrode. At block 155, method 100 includes selectively form a gate endcap in the gate opening. The gate endcap is formed on a sidewall of the gate stack, the gate endcap is disposed on the gate electrode, and the gate endcap may be disposed on the gate dielectric. The gate stack and the gate endcap form a first gate. At block 160, method 100 includes forming a gate isolation wall that fills a remainder of the gate opening. The gate isolation wall is between and may electrically isolate the first gate and a second gate. At block 165, method 100 includes forming a gate contact. The gate contact is disposed on the first gate (e.g., the gate electrode thereof). The gate contact may be disposed on the gate endcap. The gate contact extends over the gate isolation wall and connects the first gate to a second gate (e.g., a gate electrode thereof). Additional processing is contemplated by the present disclosure. Additional steps may be provided before, during, and after method 100, and some of the steps described may be moved, replaced, or eliminated for additional embodiments of method 100. The discussion that follows illustrates various embodiments of multigate-based integrated circuit devices that may be fabricated according to method 100.

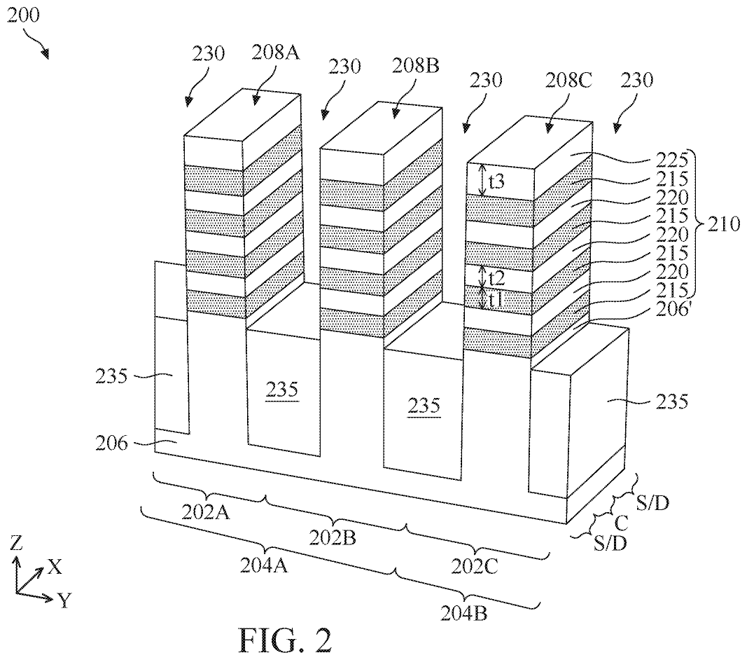

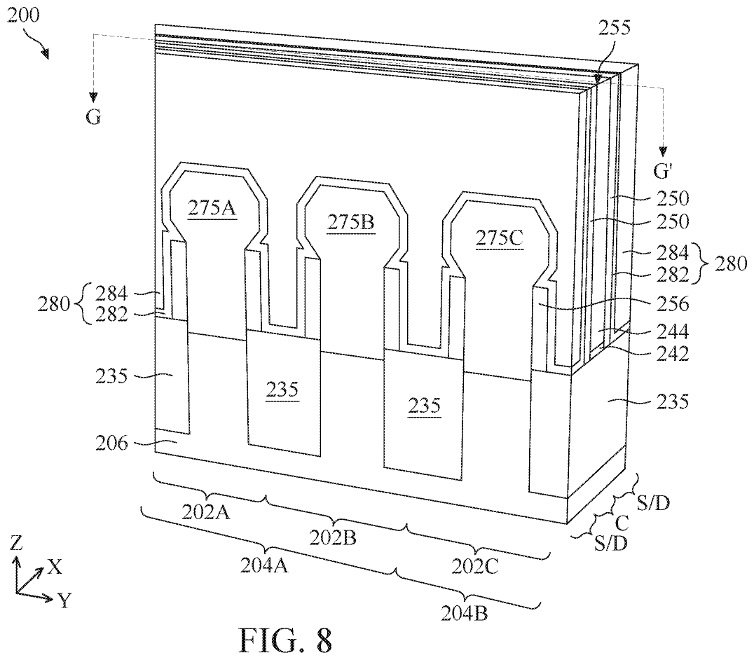

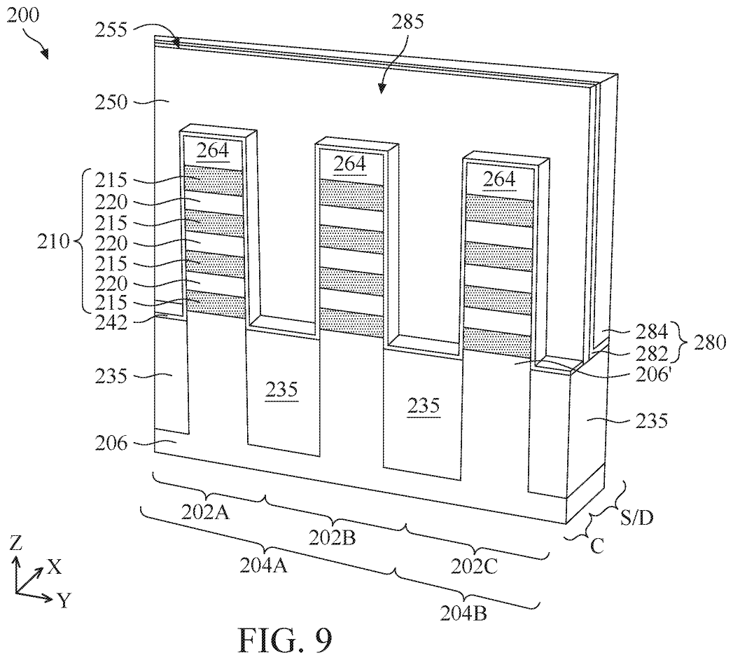

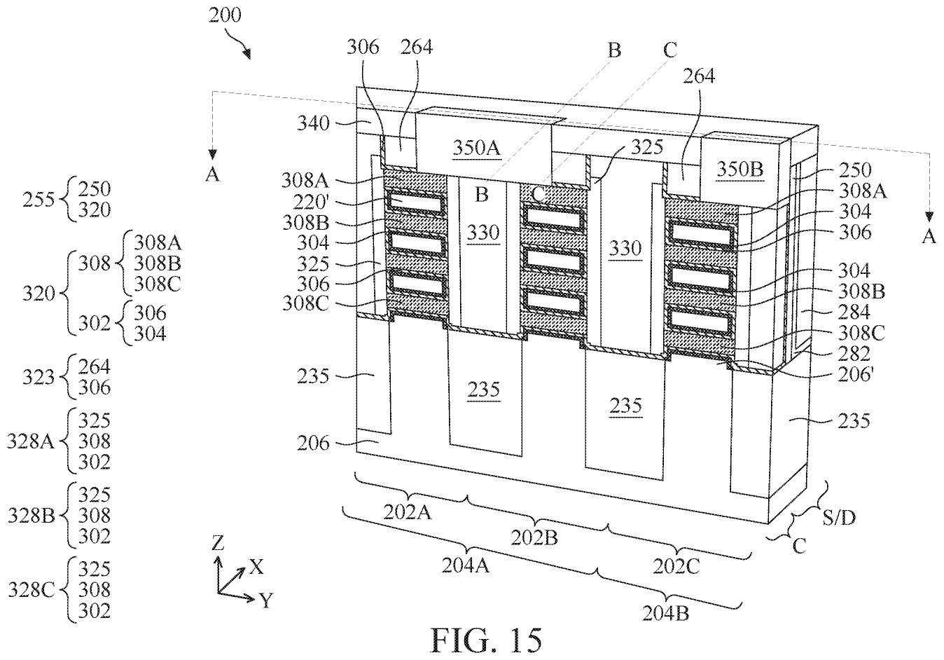

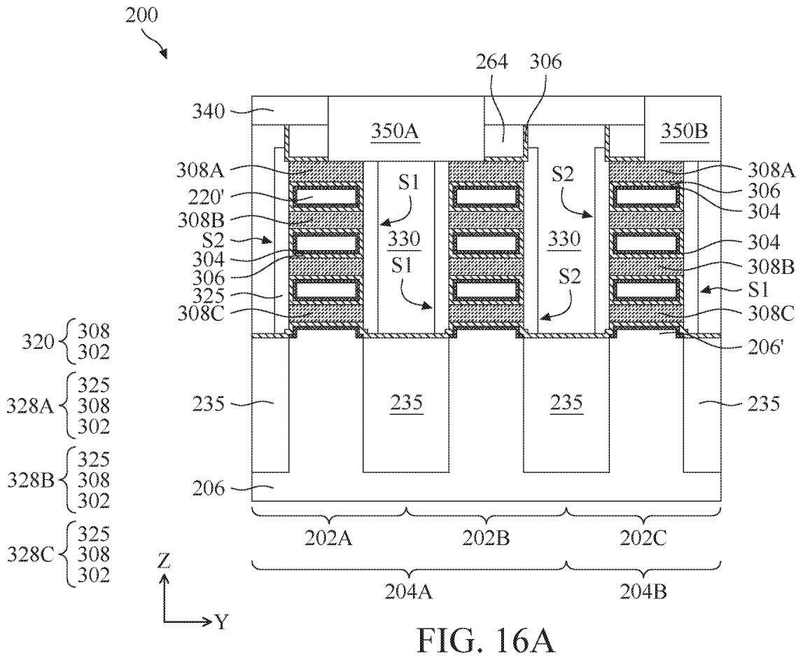

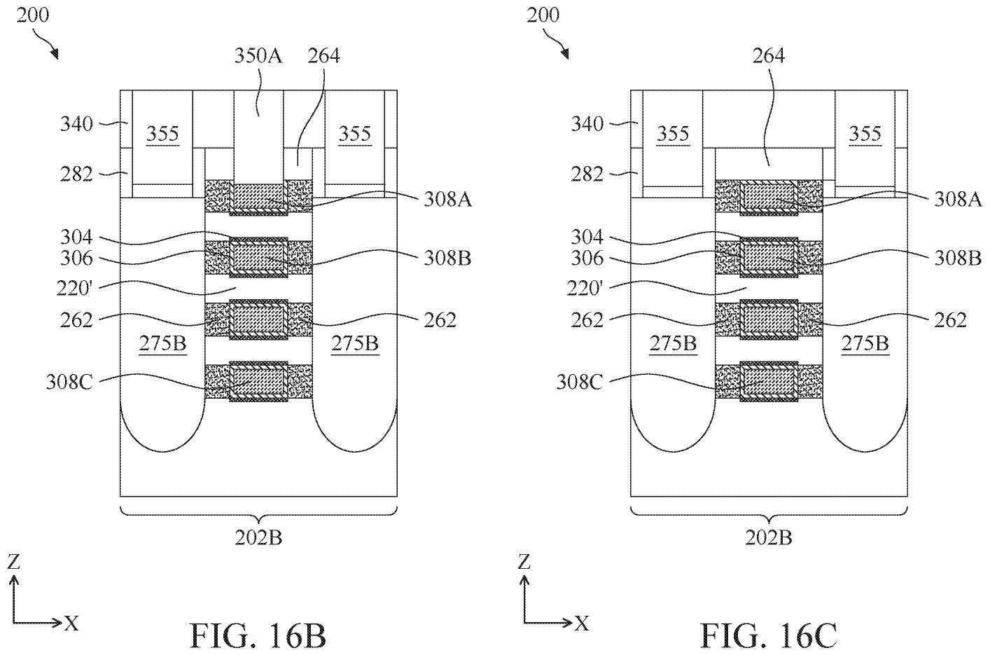

FIGS. 2-15 are perspective views of a multigate device 200, in portion or entirety, at various fabrication stages (such as those associated with method 100 in FIG. 1) according to various aspects of the present disclosure. For case of description and understanding. FIGS. 9-15 are taken (cut) through a gate structure of multigate device 200 along line G-G′ in FIG. 8 (and are thus referred to as gate cut perspective views). FIG. 16A, FIG. 16B, and FIG. 16C are cross-sectional views of multigate device 200 along line A-A, line B-B, and line C-C, respectively, of FIG. 15 (e.g., a y-cut view and x-cut views), in portion or entirety, according to various aspects of the present disclosure. FIGS. 2-15 and FIGS. 16A-16C have been simplified for the sake of clarity to better understand the inventive concepts of the present disclosure. Additional features may be added in multigate device 200, and some of the features described below may be replaced, modified, or eliminated in other embodiments of multigate device 200.

As described herein, in FIGS. 2-15, multigate device 200 may be processed to form a first transistor in a transistor region 202A, a second transistor in a transistor region 202B, and a third transistor in a transistor region 202C. In some embodiments, the first transistor, the second transistor, the third transistor, or a combination thereof is an n-type transistor. In some embodiments, the first transistor, the second transistor, the third transistor, or a combination thereof is a p-type transistor. In some embodiments, transistor regions 202A-202C are processed to provide a first multigate device in a device region 204A and a second multigate device in a device region 204B. In some embodiments, the first multigate device includes an n-type transistor (e.g., first transistor formed in transistor region 202A) and a p-type transistor (formed in transistor region 202B) and the second multigate device includes an n-type transistor (formed in transistor region 202C) and a p-type transistor (formed in a transistor region adjacent to transistor region 202C), such that device region 204A and device region 204B each include a complementary metal-oxide semiconductor (CMOS) transistor.

Referring to FIG. 2, a fin fabrication process is performed to form fins extending from a substrate (wafer) 206, such as a fin 208A, a fin 208B, and a fin 208C (also referred to as fin structures, fin elements, etc.) extending from substrate 206. Fins 208A-208C extend substantially parallel to one another along an x-direction, having a length in the x-direction, a width in a y-direction, and a height in a z-direction. Each of fins 208A-208C include a substrate portion and a semiconductor layer stack portion disposed over the substrate portion. The substrate portion includes a mesa 206′ (also referred to as a substrate extension, a fin portion of substrate 206, a substrate fin portion, an etched substrate portion, etc.). The semiconductor layer stack portion includes a semiconductor layer stack 210 having semiconductor layers 215, semiconductor layers 220, and a semiconductor layer 225.

In the depicted embodiment, substrate 206 includes silicon. Substrate 206 may alternatively or additionally include another elementary semiconductor, such as germanium; a compound semiconductor, such as silicon carbide, gallium arsenide, gallium phosphide, indium phosphide, indium arsenide, indium antimonide, or a combination thereof; an alloy semiconductor, such as SiGe, GaAsP, AlInAs, AlGaAs, GaInAs, GaInP, GaInAsP, or a combination thereof; or a combination thereof. In some embodiments, substrate 206 is a semiconductor-on-insulator substrate, such as a silicon-on-insulator substrate, a silicon germanium-on-insulator substrate, or a germanium-on-insulator substrate. Substrate 206 (including mesas 206′ extending therefrom) may include various doped regions, such as p-type doped regions/p-wells in n-type transistor regions and n-type doped regions/n-wells in p-type transistor regions. The n-wells are doped with n-type dopants, such as phosphorus, arsenic, other n-type dopant, or a combination thereof. The p-wells are doped with p-type dopants, such as boron, indium, other p-type dopant, or a combination thereof. In some embodiments, substrate 206 includes doped regions formed with a combination of p-type dopants and n-type dopants. The various doped regions may be formed directly on and/or in substrate 206, for example, providing a p-well structure, an n-well structure, a dual-well structure, a raised structure, or a combination thereof. An ion implantation process, a diffusion process, and/or other suitable doping process may be performed to form the various doped regions.

Each semiconductor layer stack 210 is disposed over a respective mesa 206′ of substrate 206 and includes respective semiconductor layers 215, respective semiconductor layers 220, and a respective semiconductor layer 225. Semiconductor layers 215 and semiconductor layers 220 are stacked vertically (e.g., along the z-direction) in an interleaving or alternating configuration from a top surface of substrate 206. A composition of semiconductor layers 215, a composition of semiconductor layers 220, and a composition of semiconductor layers 225 are different to achieve etching selectivity and/or different oxidation rates during processing. For example, semiconductor layers 215, semiconductor layers 220, and semiconductor layers 225 include different materials, constituent atomic percentages, constituent weight percentages, thicknesses, other characteristics, or a combination thereof to achieve desired etching selectivity. In the depicted embodiment, semiconductor layers 220 include silicon, semiconductor layers 215 include silicon germanium having a first germanium atomic percent, and semiconductor layers 225 include silicon germanium having a second germanium atomic percent. The second germanium atomic percent is greater than the first germanium atomic percent. In some embodiments, the second germanium atomic percent is about 30% to about 50%, and the first germanium atomic percent is about 15% to about 30%. With such compositions, semiconductor layers 215 may have a first etch rate to an etchant, semiconductor layers 220 may have a second etch rate to the etchant, and semiconductor layers 225 may have a third etch rate to the etchant, where the first etch rate, the second etch rate, and the third etch rate are different. In some embodiments, semiconductor layers 220 include silicon germanium having a third germanium atomic percent that is different than the first germanium atomic percent and the second germanium atomic percent. In such embodiments, the second germanium atomic percent is the greatest, and topmost layers of fins 208A-208C have the highest germanium atomic percent. In some embodiments, semiconductor layers 215, semiconductor layers 220, semiconductor layers 225, or a combination thereof include n-type dopants and/or p-type dopants. For example, semiconductor layers 220 in n-type transistor regions may include p-type dopants, and semiconductor layers 220 in p-type transistor regions may include n-type dopants. The present disclosure contemplates semiconductor layers 215, semiconductor layers 220, and semiconductor layers 225 having any combination of semiconductor materials that provide desired etching selectivity and/or desired performance characteristics (e.g., materials that maximize current flow), including any of the semiconductor materials disclosed herein.

As described further below, semiconductor layers 220 or portions thereof form channel regions of transistors in multigate device 200. In FIG. 2, each semiconductor layer stack 210 includes four semiconductor layers 215 and three semiconductor layers 220. Semiconductor layer stack 210 thus includes four semiconductor layer pairs disposed over substrate 206, three of which have a respective semiconductor layer 215 and a respective semiconductor layer 220 and one of which has a respective semiconductor layer 215 and a respective semiconductor layer 225. After processing, this configuration may result in multigate device 200 having three channels. However, in some embodiments, semiconductor layer stack 210 includes more or less semiconductor layers depending, for example, on a number of channels desired for and/or design requirements of multigate device 200. For example, semiconductor layer stacks 210 and semiconductor layers 215 may each include two to ten semiconductor layers 220. In furtherance of the depicted embodiment, semiconductor layers 215 have a thickness t1, semiconductor layers 220 have a thickness t2, and semiconductor layers 225 have a thickness t3. Thickness t1, thickness t2, and thickness t3 may be chosen based on fabrication and/or device performance considerations. For example, thickness t1 is configured to provide a desired distance (or spacing) between adjacent channels of transistors (e.g., between semiconductor layers 220), thickness t2 is configured to provide a desired thickness of channels of transistors, and thickness t3 is configured to provide a desired thickness of gate helmets for protecting the channels.

Fabrication of fins 208A-208C may include forming a semiconductor layer stack precursor over substrate 206 and performing a lithography process and/or etching process to pattern the semiconductor layer stack precursor and/or substrate 206. In some embodiments, forming the semiconductor layer stack precursor includes epitaxially growing semiconductor layers 215 and semiconductor layers 220 in an interleaving and alternating configuration over substrate 206 and then epitaxially growing semiconductor layer 225 over topmost semiconductor layer 215. For example, a first one of semiconductor layers 215 is epitaxially grown on substrate 206, a first one of semiconductor layers 220 is epitaxially grown on the first one of semiconductor layers 220, a second one of semiconductor layers 215 is epitaxially grown on the first one of semiconductor layers 220, and so on until a desired number of semiconductor layers 215 and semiconductor layers 220 for semiconductor layer stacks 210 are provided over substrate 206. Semiconductor layer 225 may then be epitaxially grown on topmost semiconductor layer 215. Epitaxial growth is achieved by a molecular beam epitaxy (MBE) process, a chemical vapor deposition (CVD) process, a metalorganic chemical vapor deposition (MOCVD) process, other suitable epitaxial growth process, or a combination thereof.

The lithography process may include forming a resist layer over the semiconductor layer stack precursor (for example, by spin coating), performing a pre-exposure baking process, performing an exposure process using a mask, performing a post-exposure baking process, and performing a developing process. During the exposure process, the resist layer is exposed to radiation energy (such as ultraviolet (UV) light, deep UV (DUV) light, or extreme UV (EUV) light), where the mask blocks, transmits, and/or reflects radiation to the resist layer depending on a mask pattern of the mask and/or mask type (for example, binary mask, phase shift mask, or EUV mask), such that an image is projected onto the resist layer that corresponds with the mask pattern. Since the resist layer is sensitive to radiation energy, exposed portions of the resist layer chemically change, and exposed (or non-exposed) portions of the resist layer are dissolved during the developing process depending on characteristics of the resist layer and characteristics of a developing solution used in the developing process. After development, the patterned resist layer includes a resist pattern that corresponds with the mask. The etching process removes portions of the semiconductor layer stack precursor and/or substrate 206 using the patterned resist layer as an etch mask. In some embodiments, the patterned resist layer is formed over a mask layer disposed over the semiconductor layer stack precursor, a first etching process removes portions of the mask layer to form a patterning layer (e.g., a patterned hard mask layer), and a second etching process removes portions of the semiconductor layer stack precursor and/or substrate 206 using the patterning layer as an etch mask. The etching process is a dry etch, a wet etch, other suitable etching process, or a combination thereof. In some embodiments, the etching process is a reactive ion etching (RIE) process. After etching, the patterned resist layer may be removed, for example, by a resist stripping process or other suitable process.

In some embodiments, fins 208A-208C are formed by a multiple patterning process, such as a double patterning lithography (DPL) process (for example, a lithography-etch-lithography-etch (LELE) process, a self-aligned double patterning (SADP) process, a spacer-is-dielectric (SID) SADP process, other double patterning process, or a combination thereof), a triple patterning process (for example, a lithography-etch-lithography-etch-lithography-etch (LELELE) process, a self-aligned triple patterning (SATP) process, other triple patterning process, or a combination thereof), other multiple patterning process (for example, a self-aligned quadruple patterning (SAQP) process), or a combination thereof. Such processes may also provide fins 208A-208C with a respective semiconductor layer stack 210 over a respective mesa 206′, as depicted in FIG. 2. In some embodiments, directed self-assembly (DSA) techniques are implemented while patterning the semiconductor layer stack precursor. Further, in some embodiments, the exposure process may implement maskless lithography, electron-beam (e-beam) writing, ion-beam writing, or a combination thereof for patterning the resist layer.

Trenches 230 are between fins 208A-208C, and isolation features 235 are formed in trenches 230. Isolation features 235 fill lower portions of trenches 230 and surround portions of fins 208A-208C. Portions of fins 208A-208C that extend from top surfaces of isolation features 235 may be referred to as fin active regions. Isolation features 235 electrically isolate active device regions and/or passive device regions. For example, isolation features 235 separate and electrically isolate fin 208A and fin 208B, fin 208B and fin 208C, fin 208A from other device regions/features, and fin 208C from other device regions/features. Isolation features 235 include silicon oxide, silicon nitride, silicon oxynitride, other suitable isolation material (for example, including silicon, oxygen, nitrogen, carbon, etc.), or a combination thereof. Isolation features 235 may have a multilayer structure. For example, isolation features 235 include a bulk dielectric (e.g., an oxide layer) over a dielectric liner (for example, silicon nitride, silicon oxide, silicon oxynitride, silicon oxycarbonitride, or a combination thereof). In another example, isolation features 235 include a bulk dielectric over a doped liner, such as a boron silicate glass (BSG) liner and/or a phosphosilicate glass (PSG) liner. Dimensions and/or characteristics of isolation features 235 are configured to provide shallow trench isolation (STI) structures, deep trench isolation (DTI) structures, local oxidation of silicon (LOCOS) structures, other suitable isolation structures, or a combination thereof. In FIG. 2, isolation features 235 may be STIs.

Isolation features 235 may be formed by depositing a liner layer (e.g., a dielectric layer) over multigate device 200 that partially fills trenches 230, depositing an oxide material over multigate device 200 (e.g., over the liner layer) that fills remainders of trenches 230, and performing a planarization process. The planarization process, such as a chemical mechanical polishing (CMP) process, is performed until reaching and exposing a planarization stop layer, such as semiconductor layers 225. In some embodiments, the planarization process removes mask layers, any of the liner layer, any of the oxide material, or a combination thereof that are above and/or over top surfaces of fins 208A-208C. Remainders of the liner layer and the oxide material form liners and bulk dielectrics, respectively, of isolation features 235. The liner may cover sidewalls of trenches 230 (formed by sidewalls of fins 208A-208C) and bottoms of trenches 230 (formed by substrate 206). The liner layer is formed by atomic layer deposition (ALD), CVD, physical vapor deposition (PVD), high density plasma CVD (HDPCVD), MOCVD, RPCVD, PECVD, LPCVD, atomic layer CVD (ALCVD), atmospheric pressure CVD (APCVD), sub-atmospheric CVD (SACVD), other suitable methods, or a combination thereof. The oxide material is formed by flowable CVD (FCVD), a high aspect ratio deposition (HARP) process, HDPCVD, other suitable process, or a combination thereof. In some embodiments, an annealing process is performed when forming isolation features 235.

Isolation features 235 are then recessed and/or etched back, such that fins 208A-208C protrude from isolation features 235. In FIG. 2, isolation features 235 are etched back until below semiconductor layer stacks 210. In some embodiments, a height of isolation features 235 along the z-direction is less than a height of mesas 206′ along the z-direction (e.g., relative to a top surface of substrate 206). In some embodiments, an etching process selectively removes isolation features 235 with respect to semiconductor layer stacks 210. For example, the etching process removes isolation features 235 but does not remove, or does not substantially remove, semiconductor layers 225, semiconductor layers 220, semiconductor layers 215, and mesas 206′. An etchant may be selected for the etch process that etches dielectric materials (e.g., isolation features 235) at a higher rate than semiconductor materials. The etching process is a dry etch, a wet etch, other suitable etching process, or a combination thereof. In some embodiments, the etching process removes mask/patterning layers of fins 208A-208C. In some embodiments, the mask/patterning layers function as etch masks during the etching process.

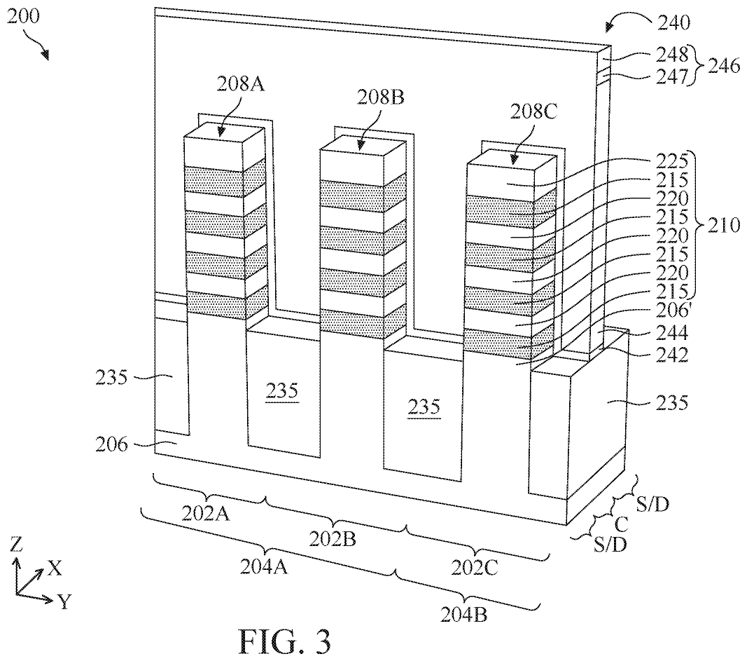

Turning to FIG. 3, a dummy gate stack 240 is formed over portions of fins 208A-208C. Dummy gate stack 240 partially fills upper portions of trenches 230. Dummy gate stack 240 extends lengthwise in a direction that is different than (e.g., orthogonal to) the lengthwise direction of fins 208A-208C. For example, dummy gate stack 240 extends along the y-direction, having a length in the y-direction, a width in the x-direction, and a height in the z-direction. Dummy gate stack 240 is disposed over channel regions (C) and between source/drain regions (S/D). In the Y-Z plane, dummy gate stack 240 is disposed on tops and sidewalls of fins 208A-208C, and dummy gate stack 240 wraps channel regions of fins 208A-208C. Dummy gate stack 240 is further disposed over tops of isolation features 235. In the X-Z plane, dummy gate stack 240 is disposed over tops of channel regions of fins 208A-208C, and dummy gate stack 240 is disposed between source/drain regions of fins 208A-208C.

Dummy gate stack 240 includes a dummy gate dielectric 242, a dummy gate electrode 244, and a hard mask 246 (including, for example, a first mask layer 247 and a second mask layer 248). Dummy gate dielectric 242 includes a dielectric material, such as silicon oxide, a high-k dielectric material, other suitable dielectric material, or a combination thereof. For example, dummy gate dielectric 242 is an oxide layer. Dummy gate electrode 244 includes a suitable dummy gate material, such as polysilicon. In some embodiments, dummy gate stack 240 includes other layers, such as a capping layer, an interface layer, a diffusion layer, a barrier layer, or a combination thereof. Dummy gate stack 240 is formed by deposition processes, lithography processes, etching processes, other suitable processes, or a combination thereof. For example, dummy gate stack 240 is formed by depositing a dummy gate dielectric layer over multigate device 200, depositing a dummy gate electrode layer over the dummy gate dielectric layer, depositing a hard mask layer over the dummy gate electrode layer, and performing a lithography process and an etching process to pattern the hard mask layer, the dummy gate electrode layer, and the dummy gate dielectric layer. A remainder of the hard mask layer, the dummy gate electrode layer, and the dummy gate dielectric layer form dummy gate dielectric 242, dummy gate electrode 244, and hard mask 246, respectively, as depicted. The hard mask layer, the dummy gate electrode layer, and the dummy gate dielectric layer may be deposited by CVD, PVD, ALD, other suitable deposition process, or a combination thereof.

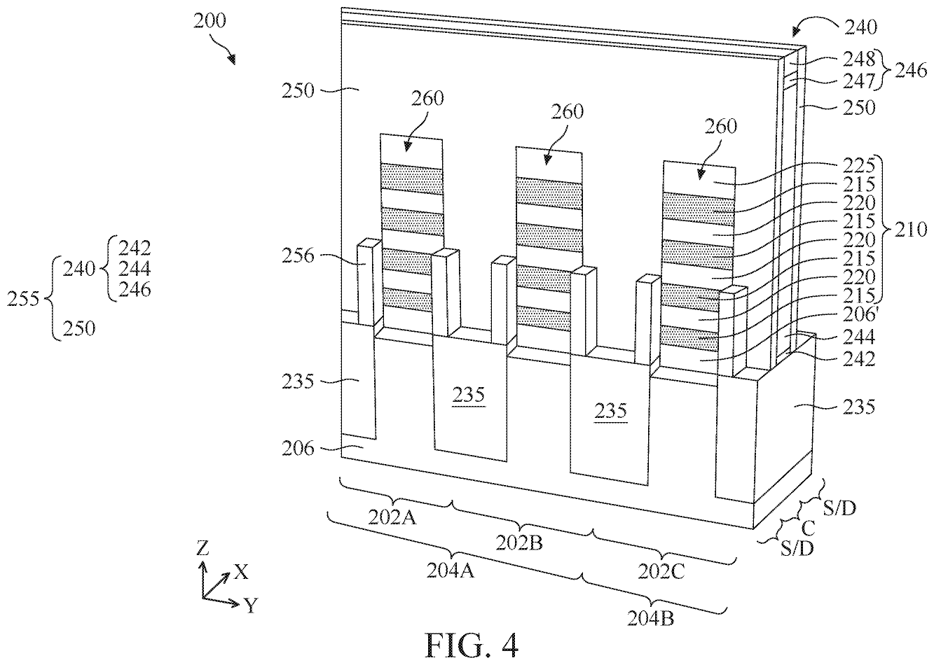

Turning to FIG. 4, gate spacers 250 are formed along sidewalls of dummy gate stack 240, thereby forming a gate structure 255 (which collectively refers to dummy gate stack 240 and gate spacers 250), fin spacers 256 are formed along sidewalls of source/drain regions of fins 208A-208C, and portions of fins 208A-208C (i.e., source/drain regions of fins 208A-208C that are not covered by gate structure 255) are at least partially removed to form source/drain recesses (trenches) 260. Gate spacers 250 are disposed adjacent to dummy gate stack 240, and fin spacers 256 are disposed adjacent to semiconductor layer stacks 210 in source/drain regions of fins 208A-208C before removal thereof. Gate spacers 250 and fin spacers 256 are formed by any suitable process and include a dielectric material, which may include silicon, oxygen, carbon, nitrogen, other suitable dielectric constituent, or a combination thereof (e.g., silicon oxide, silicon nitride, silicon oxynitride, silicon carbide, silicon carbonitride, silicon oxycarbide, silicon oxycarbonitride, or a combination thereof). For example, a spacer layer including silicon and nitrogen, such as a silicon nitride layer, is deposited over multigate device 200 and etched to form gate spacers 250 and fin spacers 256. In some embodiments, gate spacers 250 and/or fin spacers 256 have a multilayer structure, such as a first dielectric layer that includes silicon nitride and a second dielectric layer that includes silicon carbide. In some embodiments, gate spacers 250 and/or fin spacers 256 include more than one set of spacers, such as seal spacers, offset spacers, sacrificial spacers, dummy spacers, main spacers, or a combination thereof. In such embodiments, the various sets of spacers may have different compositions.

In the depicted embodiment, an etching process completely removes semiconductor layer stacks 210 in source/drain regions of fins 208A-208C, thereby exposing mesas 206′. The etching process further removes some, but not all, of mesas 206′, such that source/drain recesses 260 extend below top surfaces of isolation features 235. Each source/drain recess 260 has respective sidewalls formed by fin spacers 256 and isolation features 235 thereunder, a respective sidewall formed by a remaining portion of a semiconductor layer stack 210 in a channel region of a respective one of fins 208A-208C, and a bottom formed by a respective mesa 206′. In some embodiments, the etching process removes some, but not all, of semiconductor layer stacks 210, and source/drain recesses 260 have bottoms formed by semiconductor layers 215 or semiconductor layers 220. In some embodiments, the etching process stops at mesas 206′, and source/drain recesses 260 do not extend below isolation features 235. The etching process is a dry etch, a wet etch, other suitable etch, or a combination thereof. In some embodiments, the etching process is a multistep etch process. In some embodiments, parameters of the etching process are configured to selectively etch semiconductor layer stacks 210 with minimal to no (i.e., negligible) etching of gate structure 255 (i.e., dummy gate stack 240 and gate spacers 250), fin spacers 256, isolation features 235, or a combination thereof.

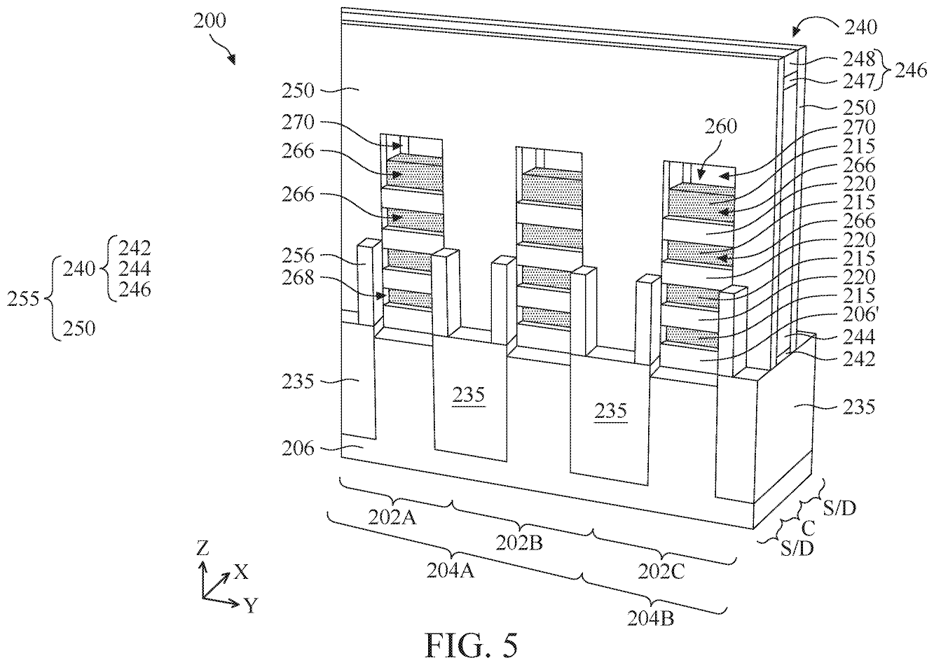

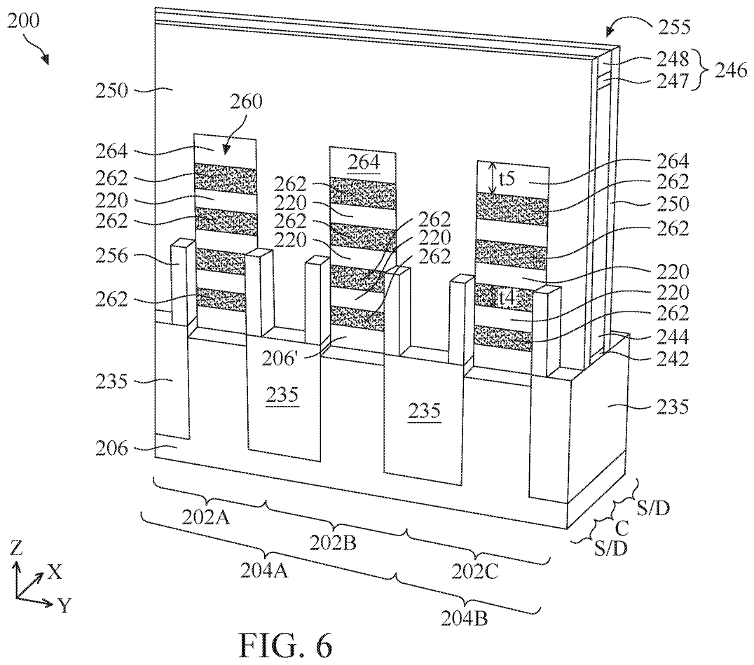

Turning to FIG. 5 and FIG. 6, processing includes forming inner spacers 262 under gate spacers 250 along sidewalls of semiconductor layers 215 and forming gate helmets 264 under gate structure 255 (i.e., under dummy gate stack 240 and gate spacers 250) over semiconductor layer stacks 210. Inner spacers 262 separate semiconductor layers 220 from one another and bottom semiconductor layers 220 from mesas 206′, while gate helmets 264 separate top semiconductor layers 215 from gate structure 255. Inner spacers 262 replace portions of semiconductor layers 215 under gate spacers 250, and gate helmets 264 replace semiconductor layers 225 under gate structure 255. Inner spacers 262 have a thickness t4, and gate helmets 264 have a thickness t5. Thickness t5 is greater than thickness t4. In some embodiments, thickness t5 is about 3 nm to about 15 nm. In some embodiments, thickness t4 is about 2.5 nm to about 14 nm. In some embodiments, thickness t5 is less than or equal to thickness t4. In some embodiments, thickness t5 is thickness t3 and/or thickness t4 is thickness t1.

Forming inner spacers 262 and gate helmets 264 may include a first etching process, a deposition process, and a second etching process. For example, in FIG. 5, the first etching process selectively etches semiconductor layers 215 and semiconductor layers 225 with negligible etching of semiconductor layers 220, mesas 206′, isolation features 235, dummy gate stack 240, gate spacers 250, fin spacers 256, or a combination thereof. The first etching process is also configured to laterally etch (e.g., along the x-direction and/or the y-direction) semiconductor layers 215 and semiconductor layers 225 to reduce lengths thereof along the x-direction. Accordingly, the first etching process forms gaps 266 between semiconductor layers 220, gaps 268 between mesas 206′ and semiconductor layers 220, and gaps 270 between gate structure 255 and top semiconductor layers 215. Gaps 266 and gaps 268 are underneath gate spacers 250, such that semiconductor layers 220 are suspended under gate spacers 250, separated from adjacent semiconductor layers 220 by gaps 266, and separated by adjacent mesas 206′ by gaps 268. In some embodiments, gaps 266 laterally extend (e.g., along the x-direction) under dummy gate stack 240. Gaps 270 are underneath gate spacers 250 and dummy gate stack 240, such that top semiconductor layers 215 are separated from gate structure 255 by gaps 270.

Because semiconductor layers 215 and semiconductor layers 225 have different compositions (e.g., different germanium concentrations), parameters of the first etching process may be configured to completely remove semiconductor layers 225 and partially remove semiconductor layers 215. For example, an etchant of the first etching process removes semiconductor layers 225 (e.g., SiGe having a germanium atomic concentration of about 30% to about 50%) at a first etch rate and semiconductor layers 215 (e.g., SiGe having a germanium atomic concentration of about 15% to about 30%) at a second etch rate, where the first etch rate is greater than the second etch rate. In such example, a ratio of the first etch rate to the second etch rate may be tuned to simultaneously remove semiconductor layers 225 and semiconductor layers 215, yet completely remove semiconductor layers 225 while partially removing semiconductor layers 215. The first etching process is a dry etch, a wet etch, other suitable etch, or a combination thereof. In some embodiments, the first etching process is an anisotropic etch having a horizontal etch rate that is greater than a vertical etch rate (in some embodiments, the vertical etch rate equals zero), such that the anisotropic etch removes material in substantially the horizontal direction with negligible material removal in the vertical direction.

In FIG. 6, a deposition process forms a spacer layer over multigate device 200, and a second etching process selectively etches the spacer layer to form inner spacers 262, which fill gaps 266 and gaps 268, and gate helmets 264, which fill gaps 270, with negligible etching of semiconductor layers 220, mesas 206′, isolation features 235, dummy gate stack 240, gate spacers 250, fin spacers 256, or a combination thereof. To achieve desired etching selectivity during the second etching process, the spacer layer (and thus inner spacers 262 and gate helmets 264) has a composition different than compositions of semiconductor layers 220, mesas 206′, isolation features 235, dummy gate stack 240, gate spacers 250, fin spacers 256, or a combination thereof. In some embodiments, the spacer layer includes a dielectric material that includes silicon, oxygen, carbon, nitrogen, other suitable dielectric constituent, or a combination thereof. For example, the spacer layer is a silicon nitride layer, a silicon carbonitride layer, a silicon oxycarbonitride layer, a silicon oxycarbide layer, or a combination thereof. The second etching process is a dry etch, a wet etch, other suitable etch, or a combination thereof.

The deposition process may include CVD, PVD, ALD, HDPCVD, MOCVD, RPCVD, PECVD, LPCVD, ALCVD, APCVD, other suitable methods, or a combination thereof. The deposition process is configured to fill gaps 266, gaps 268, and gaps 270 with the spacer layer. In some embodiments, a single deposition process is performed to form the spacer layer filling gaps 266, gaps 268, and gaps 270. In some embodiments, where gaps 270 are wider than gaps 266 and gaps 268 (e.g., where semiconductor layers 225 are thicker than semiconductor layers 215), gaps 266 and gaps 268 may be filled by the deposition process before gaps 270. In such embodiments, a first deposition process may be performed to form a first spacer layer that completely fills gaps 266 and gaps 268 and partially fills gaps 270, and a second deposition process may be performed to form a second spacer layer that fills remainders of gaps 270. Inner spacers 262 are thus formed from the first spacer layer, and gate helmets 264 are formed from the first spacer layer and the second spacer layer. A composition and/or a material of the first spacer layer is the same or different than a composition and/or a material of the second spacer layer. In embodiments where the first spacer layer and the second spacer layer have different compositions and/or materials, gate helmets 264 have multilayer structures.

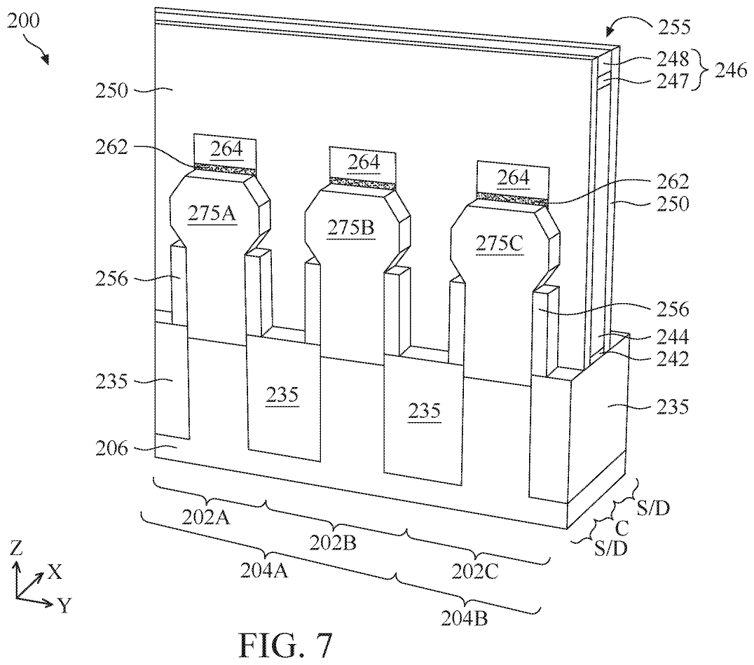

Turning to FIG. 7, epitaxial source/drains are formed in source/drain recesses 260. For example, a semiconductor material is epitaxially grown from mesas 206′, semiconductor layers 220, semiconductor layers 215, or a combination thereof, thereby forming epitaxial source/drains 275A in transistor region 202A, epitaxial source/drains 275B in transistor region 202B, and epitaxial source/drains 275C in transistor region 202C. Epitaxial source/drains 275A-275C fill respective source/drain recesses 260, and in the depicted embodiment, have portions between respective isolation features 235, between respective fin spacers 256, and over fin spacers 256. In FIG. 7, epitaxial source/drains 275A-275C are below gate helmets 264. For example, a distance between tops of epitaxial source/drains 275A-275C and tops of fin spacers 256 (e.g., along the z-direction) is less than a distance between gate helmets 264 (e.g., bottoms thereof) and tops of fin spacers 256. In the depicted embodiment, epitaxial source/drains 275A-275C are also below top inner spacers 262. For example, the distance between tops of epitaxial source/drains 275A-275C and tops of fin spacers 256 is less than a distance between tops of top inner spacers 262 and tops of fin spacers 256. Other configurations of epitaxial source/drains 275A-275C relative to gate helmets 264 and/or top inner spacers 262 are contemplated.

An epitaxy process may use CVD deposition techniques (e.g., RPCVD, LPCVD, VPE, UHV-CVD, or a combination thereof), MBE, other suitable epitaxial growth processes, or a combination thereof. The epitaxy process may use gaseous precursors and/or liquid precursors, which interact with the composition of mesas 206′, semiconductor layers 220, semiconductor layers 215, or a combination thereof. Epitaxial source/drains 275A-275C have the same or different compositions and/or materials depending on configurations of their respective transistor regions 202A-202C. Epitaxial source/drains 275A-275C may be doped with n-type dopants and/or p-type dopants. In some embodiments (e.g., when forming portions of n-type transistors), epitaxial source/drains 275A-275C include silicon that may be doped with carbon, phosphorous, arsenic, other n-type dopant, or a combination thereof (e.g., Si:C epitaxial source/drains, Si:P epitaxial source/drains, or Si:C:P epitaxial source/drains). In some embodiments (e.g., when forming portions of p-type transistors), epitaxial source/drains 275A-275C include silicon germanium or germanium, which may be doped with boron, other p-type dopant, or a combination thereof (e.g., Si:Ge:B epitaxial source/drains). In some embodiments, epitaxial source/drains 275A-275C include more than one epitaxial semiconductor layer, where the epitaxial semiconductor layers may include the same or different materials and/or the same or different dopant concentrations. In some embodiments, epitaxial source/drains 275A-275C include materials and/or dopants that achieve desired tensile stress and/or compressive stress in channel regions of transistor regions 202A-202C. In some embodiments, epitaxial source/drains 275A-275C are doped during deposition by adding impurities to a source material of the epitaxy process (i.e., in-situ). In some embodiments, epitaxial source/drains 275A-275C are doped by an ion implantation process after a deposition process. In some embodiments, annealing processes (e.g., rapid thermal annealing and/or laser annealing) are performed to activate dopants in epitaxial source/drains 275A-275C and/or other source/drain regions, such as heavily doped source/drain (HDD) regions and/or lightly doped source/drain (LDD) regions. In some embodiments, epitaxial source/drains 275A-275C are formed in separate processing sequences. For example, p-type transistor regions are masked when epitaxial source/drains are formed for n-type transistors in n-type transistor regions, and n-type transistor regions are masked when epitaxial source/drains are formed for p-type transistors in p-type transistor regions.

Turning to FIG. 8, a dielectric layer 280 is formed over multigate device 200. Dielectric layer 280 is disposed over epitaxial source/drains 275A-275C. In the Y-Z plane, dielectric layer 280 fills spaces between epitaxial source/drains 275A-275C and spaces between fin spacers 256. In the X-Z plane, dielectric layer 280 fills spaces between gate structure 255 and adjacent features. For example, dielectric layer 280 may fill spaces between gate spacers 250 of gate structure 255 and gate spacers of adjacent gate structures. In some embodiments, forming dielectric layer 280 includes depositing a contact etch stop layer (CESL) 282, depositing an interlayer dielectric (ILD) layer 284 over CESL 282, and performing a CMP and/or other planarization process until reaching (exposing) dummy gate electrode 244. The planarization process may remove hard mask 246 of dummy gate stack 240 to expose underlying dummy gate electrode 244, such as a polysilicon dummy gate electrode. CESL 282 and ILD layer 284 are formed by CVD, other suitable methods, or a combination thereof. In some embodiments, ILD layer 284 is formed by FCVD, HARP, HDPCVD, or a combination thereof.

ILD layer 284 includes a dielectric material, such as silicon oxide, carbon doped silicon oxide, silicon nitride, silicon oxynitride, TEOS-formed oxide, PSG, BSG, BPSG, FSG, xerogel, aerogel, amorphous fluorinated carbon, parylene, BCB-based dielectric material, polyimide, other suitable dielectric material, or a combination thereof. In some embodiments, ILD layer 284 includes a low-k dielectric material having a dielectric constant that is less than a dielectric constant of silicon dioxide (e.g., k<3.9). In some embodiments, ILD layer 284 includes a dielectric material having a dielectric constant that is less than about 2.5 (i.e., an extreme low-k (ELK) dielectric material), such as porous silicon dioxide, silicon carbide, carbon-doped oxide (e.g., a SiCOH-based material having, for example, Si—CH₃ bonds), or a combination thereof, each of which is tuned/configured to exhibit a dielectric constant less than about 2.5. ILD layer 284 may include a multilayer structure having multiple dielectric materials. CESL 282 includes a material different than ILD layer 284, such as a dielectric material that is different than the dielectric material of ILD layer 284. For example, where ILD layer 284 includes a silicon-and-oxygen comprising low-k dielectric material, CESL 282 may include silicon and nitrogen, such as silicon nitride or silicon oxynitride.

Turning to FIGS. 9-13, a gate replacement process is performed to replace dummy gate stack 240 with gates in transistor regions 202A-202C and a channel release process is performed to form suspended channel layers in channel regions of transistor regions 202A-202C. The gates at least partially surround the suspended channel layers. For ease of description and understanding, FIGS. 9-13 are taken (cut) through gate structure 255 along line G-G′ in FIG. 8 (and are thus referred to as gate cut perspective views). Referring to FIG. 9, a gate opening 285 is formed in gate structure 255 by removing dummy gate electrode 244. For example, an etching process selectively removes dummy gate electrode 244 with respect to dummy gate dielectric 242, gate spacers 250, ILD layer 284, CESL 282, or a combination thereof. In other words, the etching process removes dummy gate electrode 244 with negligible removal of dummy gate dielectric 242, gate spacers 250, ILD layer 284, CESL 282, or a combination thereof. For example, an etchant is selected for the etching process that removes polysilicon (i.e., dummy gate electrode 244) at a higher rate than dielectric materials (i.e., dummy gate dielectric 242, gate spacers 250, ILD layer 284, CESL 282, etc.) (i.e., the etchant has a high etch selectivity with respect to polysilicon). In the depicted embodiment, the etching process completely removes dummy gate electrode 244 and exposes dummy gate dielectric 242. In some embodiments, the etching process may partially or completely remove dummy gate dielectric 242. The etching process is a dry etch, a wet etch, other suitable etch, or a combination thereof. In some embodiments, the etch process includes multiple steps. In some embodiments, during the etching process, a patterned mask layer covers ILD layer 284, CESL 282, gate spacers 250, or a combination thereof, and has an opening therein that exposes dummy gate stack 240.

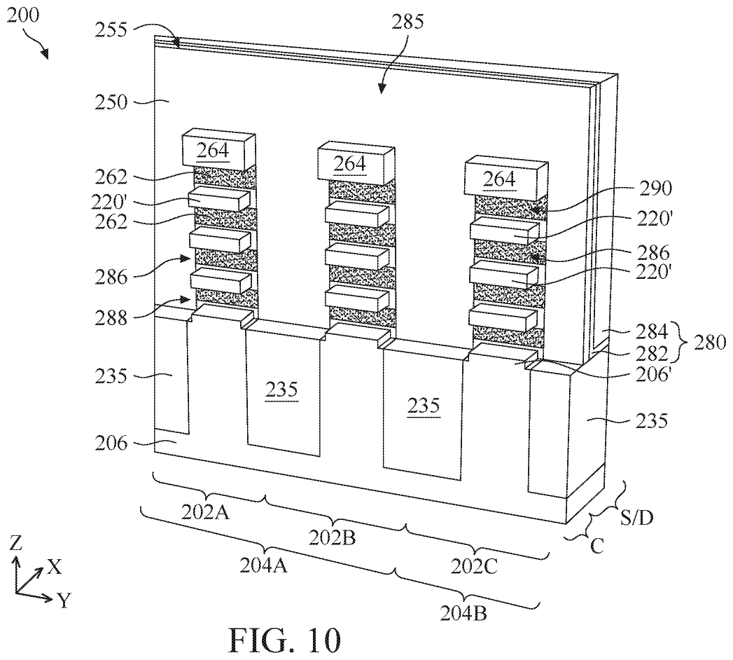

Referring to FIG. 10, processing includes removing dummy gate dielectric 242 and performing a channel release process to form suspended channel layers in channel regions of transistor regions 202A-202C. For example, an etching process selectively removes dummy gate dielectric 242 with respect to semiconductor layer stacks 210, gate spacers 250, ILD layer 284, CESL 282, or a combination thereof. In other words, the etching process removes dummy gate dielectric 242 with negligible removal of semiconductor layer stacks 210, gate spacers 250, ILD layer 284, CESL 282, or a combination thereof. For example, an etchant is selected for the etching process that removes dummy gate dielectric 242 at a higher rate than semiconductor layer stacks 210, gate spacers 250, ILD layer 284, CESL 282, or a combination thereof (i.e., the etchant has a high etch selectivity with respect to an interfacial oxide). The etching process is a dry etch, a wet etch, other suitable etch, or a combination thereof. In some embodiments, the etch process includes multiple steps. In some embodiments, the patterned mask layer used during removal of dummy gate electrode 244 may be used during removal of dummy gate dielectric 242 and/or during the channel release process described below.

In FIG. 10, semiconductor layers 215 exposed by gate opening 285 are also selectively removed to form gaps/openings 286, gaps/openings 288, and gaps/openings 290, thereby suspending semiconductor layers 220 over mesas 206′ in channel regions of transistor regions 202A-202C. Gate opening 285 is thus extended between semiconductor layers 220, between semiconductor layers 220 and gate helmets 264, and between semiconductor layers 220 and mesas 206′. Gaps 286 are between semiconductor layers 220, gaps 288 are between semiconductor layers 220 and mesas 206′, and gaps 290 are between semiconductor layers 220 and gate helmets 264. In the depicted embodiment, each channel region has three suspended semiconductor layers 220, which are referred to hereafter as channel layers 220′. Channel layers 220′ are vertically stacked along the z-direction and provide three channels, respectively, through which current may flow between respective epitaxial source/drains 275A-275C.

In some embodiments, an etching process selectively removes semiconductor layers 215 with negligible removal of mesas 206′, semiconductor layers 220, gate helmets 264, inner spacers 262, gate spacers 250, dielectric layer 280, or a combination thereof. For example, an etchant is selected for the etch process that etches silicon germanium (i.e., semiconductor layers 215) at a higher rate than silicon (i.e., semiconductor layers 220 and mesas 206′) and dielectric materials (i.e., gate helmets 264, inner spacers 262, gate spacers 250, CESL 282, ILD layer 284, or a combination thereof) (i.e., the etchant has a high etch selectivity with respect to silicon germanium). The etching process is a dry etch, a wet etch, other suitable etch, or a combination thereof. In some embodiments, before performing the etching process, an oxidation process converts semiconductor layers 215 into silicon germanium oxide features, and the etching process removes the silicon germanium oxide features. In some embodiments, dummy gate dielectric 242 and semiconductor layers 215 are removed by different etching processes (e.g., a first etch for dummy gate dielectric 242 removal and a second etch for semiconductor layers 215 removal). In some embodiments, a single etching process is performed to remove dummy gate dielectric 242 and semiconductor layers 215 (e.g., using an etchant that may remove both).

An etching process may be performed to modify a profile of channel layers 220′ to provide target dimensions and/or target shapes thereof. For example, the etching process may provide channel layers 220′ with cylindrical-shaped profiles (e.g., nanowires), rectangular-shaped profiles (e.g., nanobars), sheet-shaped profiles (e.g., nanosheets (e.g., dimensions in the X-Y plane are sufficiently greater than dimensions in the X-Z plane and the Y-Z plane to form sheet-like structures)), or any other suitable shaped profile. In some embodiments, channel layers 220′ have nanometer-sized dimensions and may be referred to as “nanostructures,” alone or collectively. In some embodiments, channel layers 220′ have sub-nanometer dimensions and/or other suitable dimensions. In the depicted embodiment, channel layers 220′ have dimensions that are less than dimensions of inner spacers 262 and/or gate helmets 264. In some embodiments, widths (e.g., along the y-direction) of channel layers 220′ are less than widths (e.g., along the y-direction) of inner spacers 262 and/or gate helmets 264. In some embodiments, thicknesses (e.g., along the z-direction) of channel layers 220′ are less than thicknesses (e.g., along the z-direction) of inner spacers 262 and/or gate helmets 264.

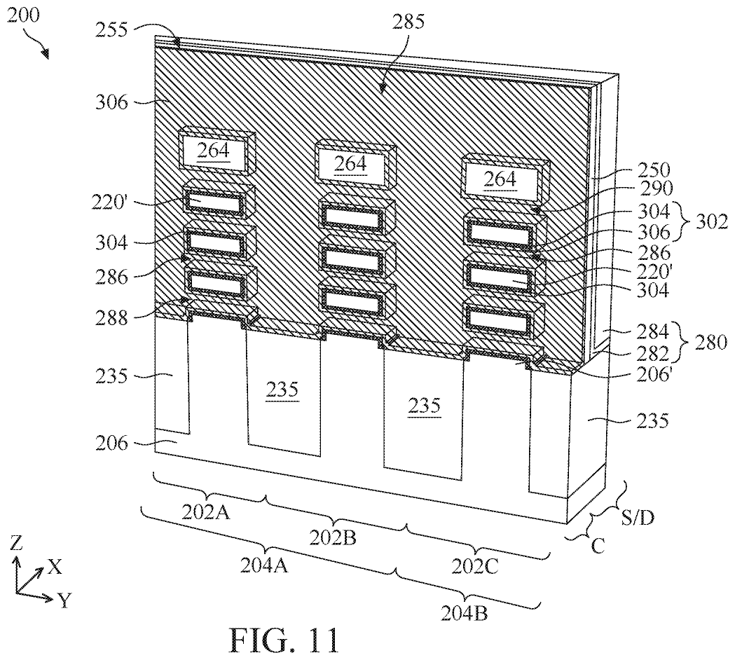

Referring to FIG. 11, a gate dielectric 302 is formed in and partially fills gate opening 285. Gate dielectric 302 also partially fills gaps 286, gaps 288, and gaps 290. Gate dielectric 302 includes a dielectric layer, such as an interfacial layer 304 and a high-k dielectric layer 306. Interfacial layer 304 and high-k dielectric layer 306 are disposed on top surfaces, bottom surfaces, and sidewalls of channel layers 220′. For example, gate dielectric 302 surrounds channel layers 220′. Gate dielectric 302 is also disposed over mesas 206′, isolation features 235, gate spacers 250, and gate helmets 264. For example, interfacial layer 304 and high-k dielectric layer 306 wrap mesas 206′, high-k dielectric layer 306 is disposed on top surfaces of isolation features 235, high-k dielectric layer 306 is disposed on sidewalls of gate spacers 250, and high-k dielectric layer 306 is disposed on top surfaces, bottom surfaces, and sidewalls of gate helmets 264 (e.g., high-k dielectric layer 306 surrounds gate helmets 264).

Interfacial layer 304 includes a dielectric material, such as SiO₂, HfSiO, SiON, other silicon-comprising dielectric material, other suitable dielectric material, or a combination thereof. Interfacial layer 304 is formed by thermal oxidation, chemical oxidation, ALD, CVD, other suitable process, or a combination thereof. For example, interfacial layer 304 is formed by a chemical oxidation process that exposes channel layers 220′ and mesas 206′ to hydrofluoric acid. In another example, interfacial layer 304 is formed by a thermal oxidation process that exposes channel layers 220′ and mesas 206′ to an oxygen ambient and/or air ambient. In some embodiments, interfacial layer 304 is formed on exposed semiconductor surfaces (e.g., channel layers 220′ and mesas 206′) but not exposed dielectric surfaces (e.g., gate helmets 264 and gate spacers 250). In some embodiments, interfacial layer 304 is formed after forming high-k dielectric layer 306. For example, after forming high-k dielectric layer 306, multigate device 200 may be annealed in an oxygen ambient and/or nitrogen ambient (e.g., nitrous oxide).

High-k dielectric layer 306 includes a high-k dielectric material, which refers to a dielectric material having a dielectric constant that is greater than that of silicon dioxide (k≈3.9). For example, high-k dielectric layer 306 includes HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba,Sr)TiO₃ (BST), Si₃N₄, hafnium dioxide-alumina (HfO₂—Al₂O₃) alloy, other suitable high-k dielectric material, or a combination thereof. High-k dielectric layer 306 is formed by ALD, CVD, PVD, oxidation-based deposition process, other suitable process, or a combination thereof. For example, an ALD process conformally deposits high-k dielectric layer 306, such that a thickness of high-k dielectric layer 306 is substantially uniform (conformal) over various surfaces in gate opening 285.

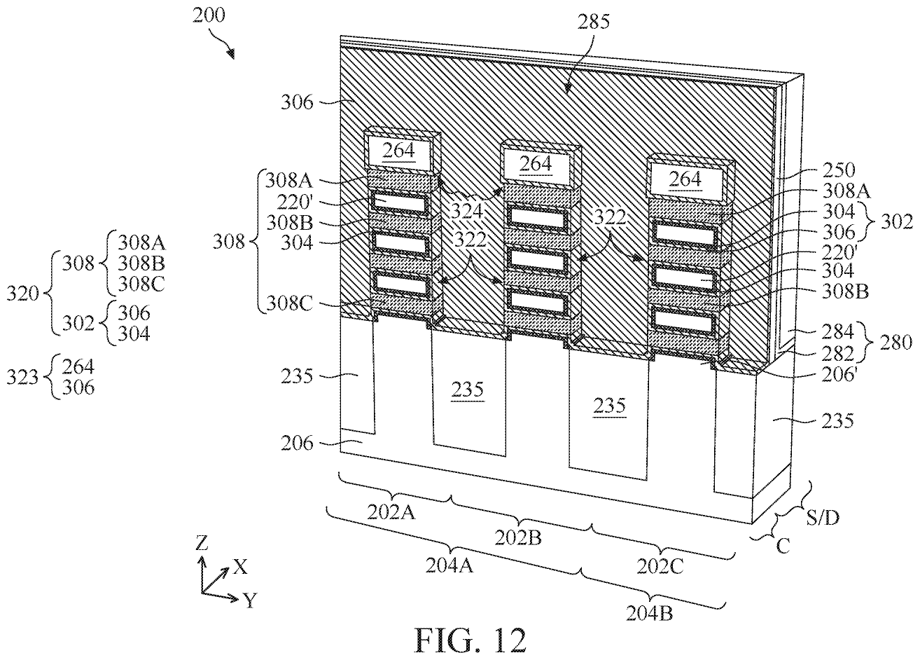

Referring to FIG. 12, gate electrodes 308 are formed over gate dielectric 302 in gate opening 285. Gate electrodes 308 partially fill gate opening 285, and gate electrodes 308 fill remainders of gaps 286, gaps 288, and gaps 290. For example, each gate electrode 308 includes a portion 308A that fills a remainder of a respective gap 290, portions 308B that fill remainders of respective gaps 286, and a portion 308C that fills a remainder of a respective gap 288. In such embodiments, gate electrodes 308 are disposed along top surfaces and bottom surfaces of channel layers 220′, bottom surfaces of gate helmets 264, and top surfaces of mesas 206′.

Gate electrodes 308 include an electrically conductive material, such as polysilicon, Al, Cu, Ti, Ta, W, Mo, Co, TaN, NiSi, CoSi, TIN, WN, TiAl, TiAlN, TaCN, TaC, TaSiN, other suitable electrically conductive material, or a combination thereof. Gate electrodes 308 may have a single layer structure or a multilayer structure. In some embodiments, portions 308A-308C each include a work function layer and a bulk (or fill) layer. The work function layer is an electrically conductive layer that is tuned to have a desired work function, such as an n-type work function or a p-type work function, and the bulk layer is an electrically conductive layer disposed over the work function layer. In some embodiments, the work function layer includes n-type work function materials, such as Ti, Ag, Mn, Zr, TaAl, TaAIC, TiAlN, TaC, TaCN, TaSiN, other suitable n-type work function material, or a combination thereof. In some embodiments, the work function layer includes a p-type work function material, such as Ru, Mo, Al, TiN, TaN, WN, ZrSi₂, MoSi₂, TaSi₂, NiSi₂, WN, other suitable p-type work function material, or a combination thereof. The bulk layer may include Al, W, Cu, Ti, Ta, alloys thereof, or a combination thereof. In some embodiments, portions 308A-308C include diffusion layers and/or barrier layers, such as a bulk layer disposed over a diffusion/barrier layer.

Forming gate electrodes 308 includes depositing a gate electrode material in gate opening 285 that fills remainders of gaps 286, gaps 288, and gaps 290 and etching back the gate electrode material, such that a remainder of the gate electrode material forms portions 308A-308C. The gate electrode material may partially or completely fill gate opening 285. In some embodiments, the etching back is an etching process that selectively removes the gate electrode material with negligible removal of high-k dielectric layer 306, CESL 282, ILD layer 284, or a combination thereof. For example, an etchant is selected for the etch process that removes metal materials (i.e., gate electrode material, which may form one or more layers of portions 308A-308C) at a higher rate than dielectric materials (i.e., high-k dielectric layer 306, CESL 282, ILD layer 284, or a combination thereof) (i.e., the etchant has a high etch selectivity with respect to metal materials). In some embodiments, after deposition, the gate electrode material is disposed along top surfaces, bottom surfaces, and sidewalls of channel layers 220′ and/or gate helmets 264 (i.e., the gate electrode material surrounds channel layers 220′ and/or gate helmets 264), and the etching back removes the gate electrode material from sidewalls of channel layers 220′, sidewalls of gate helmets 264, and tops of gate helmets 264. In such embodiments, the etching back exposes high-k dielectric layer 306 along sidewalls of channel layers 220′ and/or sidewalls and/or top of gate helmets 264. In some embodiments, the etching process is configured to stop upon reaching high-k dielectric layer 306. In some embodiments, the etching process uses high-k dielectric layer 306 as an etch stop. To minimize and/or prevent removal of the gate electrode material that fills gaps 286, gaps 288, and gaps 290, the etching process may be an anisotropic etch having a vertical etch rate that is greater than a horizontal etch rate, such that the anisotropic etch removes material in substantially the vertical direction with negligible material removal in the horizontal direction. In some embodiments, the horizontal etch rate may be zero. The etching process is a dry etch, a wet etch, other suitable etch, or a combination thereof.

In FIG. 12, each of transistor regions 202A-202C has a respective gate stack 320. Each gate stack 320 includes a respective gate dielectric 302 and a respective gate electrode 308. In the depicted embodiment, high-k dielectric layer 306 spans transistor regions 202A-202C, such that gate stacks 320 of transistor regions 202A-202C share high-k dielectric layer 306 (which may extend uninterrupted from transistor region 202A to transistor region 202C), but have separate, respective interfacial layers 304 and separate, respective gate electrodes 308. Because the gate electrode material is etched back, each gate stack 320 has sidewalls 322 formed by both its respective gate dielectric 302 (e.g., high-k dielectric layer 306 thereof) and its respective gate electrode 308. Further, each gate helmet 264 is surrounded by a respective portion of high-k dielectric layer 306. Gate helmets 264 and their respective surrounding high-k dielectric layer 306 are collectively referred to as gate helmet structures 323. In some embodiments, such as depicted, gate stacks 320 are disposed under gate helmet structures 323, and gate helmet structures 323 extend laterally (e.g., along the y-direction) beyond sidewalls 322 of gate stacks 320. For example, gate helmet structures 323 have overhangs 324, such that a distance (e.g., along the y-direction) is between sidewalls of gate helmet structures 323 and sidewalls 322 of gate stacks 320. In some embodiments, gate helmet structures 323 and gate stacks 320 may have substantially the same widths, such that sidewalls of gate helmet structures 323 are aligned with sidewalls 322 (e.g., along the z-direction).

Gate stacks 320 are configured to achieve desired functionality according to design requirements of multigate device 200, and gate stacks 320 may have different layers in transistor regions 202A-202C depending on configurations thereof. For example, a number, configuration, materials, or a combination thereof of layers of gate dielectrics 302 and/or gate electrodes 308 corresponding with a p-type transistor region may be different than a number, configuration, materials, or a combination thereof of layers of gate dielectrics 302 and/or gate electrodes 308 corresponding with an n-type transistor region. In another example, a number, configuration, materials, or a combination thereof of layers of gate dielectrics 302 and/or gate electrodes 308 corresponding with a first n-type transistor region may be different than a number, configuration, materials, or a combination thereof of layers of gate dielectrics 302 and/or gate electrodes 308 corresponding with a second n-type transistor region. In yet another example, a number, configuration, materials, or a combination thereof of layers of gate dielectrics 302 and/or gate electrodes 308 corresponding with a first p-type transistor region may be different than a number, configuration, materials, or a combination thereof of layers of gate dielectrics 302 and/or gate electrodes 308 corresponding with a second p-type transistor region. Gate stacks 320 may include numerous other layers, for example, capping layers, interface layers, diffusion layers, barrier layers, hard mask layers, or a combination thereof.

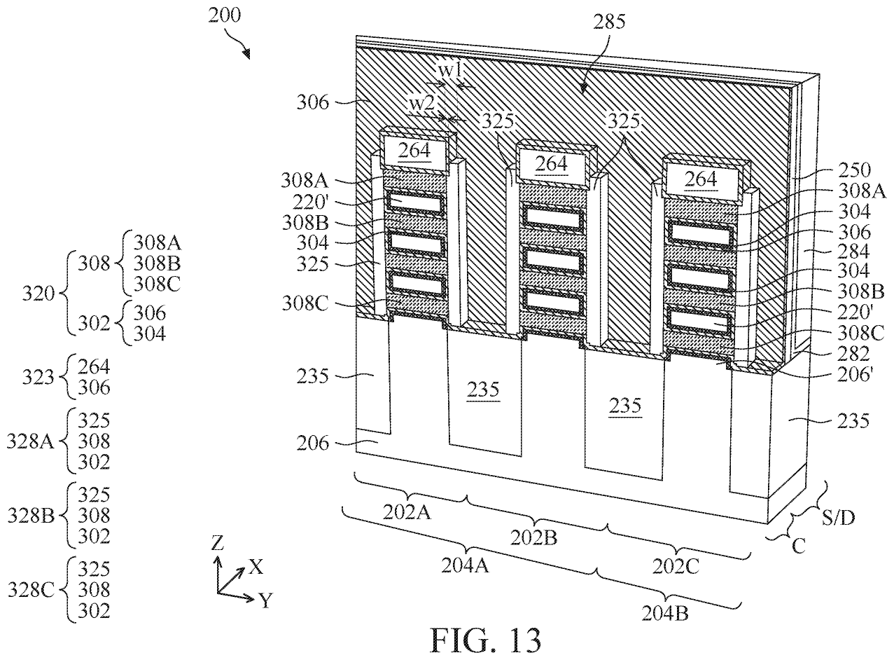

Turning to FIG. 13, gate endcaps 325 are formed in and partially fill gate opening 285. In such embodiments, a gate 328A is provided in transistor region 202A, a gate 328B is provided in transistor region 202B, and a gate 328C is provided in transistor region 202C. Each of gates 328A-328C includes a respective gate stack 320 (e.g., a respective gate dielectric 302 and a respective gate electrode 308) and respective gate endcaps 325 forming sidewalls thereof. Gates 328A-328C are also referred to as metal gates and/or high-k/metal gates.

In multigate device 200, gate endcaps 325 cover sidewalls 322 of gate stacks 320, which are formed by both high-k dielectric layer 306 and gate electrodes 308. For example, gate endcaps 325 are disposed on sidewalls of portions 308A-308C, and gate endcaps 325 physically and/or electrically connect one or more of portions 308A-308C. Gate endcaps 325 are disposed along sidewalls of channel layers 220′, and gate dielectric 302 is between channel layers 220′ and gate endcaps 325. Gate endcaps 325 may extend above gate electrodes 308 along the sidewalls of gate helmet structures 323, and gate endcaps 325 may wrap overhangs 324 of gate helmet structures 323. In the depicted embodiment, gate endcaps 325 extend along a bottom and sidewalls of gate helmets 264, such as portions forming overhangs 324 of gate helmet structures 323, and high-k dielectric layer 306 is between gate helmets 264 and gate endcaps 325. Gate endcaps 325 may extend below gate electrodes 308 along sidewalls of mesas 206′, such as depicted, and gate dielectric 302 may be between mesas 206′ and gate endcaps 325. In some embodiments, gate endcaps 325 do not extend above and/or below gate electrodes 308.

Gate endcaps 325 include tungsten, ruthenium, molybdenum, other electrically conductive material that may be selectively formed on gate electrodes 308, alloys thereof, or a combination thereof. For example, gate endcaps 325 are tungsten layers. In another example, gate endcaps 325 are ruthenium layers. In yet another example, gate endcaps 325 are molybdenum layers. Gate endcaps 325 have a width w1 (e.g., along the y-direction) along sidewalls 322 of gate stacks 320. In some embodiments, width w1 is about 4 nm to about 10 nm. Width w1 may be a total thickness of gate endcaps 325. In some embodiments, gate endcaps 325 have a width w2 (e.g., along the y-direction) along sidewalls of gate helmet structures 323. Width w2 is less than width w1. In some embodiments, a width of gate endcaps 325 along sidewalls of mesas 206′ is width w2. In some embodiments, a width of gate endcaps 325 along sidewalls of mesas 206′ is less than width w1 and different than width w2.

Gate endcaps 325 are formed by a selective deposition process, such as a deposition process that is configured to selectively grow gate endcap material from metal surfaces. The selective deposition process may limit (or prevent) growth of the gate endcap material from dielectric surfaces. For example, forming gate endcaps 325 includes performing selective CVD or selective ALD, where parameters of the selective CVD or selective ALD are tuned to selectively grow metal material (e.g., tungsten, ruthenium, molybdenum, or alloys thereof) from portions 308A-308C. The selective CVD or ALD may further be tuned to limit (or prevent) growth of metal material from high-k dielectric layer 306, gate spacers 250, and dielectric layer 280. In the depicted embodiment, the selective deposition process is performed until metal material grown from portions 308A-308C merges together to form gate endcaps 325 that extend continuously along sidewalls 322 of gate stacks 320, such that gate endcaps 325 connect portions 308A-308C between channel layers 220′. The deposition parameters may include deposition precursors (e.g., metal precursors and/or reactants), deposition precursor flow rates, deposition temperature, deposition time, deposition pressure, source power, radio frequency (RF) bias voltage, RF bias power, other suitable deposition parameters, or a combination thereof. In some embodiments, a carrier gas is used to deliver the metal precursors and/or reactants. In some embodiments, multiple CVD cycles or ALD cycles are performed to form gate endcaps 325. In some embodiments, the selective deposition process includes multiple deposition/etch cycles, each of which may include depositing and etching back a metal material.

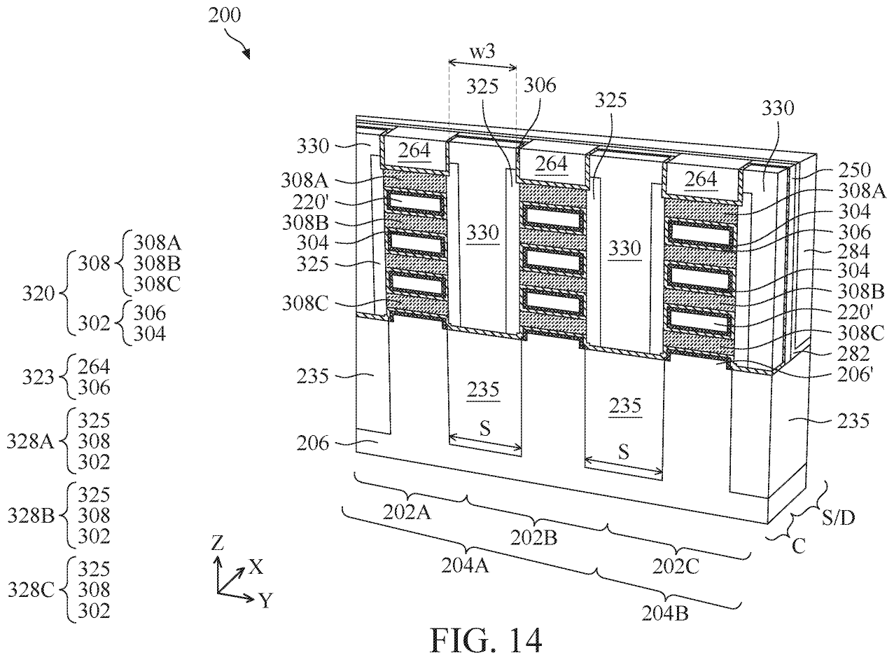

Turning to FIG. 14, processing includes a self-aligned metal gate isolation process (also referred to as a metal gate cut process), which includes forming gate isolation walls 330 that fill a remainder of gate opening 285. For example, gate isolation walls 330 fill spaces between gates 328A-328C, and each gate isolation wall 330 is disposed between gate endcaps 325 of adjacent gates 328A-328C. Gate isolation walls 330 may also fill spaces between gate helmets 264, such that each gate isolation wall 330 is disposed between adjacent gate helmet structures 323. In the depicted embodiment, high-k dielectric layer 306 is disposed between gate isolation walls 330 and gate helmets 264, and high-k dielectric layer 306 is disposed between gate isolation walls 330 and isolation features 235. Gate isolation walls 330 may electrically isolate gates 328A-328C from one another. For example, gate 328A in transistor region 202A is separated and electrically isolated from gate 328B in transistor region 202B by one of gate isolation walls 330, and gate 328B in transistor region 202B is separated and electrically isolated from gate 328C in transistor region 202C by another one of gate isolation walls 330. In some embodiments, gate 328A and gate 328C may further be isolated from other active regions, such as gates of adjacent transistor regions, by respective gate isolation walls 330.

Gate isolation walls 330 include a dielectric material that includes silicon, oxygen, carbon, nitrogen, other suitable dielectric constituent, or a combination thereof. For example, the gate isolation walls 330 include silicon nitride, silicon carbonitride, silicon oxycarbonitride, silicon oxycarbide, or a combination thereof. In the depicted embodiment, gate isolation walls 330 are silicon nitride walls. In some embodiments, where gate helmets 264 function as planarization stops during a planarization process, a composition of gate isolation walls 330 may be different than a composition of gate helmets 264. In the depicted embodiment, gate isolation walls 330 are formed of a single layer. In some embodiments, gate isolation walls 330 may have multilayer structures, such as a bulk dielectric over one or more dielectric liners.

Gate isolation walls 330 have a width w3 (e.g., along the y-direction). In some embodiments, width w3 is about 5 nm to about 100 nm. Gate isolation walls 330 may be formed by depositing a dielectric material (e.g., silicon nitride) over multigate device 200 that fills a remainder of gate opening 285 and performing a planarization process. The planarization process, such as CMP, is performed until reaching and exposing gate helmets 264, such that top surfaces of gate helmets 264 are free of high-k dielectric layer 306. In some embodiments, gate helmets 264 may function as a planarization stop layer. In some embodiments, the planarization process removes any of the dielectric material, high-k dielectric layer 306, ILD layer 284, CESL 282, gate spacers 250, or a combination thereof disposed above and/or over top surfaces of gate helmets 264, and remainders of the dielectric material form gate isolation walls 330. Because gates 328A-328C are fabricated to include etched back gate electrodes 308 and gate endcaps 325, gate isolation walls 330 may have T-shaped profiles, such as depicted. In such embodiments, a width of gate isolation walls 330 between gate helmet structures 323 is greater than a width of gate isolation walls 330 between gate endcaps 325. The dielectric material is formed by CVD, FCVD, HDPCVD, MOCVD, RPCVD, PECVD, APCVD, SAVCD, other suitable deposition process, or a combination thereof.

The metal gate cut process is referred to as “self-aligned” because gate isolation walls 330 are aligned between gates 328A-328C without having to perform a lithography process after forming gates 328A-328C. The self-aligned placement of gate isolation walls 330 provides electrical isolation between devices of adjacent active regions, such as transistors formed in transistor regions 202A-202C. The self-aligned placement of gate isolation walls 330 also allows for higher packing density without negatively impacting operation of closely spaced devices in a high-density IC. For example, a spacing S between active regions of transistor regions 202A-202C and/or active regions of device region 204A and device region 204B may be smaller than (e.g., about 5 nm to about 10 nm less than) spacings needed between adjacent active regions when implementing non-self-aligned metal gate cut techniques, such as those that use a lithography process to form gate isolation structures between gates. In some embodiments, spacing S is about 5 nm to about 100 nm. Smaller spacings between active regions are possible because the described self-aligned metal gate cut technique does not suffer from overlay issues associated with non-self-aligned metal gate cut techniques. Smaller spacings between active regions may thus be implemented without risking unintentional damage to channel layers 220′ and/or gates 328A-328C, such as damage that may arise from process variations inherent in non-self-aligned metal gate cut techniques. Different embodiments may have different advantages, and no particular advantage is necessarily required of any embodiment.

Turning to FIG. 15 and FIGS. 16A-16C, processing may include forming a dielectric layer 340 similar to dielectric layer 280 (e.g., a CESL and an ILD layer) over multigate device 200 and forming device-level contacts in dielectric layer 340. The device-level contacts may include metal-to-poly (MP) contacts, such as a gate contact 350A and a gate contact 350B, and metal-to-device (MD) contacts, such as source/drain contacts 355. Gate contact 350A is disposed on tops of gate stacks 320 (e.g., portions 308A and gate endcaps 325 thereof) of gate 328A and gate 328B, gate contact 350A is disposed between gate helmets 264 overlying gate 328A and gate 328B, and gate contact 350A is disposed on a top of gate isolation wall 330 between gate 328A and gate 328B. Gate contact 350B is disposed on top of gate stack 320 (e.g., portion 308A and gate endcap 325 thereof) of gate 328C, gate contact 350B is disposed adjacent to gate helmet 264 overlying gate 328C, and gate contact 350B is disposed on a top of gate isolation wall 330 between gate 328C and an adjacent device region and/or device feature. Gate contact 350A may physically and/or electrically connect gate 328A and gate 328B, and gate contact 350B may physically and/or electrically connect gate 328C and a gate of an adjacent transistor region. Source/drain contacts 355 are disposed on respective epitaxial source/drains 275B and between respective portions of CESL 382.

Gate contact 350A and gate contact 350B include tungsten, ruthenium, cobalt, copper, aluminum, iridium, palladium, platinum, nickel, low resistivity metal constituent, alloys thereof, or a combination thereof. In the depicted embodiment, gate contact 350A and gate contact 350B include tungsten, ruthenium, cobalt, alloys thereof, or a combination thereof. For example, gate contact 350A and/or gate contact 350B may be tungsten contacts, ruthenium contacts, or cobalt contacts. In some embodiments, gate contact 350A, gate contact 350B, and gate endcaps 325 include different materials. In some embodiments, gate contact 350A, gate contact 350B, and gate endcaps 325 include a same material. For example, gate endcaps 325 may be tungsten layers, and gate contact 350A and gate contact 350B may be tungsten contacts. In another example, gate endcaps 325 may be ruthenium layers, and gate contact 350A and gate contact 350B may be ruthenium contacts. In some embodiments, gate contact 350A and/or gate contact 350B are barrier-free. For example, gate contact 350A and/or gate contact 350B may have metal plugs that physically contact gate electrodes 308, gate endcaps 325, gate isolation walls 330, gate helmets 264, dielectric layer 340, other adjacent dielectric layers, or a combination thereof. In some embodiments, gate contact 350A and/or gate contact 350B include a metal plug disposed over a diffusion/barrier layer. The diffusion/barrier layer may include a material that promotes adhesion between the metal plug and adjacent dielectric material (e.g., dielectric layer 340, gate helmets 264, gate isolation walls 330, etc.) and/or a material that prevents diffusion of metal constituents from the metal plug into the adjacent dielectric material. In some embodiments, the diffusion/barrier layer includes tantalum, tantalum nitride, tantalum aluminum nitride, tantalum silicon nitride, tantalum carbide, titanium, titanium nitride, titanium silicon nitride, titanium aluminum nitride, titanium carbide, tungsten, tungsten nitride, tungsten carbide, molybdenum nitride, cobalt, cobalt nitride, ruthenium, palladium, other suitable material, or a combination thereof. In some embodiments, the diffusion/barrier layer may have a multilayer structure, such as a first sublayer and a second sublayer.

In some embodiments, forming gate contacts 350 may include forming a patterned mask layer over dielectric layer 340, where the patterned mask layer has a first opening and a second opening. The first opening overlaps a portion of gate 328A, a portion of gate 328B, and gate isolation wall 330 therebetween, and the second opening overlaps a portion of gate 328C and gate isolation wall 330 adjacent thereto. An etching process may be performed that uses the patterned mask layer as an etch mask to form a first gate contact opening and a second gate contact opening. The first gate contact opening exposes the portion of gate 328A, the portion of gate 328B, and gate isolation wall 330 therebetween, and the second gate contact opening exposes the portion of gate 328C and gate isolation wall 330 adjacent thereto. The etching process selectively removes dielectric material (e.g., dielectric layer 340, gate helmets 264, high-k dielectric layer 306, gate isolation walls 330, or a combination thereof) exposed by the first opening and the second opening of the patterned mask layer with negligible removal of metal materials (e.g., gate electrodes 308, gate endcaps 325, or a combination thereof). In some embodiments, the etching process is configured to stop upon reaching and/or exposing gate electrodes 308 and/or gate endcaps 325. The etching process is a dry etch, a wet etch, other suitable etch, or a combination thereof. One or more deposition processes (e.g., CVD, ALD, PVD, etc.) may then be performed to form a gate contact material (e.g., one or more electrically conductive layers) over dielectric layer 340 that fills the first gate contact opening and the second gate contact opening. A CMP and/or other planarization process may be performed to remove excess gate contact material, such as gate contact material over a top surface of dielectric layer 340. A remainder of contact material that fills the first gate contact opening and the second gate contact opening may provide gate contact 350A and gate contact 350B, respectively.

Source/drain contacts 355 may be formed in a manner similar to gate contact 350A and gate contact 350B. For example, forming source/drain contacts 355 may include forming a patterned mask layer over dielectric layer 340, where the patterned mask layer has openings that overlap epitaxial source/drains (e.g., epitaxial source/drains 275B); selectively removing dielectric material (e.g., dielectric layer 340 and/or dielectric layer 284) exposed by the openings of the patterned mask layer with negligible removal of semiconductor materials (e.g., epitaxial source/drains 275B) to form source/drain contact opening that expose epitaxial source/drains; depositing one or more source/drain contact materials over dielectric layer 340 that fill the source/drain contact openings; and performing a planarization process to remove excess source/drain contact material. In some embodiments, silicide layers are formed over epitaxial source/drains 275A-275C. For example, silicide layers are formed by depositing a metal layer in the source/drain contact openings over the epitaxial source/drains (e.g., epitaxial source/drains 275B) and heating multigate device 200 to cause constituents of epitaxial source/drains to react with metal constituents of the metal layer. In some embodiments, the silicide layers include a metal constituent (e.g., nickel, platinum, palladium, vanadium, titanium, cobalt, tantalum, ytterbium, zirconium, other suitable metal, or a combination thereof) and a constituent of epitaxial source/drains 275A-275C (e.g., silicon and/or germanium).

Dielectric layer 280, dielectric layer 340, MD contacts (e.g., source/drain contacts 355), and MP contacts (e.g., gate contact 350A and gate contact 350B) may form a portion of a multilayer interconnect (MLI) feature. The device-level contacts may electrically and/or physically connect electrically active regions of multigate device 200, such as gates 328A-328C and/or epitaxial source/drains 275A-275C, to metallization layers of the MLI feature. The MLI feature electrically couples various devices (for example, p-type transistors and/or n-type transistors, resistors, capacitors, inductors, or a combination thereof) and/or components (for example, gate electrodes and/or epitaxial source/drains), such that the various devices and/or components may operate as specified by design requirements. The MLI feature includes a combination of dielectric layers and electrically conductive layers (e.g., metal layers) that combine to form various interconnect structures. For example, the conductive layers form vertical interconnect features, such as device-level contacts and/or vias, and/or horizontal interconnect features, such as conductive lines. Vertical interconnect features may connect horizontal interconnect features in different levels (or different layers) of the MLI feature. During operation, the interconnect features route signals between the devices and/or the components of multigate device 200 and/or distribute signals (for example, clock signals, voltage signals, ground signals, etc.) to the devices and/or the components.

In some embodiments, dielectric layer 280 is a bottommost layer of the MLI feature (e.g., dielectric layer 280 is ILD0 and dielectric layer 340 is ILD1). Processing may continue with forming additional features of the MLI feature, such as metallization layers (levels) of the MLI feature, such as a first metallization layer (i.e., a metal one (M1) layer and a via zero (V1) layer), a second metallization layer (i.e., a metal two (M2) layer and a via one (V2) layer) . . . to a topmost metallization layer (i.e., a metal X (MX) layer and a via X (VX) layer, where X is a total number of metallization layers of the MLI feature) over the first metallization layer. Each of the metallization layers includes a patterned metal line layer and a patterned via layer configured to provide interconnect structures disposed in an insulator layer. The patterned metal line layer and the patterned metal via layer are formed by any suitable process, including by various dual damascene processes, and include any suitable materials and/or layers.

In FIG. 15 and FIGS. 16A-16C, multigate device 200 includes transistors. For example, a transistor in transistor region 202A includes respective channel layers 220′, epitaxial source/drains 275A, and gate 328A, a transistor in transistor region 202B includes respective channel layers 220′, epitaxial source/drains 275B, and gate 328B, and a transistor in transistor region 202C includes respective channel layers 220′, epitaxial source/drains 275C, and gate 328C. The transistors in transistor region 202A and transistor region 202B are electrically connected by gate contact 350A, which physically and/or electrically connects gate 328A and gate 328B. The transistor in transistor region 202C may be electrically connected to another transistor and/or device by gate contact 350B. Gate isolation walls 330 separate and isolate the transistors of transistor regions 202A-202C, such as gates 328A-328C thereof, and each of gates 328A-328C is disposed between respective gate isolation walls 330.

Each gate (e.g., gate 328B) is disposed between respective epitaxial source/drains (e.g., epitaxial source/drains 275B) along the x-direction, and inner spacers 262 are disposed between each gate and its respective epitaxial source/drains. Further, each gate (e.g., gate 328B) engages respective channel layers (e.g., channel layer 220′ in transistor region 202B), and the respective channel layers extend between respective epitaxial source/drains (e.g., epitaxial source/drains 275B) along the x-direction. Each gate (e.g., gate 328B) surrounds its respective channel layers. In the Y-Z plane, each gate has a gate dielectric (e.g., gate dielectric 302 of gate 328B) that surrounds its respective channel layers, a gate electrode (e.g., gate electrode 308 of gate 328B) disposed along tops and bottoms of its respective channel layers, and gate endcaps (e.g., gate endcaps 325 of gate 328B) along sidewalls of its respective channel layers, sidewalls of its respective gate electrode, and sidewalls of its respective gate dielectric. In the X-Z plane, each gate has a high-k dielectric layer of the gate dielectric (e.g., high-k dielectric layer 306 of gate 328B) that surrounds its respective gate electrode and an interfacial layer (e.g., interfacial layer 304 of gate 328B) disposed between the high-k dielectric layer and its respective channel layers. Further, each gate (e.g., gate 328B) has a gate helmet (e.g., gate helmet 264) disposed thereover, where the gate helmet is disposed over a top portion (e.g., portion 308A of gate 328B) of a respective gate electrode and between respective gate endcaps. A portion of its gate dielectric (e.g., high-k dielectric layer 306 of gate 328B) wraps a corner of the gate helmet, is disposed between the gate helmet and the top portion of the respective gate electrode, is disposed between the gate helmet and the respective gate endcap, and is disposed between the gate helmet and a respective gate isolation wall 330.

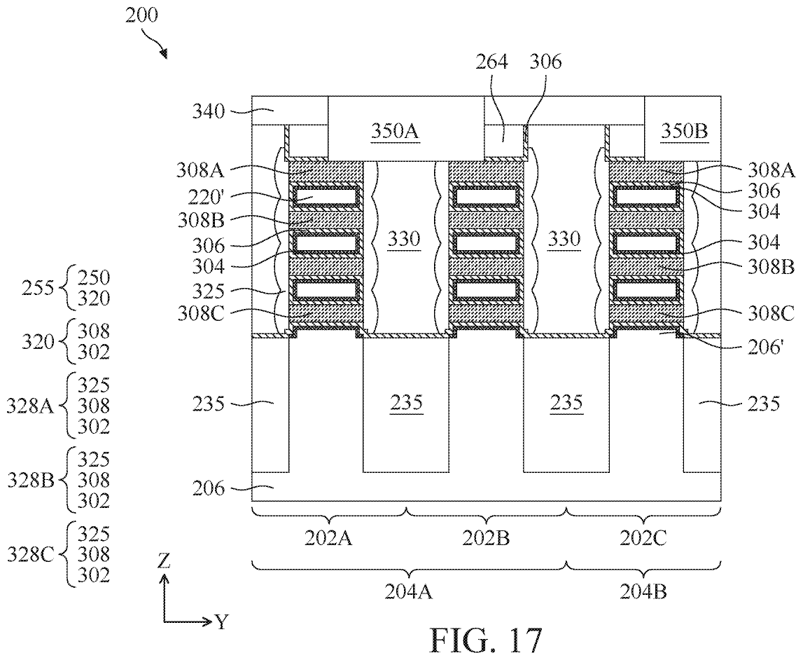

Each of gates 328A-328C has a sidewall S1 and a sidewall S2 formed by respective gate endcaps 325. In such embodiments, both sidewalls 322 of each gate stack 320 are separated from respective gate isolation walls 330 by respective gate endcaps 325. Gate contact 350A and gate contact 350B extend over sidewalls S1 of gates 328A-328C and physically contact gate endcaps 325, and each of gate isolation walls 330 is disposed between a respective pair of gate endcaps 325. In the depicted embodiment, sidewalls S1 and sidewalls S2 are substantially linear, and gate endcaps 325 have rectangular profiles/shapes. In some embodiments, such as depicted in FIG. 17, sidewalls S1 and sidewalls S2 are wavy, and gate endcaps 325 have scalloped profiles/shapes. In such embodiments, gate endcaps 325 have curved segments that interface with gate isolation walls 330. Different sidewall profiles, such as wavy sidewalls, may occur because of deposition/growth variations of selective deposition processes.

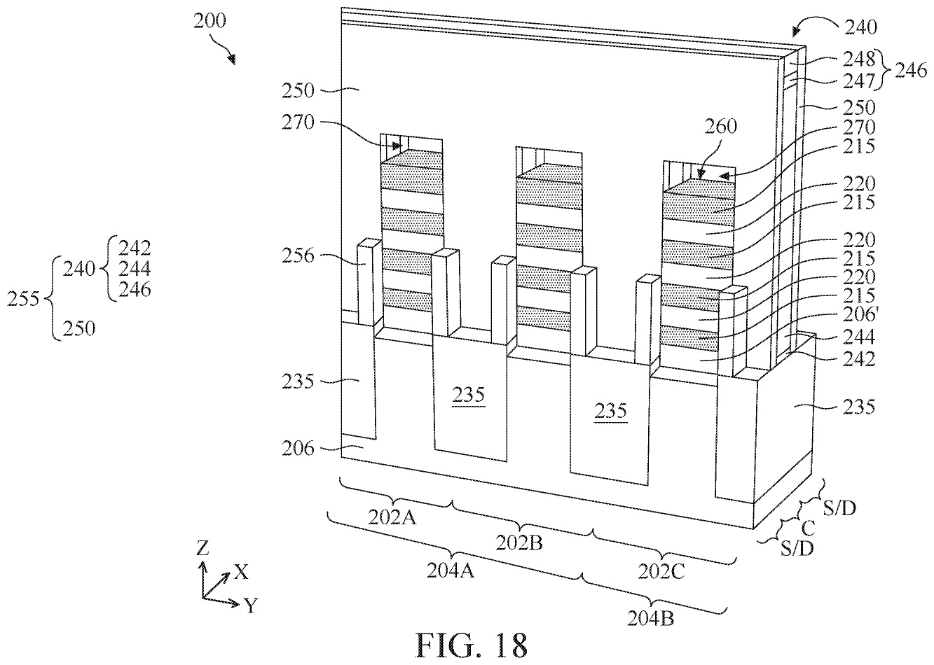

In FIGS. 2-15 and FIGS. 16A-16C, gate helmets 264 are formed at the same time as inner spacers 262. For example, gate helmets 264 and inner spacers 262 are formed by selectively etching semiconductor layers 225 and semiconductor layers 215 to form gaps 266, gaps 268, and gaps 270 (FIG. 5); depositing one or more dielectric layers to fill gaps 266, gaps 268, and gaps 270 (FIG. 6); and selectively etching the one or more dielectric layers, such that remainders of the one or more dielectric layers form gate helmets 264 and inner spacers 262 (FIG. 6). In some embodiments, gate helmets 264 may be formed before or after inner spacers 262. For example, instead of forming gate helmets 264 and inner spacers 262 as depicted and described with reference to FIG. 5 and FIG. 6, gate helmets 264 may be formed before inner spacers 262 as depicted and described with reference to FIGS. 18-21.

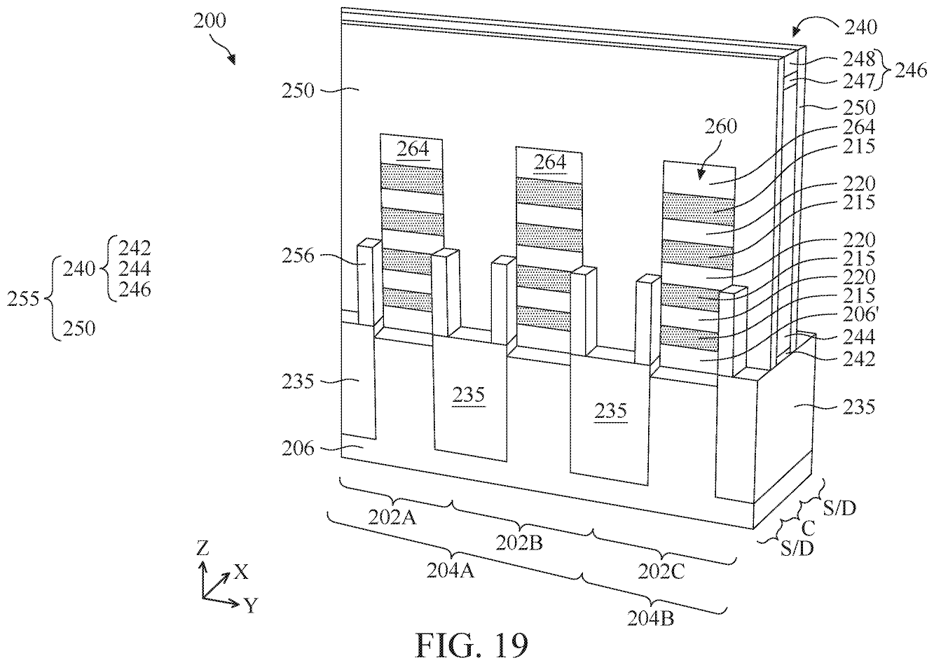

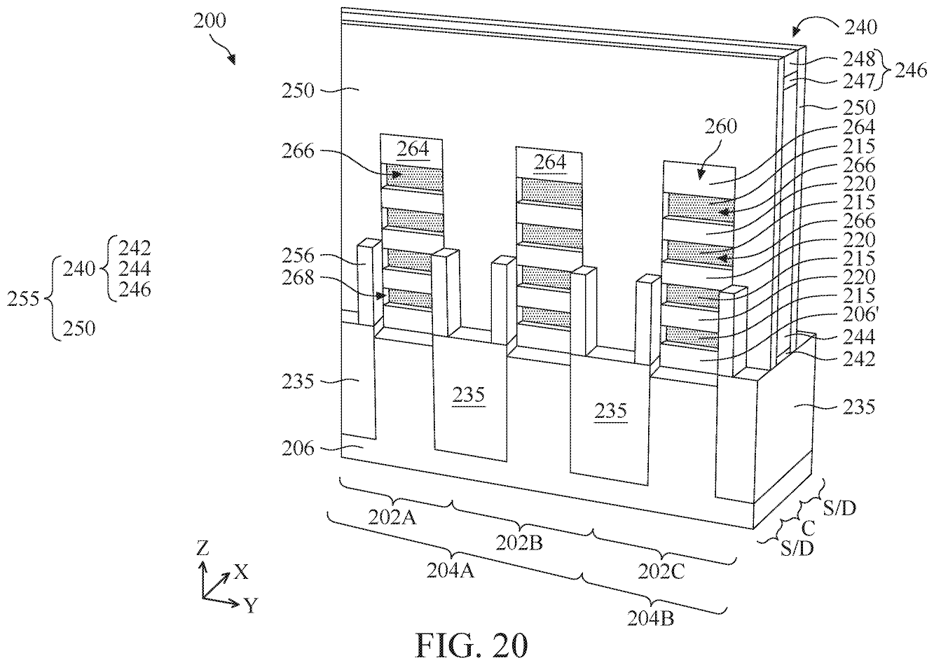

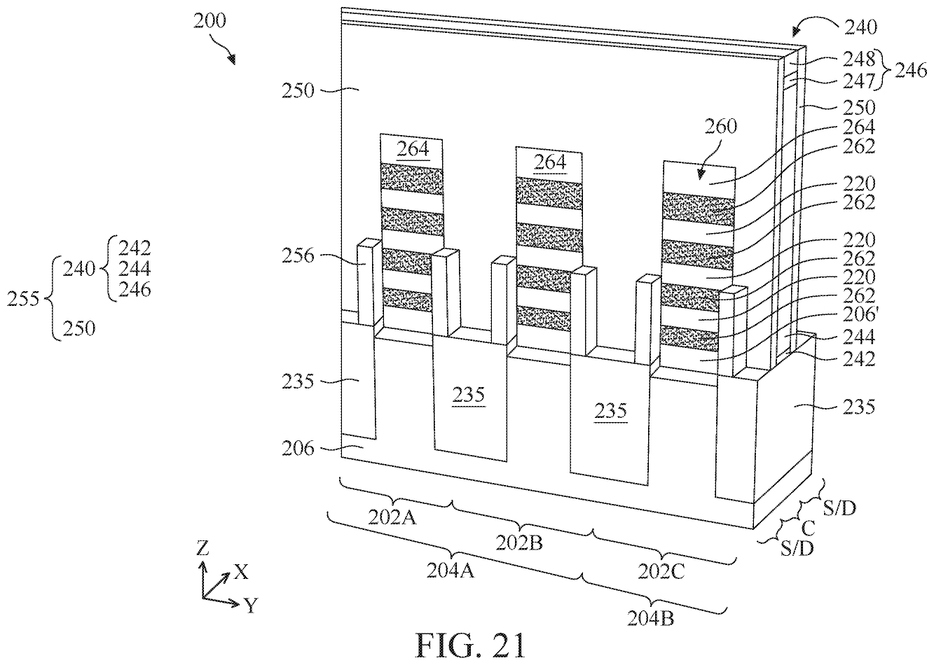

FIGS. 18-21 are fragmentary perspective views of multigate device 200 at various fabrication stages associated with forming gate helmets 264 and inner spacers 262 according to various aspects of the present disclosure. In such embodiments, multigate device 200 has undergone processing associated with FIGS. 2-4 (FIG. 18), multigate device 200 is processed to form gate helmets 264 (FIG. 18 and FIG. 19), multigate device 200 is processed to form inner spacers 262 (FIG. 20 and FIG. 21), and multigate device 200 may undergo processing associated with FIGS. 7-15 after forming gate helmets 264 and inner spacers 262. Processing may include selectively etching semiconductor layers 225 to form gaps 270 (FIG. 18); depositing one or more dielectric layers over multigate device 200 that fill gaps 270 (FIG. 19); and selectively etching the one or more dielectric layers, such that remainders of the one or more dielectric layers form gate helmets 264 (FIG. 19). Processing may then include selectively etching semiconductor layers 215 to form gaps 266 and gaps 268 (FIG. 20); depositing one or more dielectric layers over multigate device 200 that fill gaps 266 and gaps 268 (FIG. 21); and selectively etching the one or more dielectric layers, such that remainders of the one or more dielectric layers form inner spacers 262 (FIG. 21). In some embodiments, a composition of gate helmets 264 is different than a composition of inner spacers 262. In some embodiments, processing associated with FIG. 20 and FIG. 21 may be performed before processing associated with FIG. 18 and FIG. 19 to form gate helmets 264 after inner spacers 262. In such embodiments, multigate device 200 includes semiconductor layers 225 when forming inner spacers 262 and inner spacers 262 when forming gate helmets 264. FIGS. 18-21 have been simplified for the sake of clarity to better understand the inventive concepts of the present disclosure. Additional features may be added in multigate device 200 in FIGS. 18-21, and some of the features described below may be replaced, modified, or eliminated in other embodiments of multigate device 200 in FIGS. 18-21.

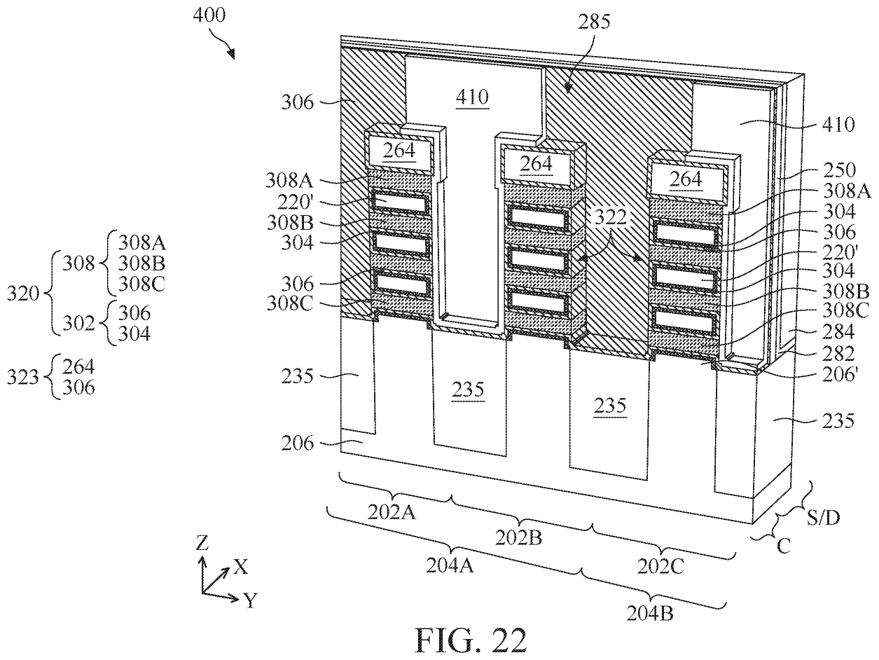

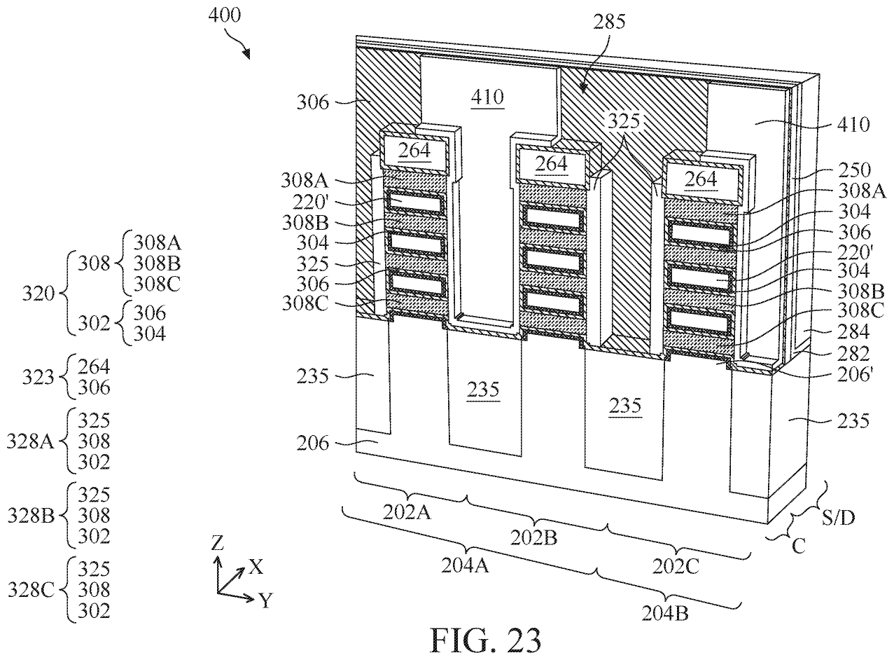

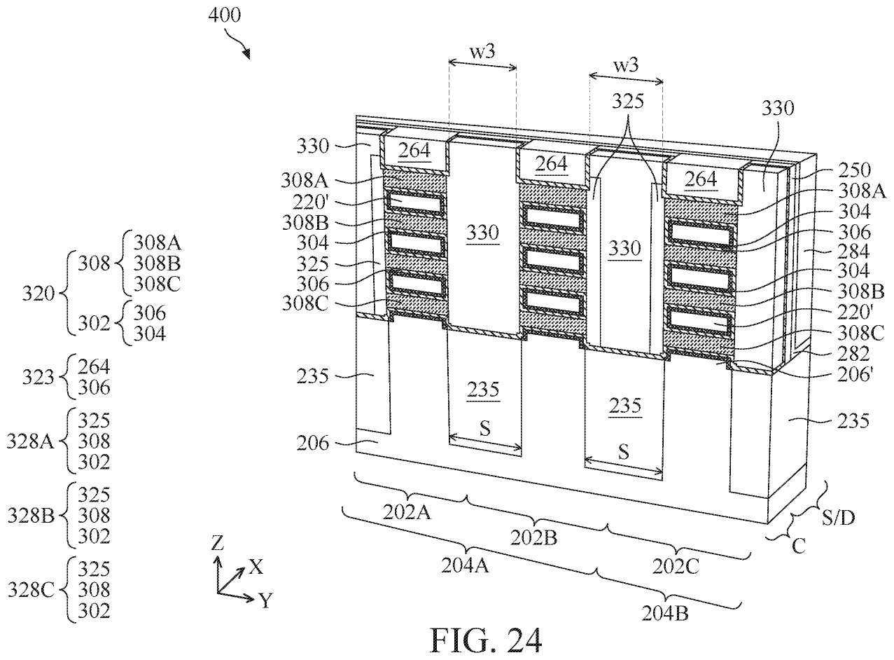

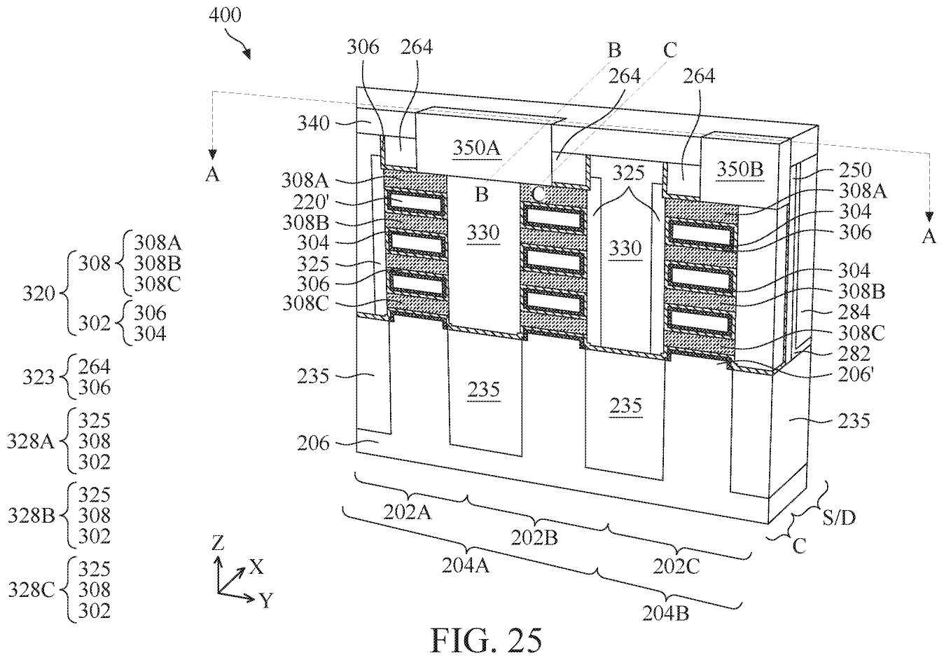

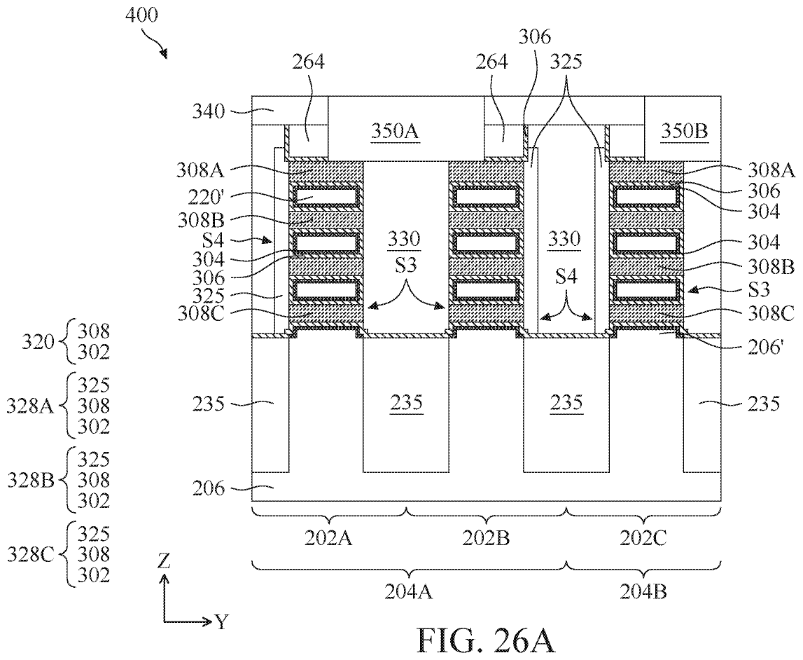

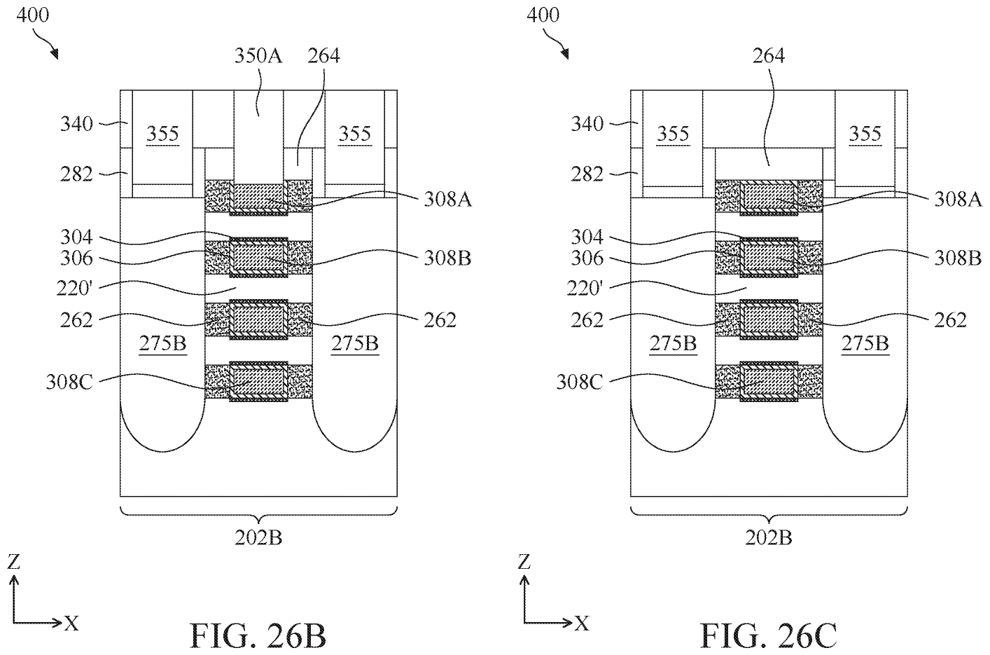

In FIGS. 2-15 and FIGS. 16A-16C, gate endcaps 325 form both sidewalls of gates 328A-328C in the y-cut view (e.g., in the Y-Z plane). In some embodiments, gate endcaps 325 may form one sidewall of gates 328A-328C in the y-cut view, instead of both, such as depicted and described with reference to FIGS. 22-25. FIGS. 22-25 are fragmentary perspective views of a multigate device 400 at various fabrication stages, such as those associated with method 100 of FIG. 1, according to various aspects of the present disclosure. FIG. 26A, FIG. 26B, and FIG. 26C are cross-sectional views of multigate device 400 along line A-A, line B-B, and line C-C, respectively, of FIG. 25 (e.g., a y-cut view and x-cut views), in portion or entirety, according to various aspects of the present disclosure. Fabrication of multigate device 400 is similar in many respects to fabrication of multigate device 200. For example, in FIG. 22, multigate device 400 has undergone processing associated with FIGS. 2-12 to form gate stacks 320 having sidewalls 322 in transistor regions 202A-202C. Gate stacks 320 are around respective channel layers 220′ and between respective ones of epitaxial source/drains 275A-275C. In FIGS. 22-25, instead of forming gate endcaps 325 on both sidewalls 322 of gate stacks 320, processing may include forming a patterned mask layer 829 over multigate device 400 that covers some sidewalls 322 while exposing other sidewalls 322 of gate stacks 320 (FIG. 22); forming gate endcaps 325 on exposed sidewalls 322 of gate stacks 320 (FIG. 23) in a manner similar to that described above with reference to FIG. 13 (e.g., allowing merger); selectively removing patterned mask layer 829 (FIG. 24) by any suitable process; forming gate isolation walls 330 between gates 328A-328C that fill a remainder of gate opening 285 (FIG. 24) in a manner similar to that described above with reference to FIG. 14, and forming gate contacts, such as gate contact 350A and gate contact 350B, to gates 328A-328C (FIG. 25) in a manner similar to that described above with reference to FIG. 15. FIGS. 22-25 and FIGS. 26A-26C have been simplified for the sake of clarity to better understand the inventive concepts of the present disclosure. Additional features may be added in multigate device 400, and some of the features described below may be replaced, modified, or eliminated in other embodiments of multigate device 400.

In FIG. 22, patterned mask layer 829 covers one sidewall 322 of each gate stack 320, such that each of gate stacks 320 has an exposed sidewall 322 on which a respective gate endcap 325 is selectively formed in FIG. 23. Accordingly, in FIG. 25 and FIGS. 26A-26C, each of gates 328A-328C has a sidewall S9 formed by its respective gate stack 320 and a sidewall S10 formed by a respective gate endcap 325. In such embodiments, one sidewall 322 of each gate stack 320 physically contacts a respective gate isolation wall 330, while another sidewall 322 of each gate stack 320 is separated from a respective gate isolation wall 330 by a respective gate endcap 325. In the depicted embodiment, sidewalls S10 are substantially linear, such as described with reference to FIG. 15 and FIGS. 16A-16C, and gate endcaps 325 have rectangular profiles/shapes. In some embodiments, sidewalls S10 are wavy, such as depicted and described with reference to FIG. 17, and gate endcaps 325 have scalloped profiles/shapes.

Further, in multigate device 400, gate contact 350A and gate contact 350B extend over sidewalls S9 of gates 328A-328C (i.e., sidewalls 322 of gate stacks 320 that physically contact gate isolation walls 330) and do not extend over and/or physically contact gate endcaps 325. Gate contact 350A is disposed on tops of gate electrodes 308 of gate 328A and gate 328B (e.g., portions 308A thereof), gate contact 350A is disposed on top of gate isolation wall 330 between gate 328A and gate 328B, gate contact 350A is disposed between gate helmets 264 overlying tops of gate electrodes 308 of gate 328A and gate 328B, and high-k dielectric layer 306 is disposed between gate helmets 264 and the tops of gate electrodes 308.

In some embodiments, processing is configured to form gate endcaps 325 on opposite sidewalls of gate stacks 320 than depicted, such that gate endcaps 325 are instead formed on sidewalls 322 of gate stacks 320 over which gate contact 350A and gate contact 350B extend. In such embodiments, gate contact 350A and gate contact 350B extend over and/or physically contact gate endcaps 325, gate isolation wall 330 between transistor region 202A and transistor region 202B is separated from sidewalls 322 of gate stacks 320 of gate 328A and gate 328B by gate endcaps 325, and gate isolation wall 330 between transistor region 202B and transistor region 202C physically contact sidewalls 322 of gate stacks 320 of gate 328B and gate 328C.

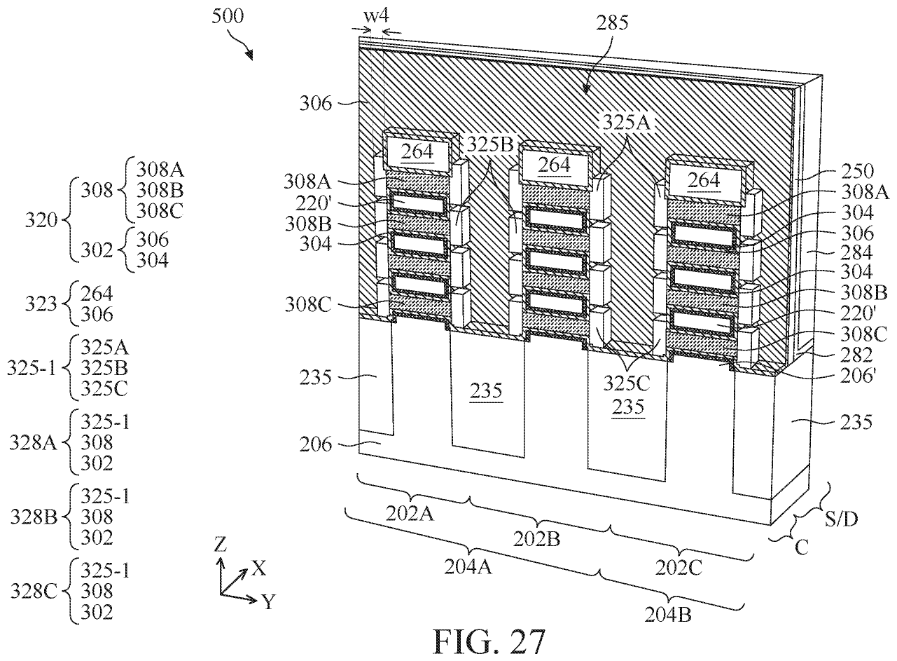

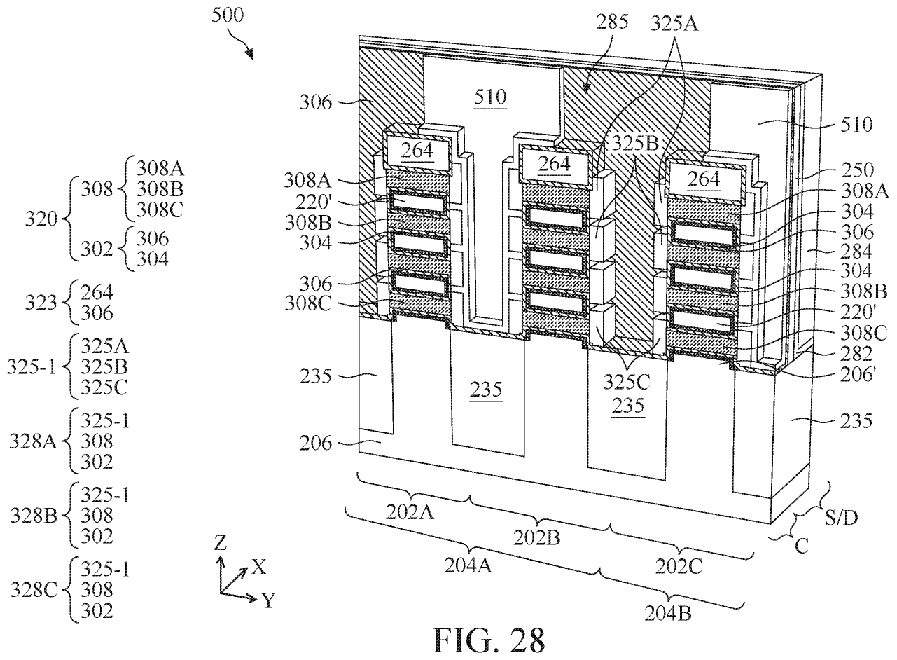

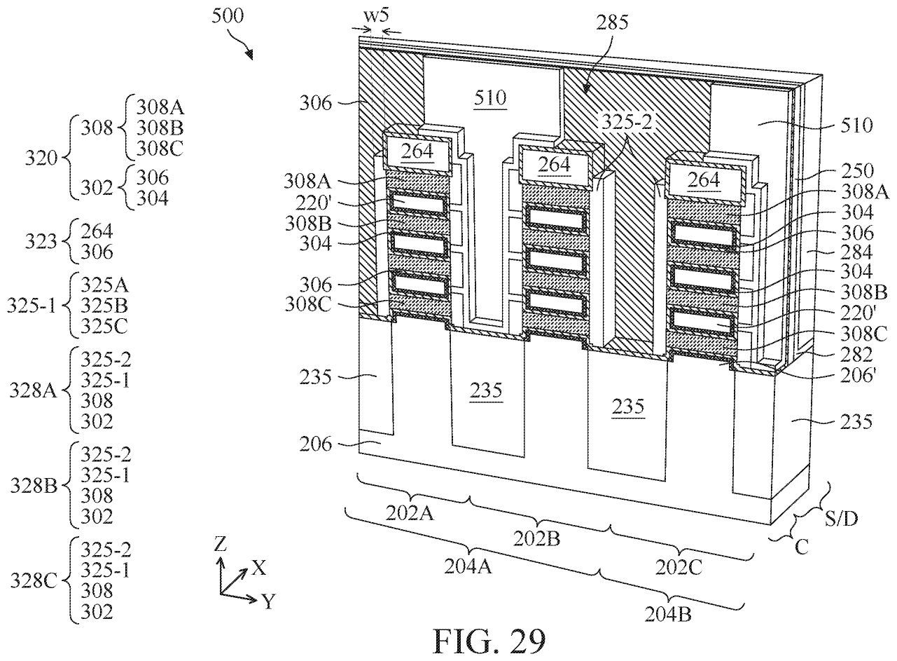

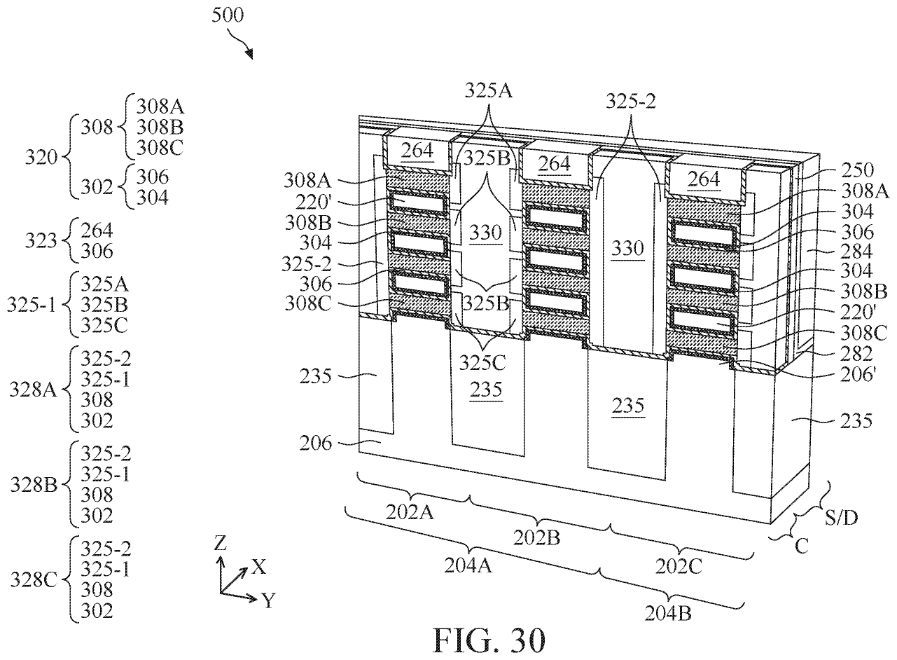

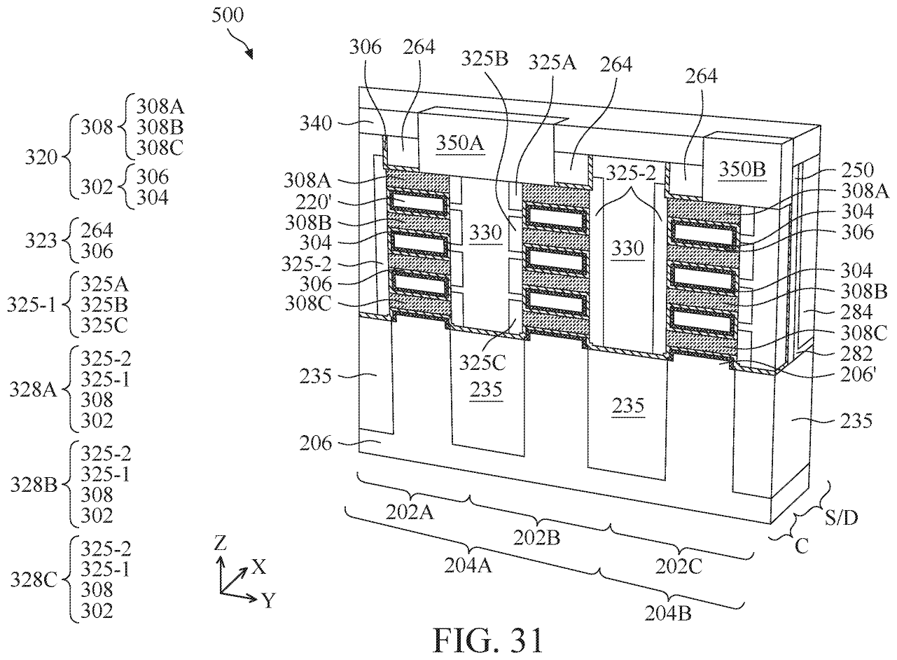

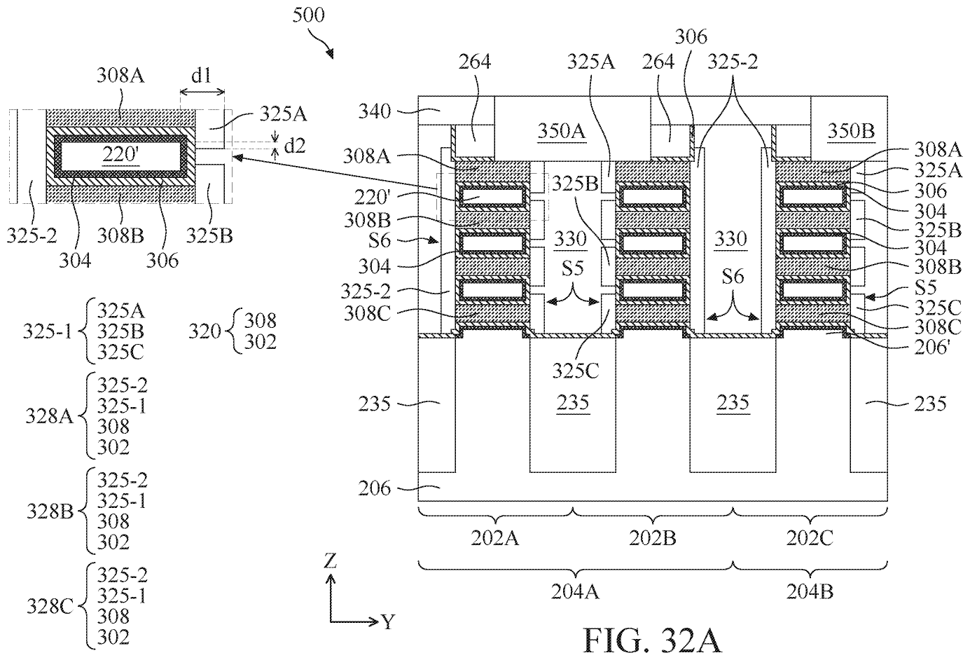

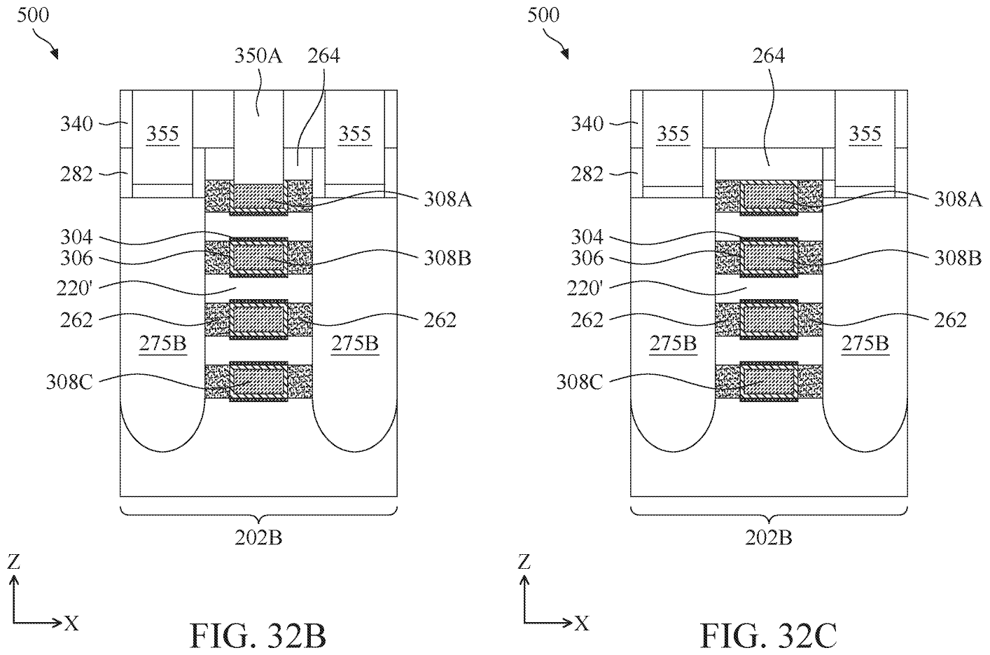

In FIGS. 2-15 and FIG. 16A-16C, gate endcaps 325 also extend continuously along sidewalls of gate stacks 320. In some embodiments, one or both of gate endcaps 325 may be segmented, such as depicted and described with reference to FIGS. 27-31. FIGS. 27-31 are fragmentary perspective views of a multigate device 500 at various fabrication stages, such as those associated with method 100 of FIG. 1, according to various aspects of the present disclosure. FIG. 32A, FIG. 32B, and FIG. 32C are cross-sectional views of multigate device 500 along line A-A, line B-B, and line C-C, respectively, of FIG. 31 (e.g., a y-cut view and x-cut views), in portion or entirety, according to various aspects of the present disclosure. Fabrication of multigate device 500 is similar in many respects to fabrication of multigate device 200. For example, in FIG. 27, multigate device 500 has undergone processing associated with FIGS. 2-12 to form gate stacks 320 having sidewalls 322 in transistor regions 202A-202C. Gate stacks 320 are around respective channel layers 220′ and between respective ones of epitaxial source/drains 275A-275C. In FIGS. 27-31, instead of forming gate endcaps 325 on both sidewalls 322 of gate stacks 320, multigate device 500 is processed to provide gates 328A-328C with segmented gate endcaps 325-1 and unsegmented gate endcaps 325-2. Processing may include performing a first selective deposition process to selectively form gate endcap segments 325A-325C (collectively referred to as segmented gate endcaps 325-1) on sidewalls 322 of gate stacks 320, such as on sidewalls of portions 308A-308C of gate electrodes 308 thereof (FIG. 27); forming a patterned mask layer 510 over multigate device 500 that covers some sidewalls 322 of gate stacks 320 and segmented gate endcaps 325-1 thereon, while exposing other sidewalls 322 of gate stacks 320 and segmented gate endcaps 325-1 thereon (FIG. 28); performing a second selective deposition process to merge exposed gate endcap segments 325A-325C to form unsegmented gate endcaps 325-2 on exposed sidewalls 322 of gate stacks 320 (FIG. 29); selectively removing patterned mask layer 510 (FIG. 30) by any suitable process; forming gate isolation walls 330 between gates 328A-328C that fill a remainder of gate opening 285 (FIG. 30) in a manner similar to that described above with reference to FIG. 14; and forming gate contacts, such as gate contact 350A and gate contact 350B, to gates 328A-328C (FIG. 31) in a manner similar to that described above with reference to FIG. 15. FIGS. 27-31 and FIGS. 32A-32C have been simplified for the sake of clarity to better understand the inventive concepts of the present disclosure. Additional features may be added in multigate device 500, and some of the features described below may be replaced, modified, or eliminated in other embodiments of multigate device 500.

In FIG. 27, the first selective deposition process (FIG. 27) is configured to selectively form and/or grow gate endcap material from metal surfaces. The first selective deposition process may limit (or prevent) formation and/or growth of the gate endcap material from dielectric surfaces, such as high-k dielectric layer 306, gate spacers 250, and dielectric layer 280. The first selective deposition process may be a selective CVD or selective ALD having parameters tuned to selectively form metal material (e.g., tungsten, ruthenium, molybdenum, alloys thereof, or a combination thereof) on sidewalls of portions 308A-308C. Parameters of the first selective deposition process may be tuned to cover sidewalls of portions 308A-308C with respective metal material portions without merger thereof, such that the respective material portions provide gate endcap segments 325A-325C having a width w4 (e.g., along the y-direction). In some embodiments, width w4 is about 4 nm to about 10 nm. In some embodiments, such as depicted, the first selective deposition process is performed until the respective metal material portions laterally extend over gate dielectric portions of sidewalls 322, such as portions formed by high-k dielectric layer 306. Top metal material portions (e.g., those formed on sidewalls of portions 308A) may laterally extend over sidewalls of gate helmet structures 323. Bottom metal material portions (e.g., those formed on sidewalls of portions 308C) may laterally extend over sidewalls of mesas 206′. In some embodiments, the respective metal material portions do not extend laterally over gate dielectric portions of sidewalls 322. In some embodiments, the respective metal material portions partially cover sidewalls of portions 308A-308C, instead of completely cover sidewalls of portions 308A-308C as depicted.

In FIG. 29, the second selective deposition process is configured to selectively form and/or grow gate endcap material from metal surfaces. The second selective deposition process may limit (or prevent) formation and/or growth of the gate endcap material from dielectric surfaces, such as high-k dielectric layer 306, gate spacers 250, and dielectric layer 280. The second selective deposition process may be a selective CVD or selective ALD having parameters tuned to selectively form metal material (e.g., tungsten, ruthenium, molybdenum, alloys thereof, or a combination thereof) over gate endcap segments 325A-325C. The second selective deposition process may be performed until the metal material formed on and/or grown from gate endcap segments 325A-325C merges together to form unsegmented gate endcaps 325-2, which extend continuously along sidewalls 322 of gate stacks 320. Gate endcaps 325-2 connect portions 308A-308C between channel layers 220′ on one side of gate stacks 320. Gate endcaps 325-2 have a width w5 (e.g., along the y-direction) that is greater than width w4. In some embodiments, width w5 is about 4 nm to about 10 nm. In some embodiments, an etch back process may be performed to reduce width w5, such that width w5 is about width w4.

In FIG. 28, patterned mask layer 510 covers one sidewall 322 (and gate endcap segments 325A-325C thereon) of each gate stack 320, such that each of gate stacks 320 has an exposed sidewall 322 and gate endcap segments 325A-325C thereon that may be merged during the second selective deposition process to form respective gate endcaps 325-2 in FIG. 29. Accordingly, in FIG. 31 and FIGS. 32A-32C, each of gates 328A-328C has a sidewall S5 and a sidewall S6. Sidewall S5 is formed by a respective segmented gate endcap 325-1 and its respective gate stack 320 (in particular, high-k dielectric layer 306 thereof). Sidewall S6 is formed by a respective unsegmented gate endcap 325-2. In such embodiments, gate dielectric portions of one sidewall 322 of each gate stack 320 (e.g., formed by its high-k dielectric layer 306) physically contact a respective gate isolation wall 330, while gate electrode portions of the one sidewall 322 of each gate stack 320 (e.g., formed by its gate electrode 308) are separated from the respective gate isolation wall 330 by respective segmented gate endcap 325-1. Further, the other sidewall 322 of each gate stack 320 is separated from a respective gate isolation wall 330 by respective gate endcap 325-2. In some embodiments, gate isolation walls 330 may fill spaces between gate endcap segments 325A-325C, such that portions of gate isolation walls 330 are between adjacent gate endcap segments 325A-325C. In the depicted embodiment, sidewalls S6 are substantially linear, such as described with reference to FIG. 15 and FIGS. 16A-16C, and gate endcaps 325-2 have rectangular profiles/shapes. Further, gate endcap segments 325A-325C have substantially linear sidewalls, such that gate endcap segments 325A-325C and/or gate endcaps 325-1 have rectangular profiles/shapes. In some embodiments, sidewalls S6 are wavy, such as depicted and described with reference to FIG. 17, and gate endcaps 325-2 have scalloped profiles/shapes. In some embodiments, gate endcap segments 325A-325C have curved sidewalls that interface with gate isolation walls 330, such that gate endcap segments 325A-325C and/or gate endcaps 325-1 have scalloped profiles/shapes.

In FIG. 31 and FIGS. 32A-32C, gates 328A-328C have pi-gate (Π-gate) portions formed by portions 308A-308C and gate endcap segments 325A-325C. For example, gate 328A has a Π-gate portion formed by its respective portion 308A and its respective gate endcap segment 325A. Π-gate portions formed by its respective portions 308B and its respective gate endcap segments 325B, and a Π-gate portion formed by its respective portion 308C and its respective gate endcap segment 325C. Gate endcap segments 325A-325C may laterally extend a distance d1 (e.g., along the y-direction) from sidewalls of channel layers 220′ and vertically extend a distance d2 (e.g., along the z-direction) to overlap sidewalls of channel layers 220′. Distance d1 is between sidewalls of channel layers 220′ and surfaces of gate endcap segments 325A-325C that form sidewalls S5 (and/or between sidewalls of channel layers 220′ and sidewalls of gate isolation walls 330). Distance d2 is between tops (or bottoms) of channel layers 220′ and ends of gate endcap segments 325A-325C. In some embodiments, distance d1 is about 1 nm to about 6 nm. In some embodiments, distance d2 is about 0.1 nm to about 2.5 nm. The first selective deposition process may be tuned to achieve desired lateral extension and/or desired vertical extension of Π-gate portions (in particular, gate endcap segments 325A-325C thereof) relative to channel layers 220′. Π-gate portions may improve short channel effect (SCE) control of transistors in transistor regions 202A-202C and/or of multigate device 400.

In FIG. 31 and FIGS. 32A-32C, gate contact 350A and gate contact 350B extend over sidewalls S5 of gates 328A-328C. In such embodiments, gate contact 350A and gate contact 350B extend over and/or physically contact gate endcaps 325-1 (in particular, gate endcap segments 325A thereof) on one sidewall of gate stacks 320. Gate contact 350A is disposed on tops of gate electrodes 308 of gate 328A and gate 328B (e.g., portions 308A thereof), gate contact 350A is disposed on top of gate isolation wall 330 between gate 328A and gate 328B, gate contact 350A is disposed between gate helmets 264 overlying tops of gate electrodes 308 of gate 328A and gate 328B, and high-k dielectric layer 306 is disposed between gate helmets 264 and the tops of gate electrodes 308. Gate contact 350B is disposed on top of gate electrode 308 of gate 328C (e.g., portion 308A thereof), gate contact 350B is disposed on top of gate isolation wall 330 between gate 328C and another device region/feature, gate contact 350B is disposed adjacent to gate helmet structure 323 (e.g., gate helmet 264 and high-k dielectric layer 306) overlying top of gate electrode 308 of gate 328C, and high-k dielectric layer 306 is disposed between gate helmet 264 and top of gate electrode 308 of gate 328C.

In some embodiments, processing is configured to form gate endcaps 325-1 and gate endcaps 325-2 on opposite sidewalls of gate stacks 320 than depicted, such that gate endcaps 325-2 are instead formed on sidewalls 322 of gate stacks 320 over which gate contact 350A and gate contact 350B extend. In such embodiments, gate contact 350A and gate contact 350B extend over and/or physically contact gate endcaps 325-2, gate isolation wall 330 between transistor region 220A and transistor region 220B is separated from sidewalls 322 of gate stacks 320 of gate 328A and gate 328B by gate endcaps 325-2, and gate isolation wall 330 between transistor region 220B and transistor region 220C physically contact gate dielectric portions of sidewalls 322 of gate stacks 320 of gate 328B and gate 328C. In some embodiments, gate endcap segments 325A are configured to partially cover sidewalls of portions 308A in a manner that provides a spacing between gate endcap segments 325A and gate contacts, such as gate contact 350A and/or gate contact 350B. In such embodiments, gate isolation walls 330 may fill the spacing between gate endcap segments 325A and the gate contacts.

Patterned mask layer 829 (FIG. 22) and patterned mask layer 510 (FIG. 28) include any suitable patterning material and are formed by any suitable process. In some embodiments, patterned mask layer 829 and/or patterned mask layer 510 may be formed by depositing a hard mask material (e.g., silicon nitride) over multigate device 400; forming a patterning layer over the hard mask material (e.g., by a lithography process and/or an etching process), where the patterning layer has openings therein that expose portions of the hard mask material; selectively removing exposed portions of the hard mask material; and selectively removing the patterning layer. Remaining portions of the hard mask material form a patterned hard mask layer (e.g., a patterned silicon nitride layer), such as patterned mask layer 829 and/or patterned mask layer 510. In some embodiments, a composition of patterned mask layer 829 and/or patterned mask layer 510 is configured to limit and/or prevent growth thereon during selective deposition processes used to form gate endcaps. In some embodiments, a composition of patterned mask layer 829 and/or patterned mask layer 510 is different than a composition of high-k dielectric layer 306 and a composition of gate endcaps (e.g., gate endcaps 325, gate endcaps 325-1, gate endcaps 325-2, etc.) to facilitate selective removal of patterned mask layer 829 and/or patterned mask layer 510 relative to high-k dielectric layer 306 and the gate endcaps. In other words, the compositions may be configured to ensure minimal to no removal of high-k dielectric layer 306 and/or the gate endcaps along when removing the patterned mask layer.

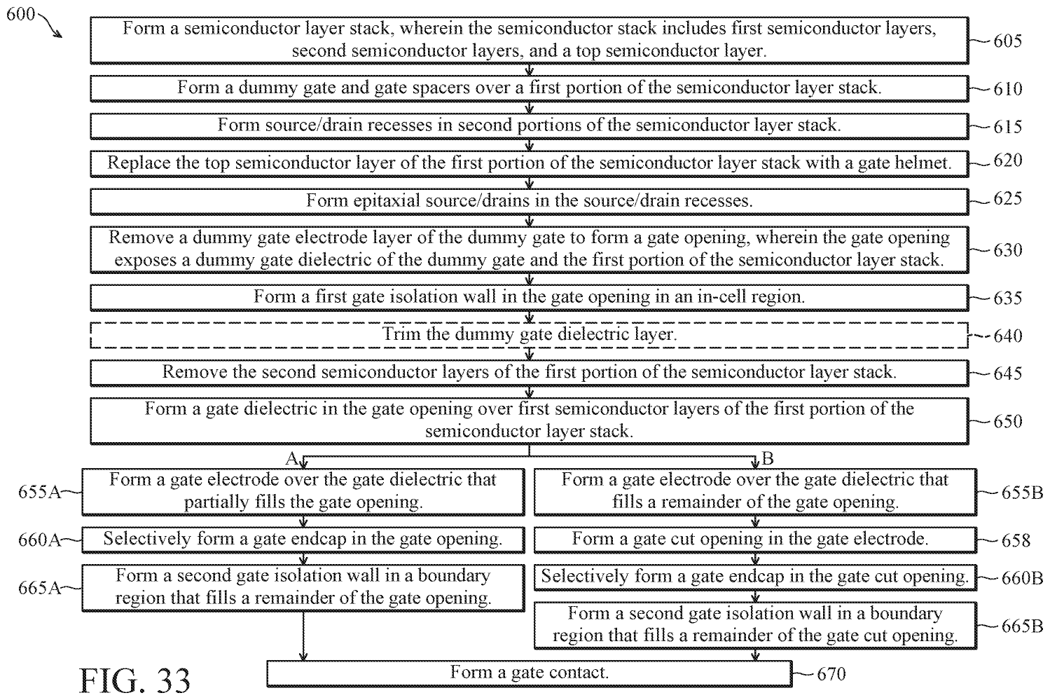

Turning to FIG. 33, FIG. 33 is a flow chart of a method 600 for fabricating a multigate device, in portion or entirety, according to various aspects of the present disclosure. At block 605, method 600 includes forming a semiconductor layer stack over a semiconductor substrate. The semiconductor layer stack has first semiconductor layers, second semiconductor layers, and a top semiconductor layer. The first semiconductor layers, the second semiconductor layers, and the top semiconductor layer have different compositions. At block 610, method 600 includes forming a dummy gate and gate spacers over a first portion of the semiconductor layer stack. The dummy gate may include a dummy gate electrode layer and a dummy gate dielectric layer. At block 615, method 600 includes forming source/drain recesses in second portions of the semiconductor layer stack. At block 620, method 600 includes replacing the top semiconductor layer of the first portion of the semiconductor layer stack with a gate helmet. In some embodiments, portions of the second semiconductor layers of the first portion of the semiconductor layer stack (e.g., portions underneath the gate spacers) may be replaced with inner spacers. The gate helmet may be formed before, after, or simultaneously with the inner spacers. At block 625, method 600 includes forming epitaxial source/drains in the source/drain recesses. In some embodiments, a dielectric layer (e.g., an interlayer dielectric layer and/or a contact etch stop layer) is formed after forming the epitaxial source/drains and before performing a gate replacement process (i.e., replacing the dummy gate with a metal gate) as described herein.

At block 630, method 600 includes removing the dummy gate electrode layer of the dummy gate, which may expose the dummy gate dielectric layer of the dummy gate and/or the first portion of the semiconductor layer stack. The gate opening may further expose the gate helmet and/or the inner spacers. At block 635, method 600 includes forming a first gate isolation wall in the gate opening in an in-cell region. The in-cell region may be between adjacent gates that will be electrically connected to one another, such as gates of a same device, a same device region, a same cell (e.g., a logic cell or a memory cell), or a combination thereof. The first gate isolation wall partially fills the gate opening. At block 640, method 600 includes optionally trimming the dummy gate dielectric layer. At block 645, method 600 includes removing the second semiconductor layers of the first portion of the semiconductor layer stack, thereby suspending the first semiconductor layers over the semiconductor substrate (e.g., a channel release process is performed at block 645). Removing the second semiconductor layers may further suspend the gate helmet over the first semiconductor layers. At block 650, method 600 includes forming a gate dielectric in the gate opening over the first semiconductor layers of the first portion of the semiconductor layer stack. The gate dielectric may surround the first semiconductor layers. The gate dielectric may further surround the gate helmet. The gate dielectric partially fills the gate opening. In some embodiments, the dummy gate dielectric layer and/or portions thereof (e.g., after trimming) may form a portion of the gate dielectric.

Method 600 then includes filling a remainder of the gate opening by a process A (which includes block 655A, block 660A, and block 665A) or a process B (which includes block 655B, block 658, block 660B, and block 665B). In process A, at block 655A, method 600 includes forming a gate electrode over the gate dielectric that partially fills the gate opening. Block 655A may include depositing a gate electrode layer that fills the remainder of the gate opening and then etching back the gate electrode layer, which reopens a portion of the gate opening. A gate stack that includes the gate dielectric and the gate electrode may surround the first semiconductor layers, and sidewalls of the gate stack may be formed by both the gate dielectric and the gate electrode. At block 660A, method 600 includes selectively forming a gate endcap in the gate opening. The gate endcap is formed on a sidewall of the gate stack, the gate endcap is disposed on the gate electrode, and the gate endcap may be disposed on the gate dielectric. The gate stack and the gate endcap form a first gate. At block 665A, method 600 includes forming a second gate isolation wall in a boundary region that fills a remainder of the gate opening. The boundary region may be between adjacent gates that will not be electrically connected to one another, such as gates of different devices, different device regions, different cells, or a combination thereof. The second gate isolation wall is between and may electrically isolate the first gate and a second gate. In some embodiments, the second gate isolation wall and the first gate isolation wall are configured differently (e.g., different number of layers and/or different materials). In some embodiments, the second gate isolation wall and the first gate isolation wall are configured the same (e.g., same number of layers and/or same materials).

In process B, at block 655B, method 600 includes forming a gate electrode over the gate dielectric that fills a remainder of the gate opening. Block 655B may include depositing a gate electrode layer that fills the remainder of the gate opening and performing a planarization process. A gate stack that includes the gate dielectric and the gate electrode may surround the first semiconductor layers, and sidewalls of the gate stack may be formed by both the gate dielectric and the gate electrode. At block 658, method 600 includes forming a gate cut opening in the gate electrode. The gate cute opening may be formed in a portion of the gate electrode that is disposed in the boundary region. At block 660B, method 600 includes selectively forming a gate endcap in the gate cut opening. The gate endcap is formed on a sidewall of the gate stack, the gate endcap is disposed on the gate electrode. The gate stack and the gate endcap form a first gate. At block 665B, method 600 includes forming a second gate isolation wall in the boundary region that fills a remainder of the gate cut opening. The second gate isolation wall is between and may electrically isolate the first gate and a second gate.

At block 670, method 600 includes forming a gate contact. The gate contact is disposed on the first gate (e.g., the gate electrode thereof). The gate contact may be disposed on the gate endcap. The gate contact may extend over the first gate isolation wall and connect the first gate to a third gate (e.g., a gate electrode thereof). Additional processing is contemplated by the present disclosure. Additional steps may be provided before, during, and after method 600, and some of the steps described may be moved, replaced, or eliminated for additional embodiments of method 600. The discussion that follows illustrates various embodiments of multigate-based integrated circuit devices that may be fabricated according to method 600.

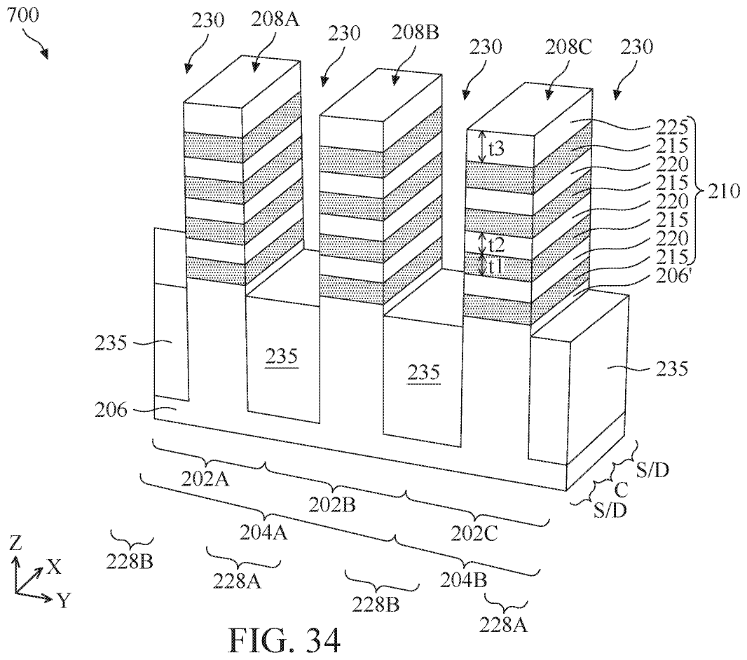

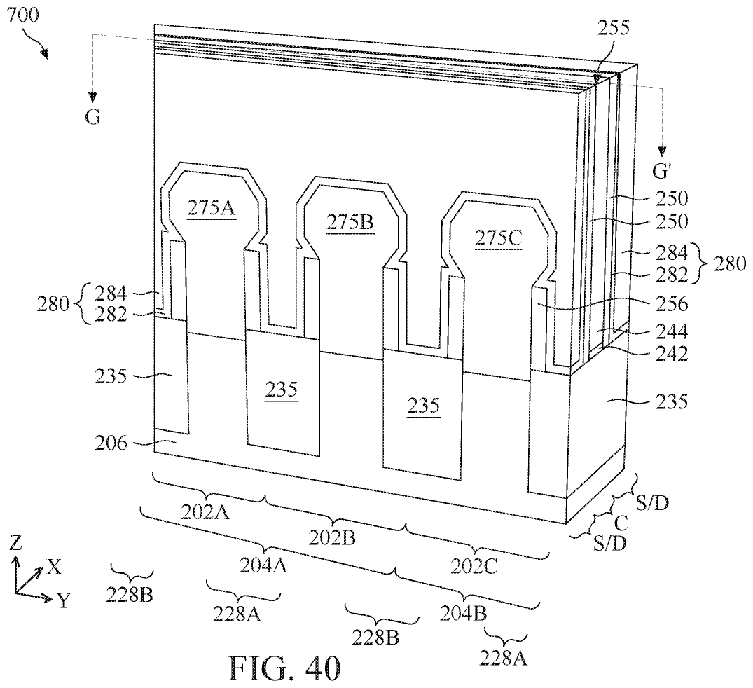

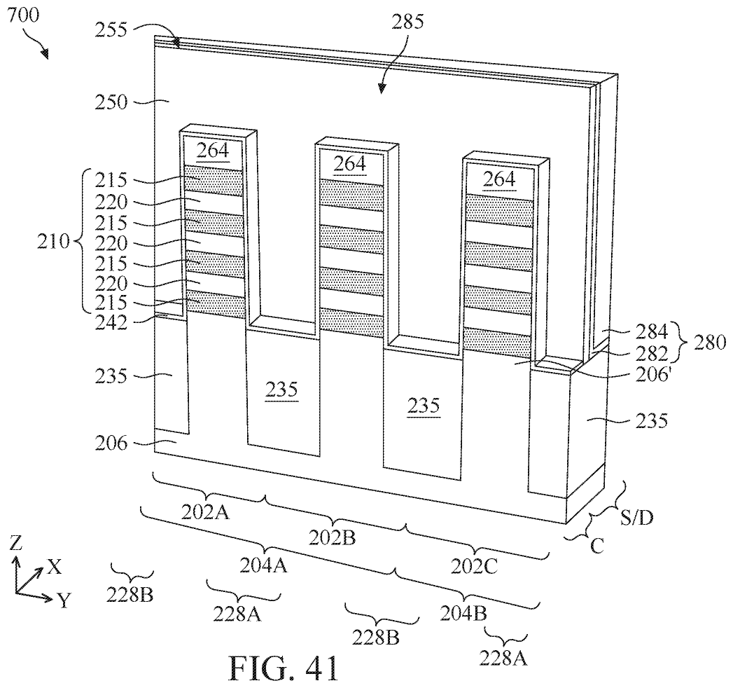

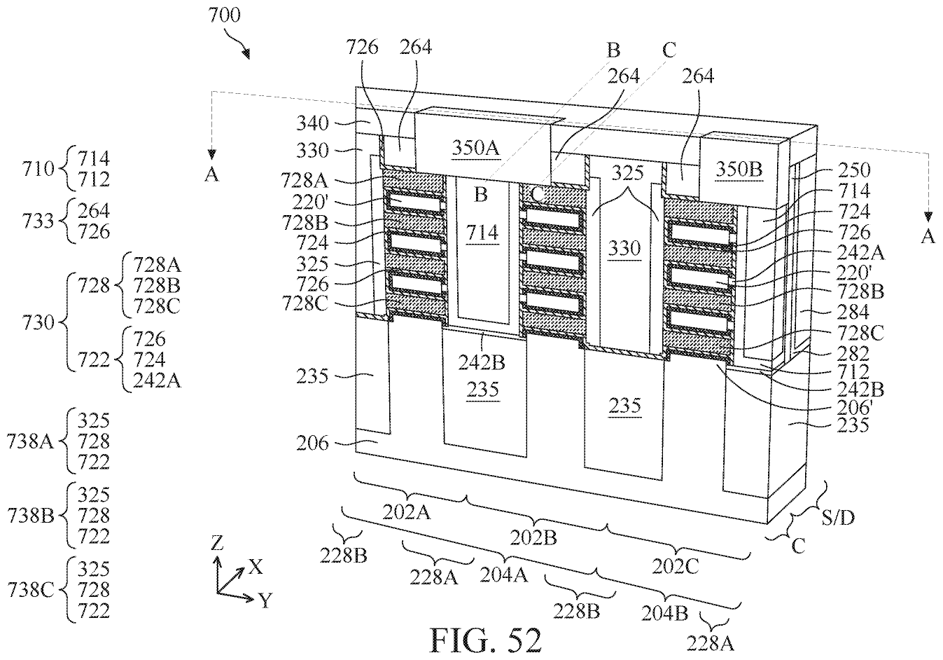

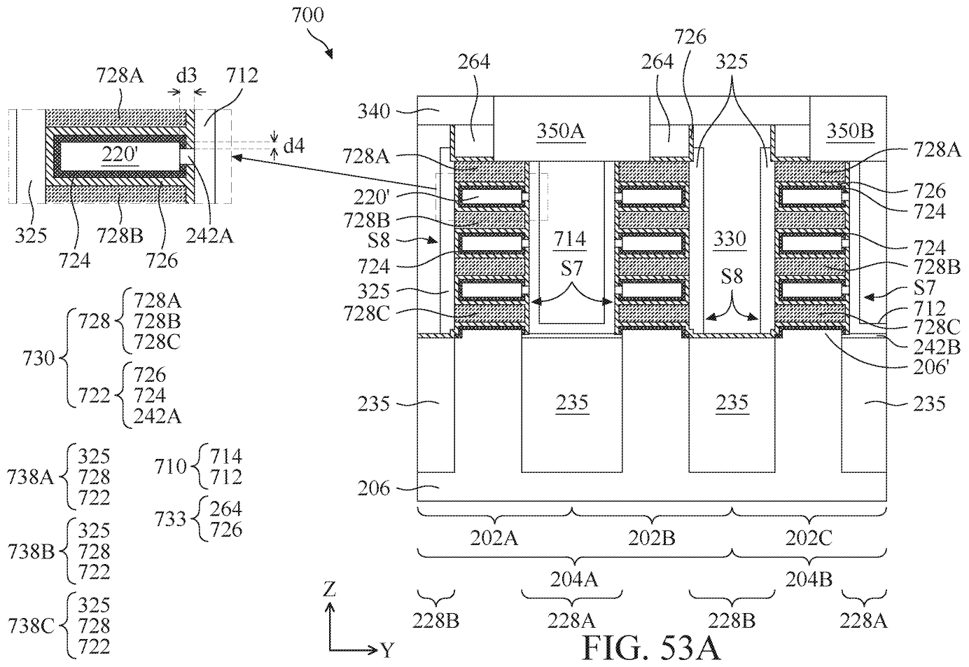

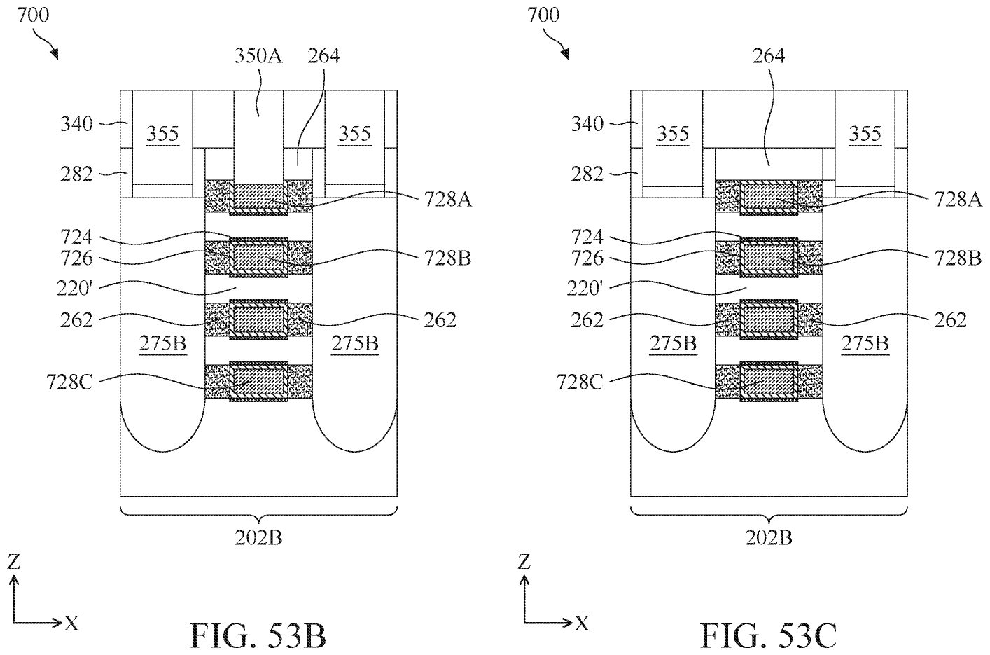

FIGS. 34-52 are perspective views of a multigate device 700, in portion or entirety, at various fabrication stages, such as those associated with method 600 in FIG. 33, according to various aspects of the present disclosure. For ease of description and understanding, FIGS. 41-52 are taken (cut) through a gate structure of multigate device 700 along line G-G′ in FIG. 40 (and are thus referred to as gate cut perspective views). FIG. 53A, FIG. 53B, and FIG. 53C are cross-sectional views of multigate device 700 along line A-A, line B-B, and line C-C, respectively, of FIG. 52 (e.g., a y-cut view and x-cut views), in portion or entirety, according to various aspects of the present disclosure. FIGS. 34-52 and FIGS. 53A-53C have been simplified for the sake of clarity to better understand the inventive concepts of the present disclosure. Further, device 700 and method 600 of fabrication thereof is similar in some respects to device 200 and method 100 of fabrication thereof, such as described above with reference to FIG. 1, FIGS. 2-20, and FIGS. 21A-21C. Accordingly, similar features in FIGS. 34-52 and FIGS. 2-20 are identified by the same reference numerals for clarity and simplicity. Additional features may be added in multigate device 700, and some of the features described below may be replaced, modified, or eliminated in other embodiments of multigate device 700.

As described herein, in FIGS. 34-52, multigate device 700 may be processed to form a first transistor in transistor region 202A, a second transistor in transistor region 202B, and a third transistor in transistor region 202C. In some embodiments, the first transistor, the second transistor, the third transistor, or a combination thereof is an n-type transistor. In some embodiments, the first transistor, the second transistor, the third transistor, or a combination thereof is a p-type transistor. In some embodiments, multigate device 700 has device region 204A, which includes transistor region 202A and transistor region 202B, and device region 204B, which includes transistor region 202C. In some embodiments, transistor regions 202A-202C are processed to provide a first multigate device and a second multigate device in device region 204A and device region 204B, respectively. In some embodiments, the first multigate device includes an n-type transistor (e.g., formed in transistor region 202A) and a p-type transistor (formed in transistor region 202B) and the second multigate device includes an n-type transistor (formed in transistor region 202C) and a p-type transistor (formed in a transistor region adjacent to transistor region 202C), such that device region 204A and device region 204B each include a complementary metal-oxide semiconductor (CMOS) transistor.

Turning to FIG. 34, a fin fabrication process is performed to form fins extending from a substrate, such as fin 208A, fin 208B, and fin 208C extending from substrate 206, such as described above with reference to FIG. 2. Fins 208A-208C each include a semiconductor layer stack portion (e.g., semiconductor layers 215, semiconductor layers 220, and semiconductor layer 225) disposed over a substrate portion (e.g., mesa 206′). In multigate device 700, as described further below, the first transistor region in transistor region 202A is electrically connected to the second transistor in transistor region 202B (e.g., gates thereof are connected), and the third transistor in transistor region 202C is not electrically connected to the first transistor or the second transistor. In such embodiments, the first transistor and the second transistor may form a portion of a device in device region 204A, and the third transistor may form a portion of a device in device region 204B. Multigate device 700 further includes in-cell regions 228A, which are regions between adjacent interconnected devices, and boundary regions 228B, which are regions between adjacent unconnected devices. In the depicted embodiment, the first transistor, the second transistor, and the third transistor are each between a respective in-cell region 228A and a respective boundary region 228B. In some embodiments, where a respective in-cell region 228A is between the third transistor and a fourth transistor in an adjacent transistor region and a respective boundary region 228B is between the first transistor and a fifth transistor in an adjacent transistor region, the third transistor may be electrically connected to the fourth transistor, while the first transistor may not be electrically connected to the fifth transistor. In some embodiments, the fourth transistor and its corresponding transistor region may form a portion the device in device region 204B.

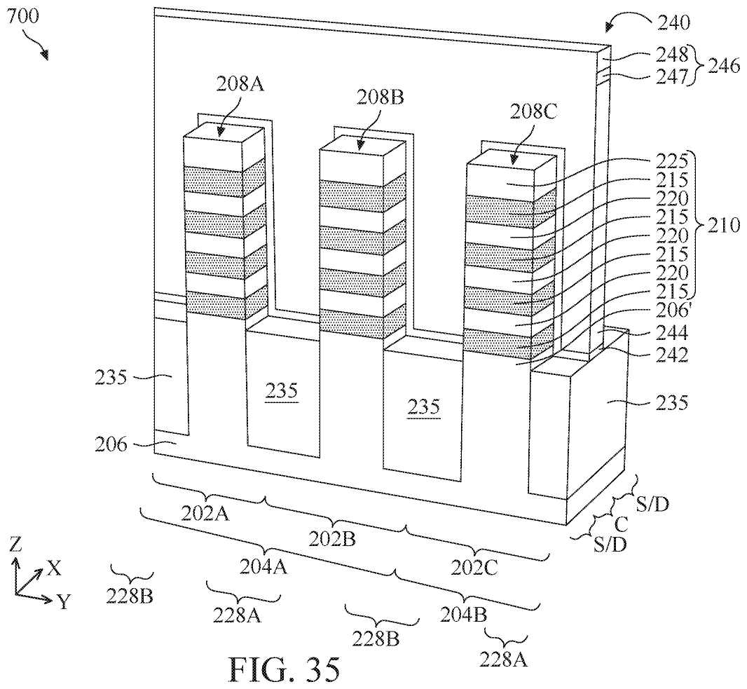

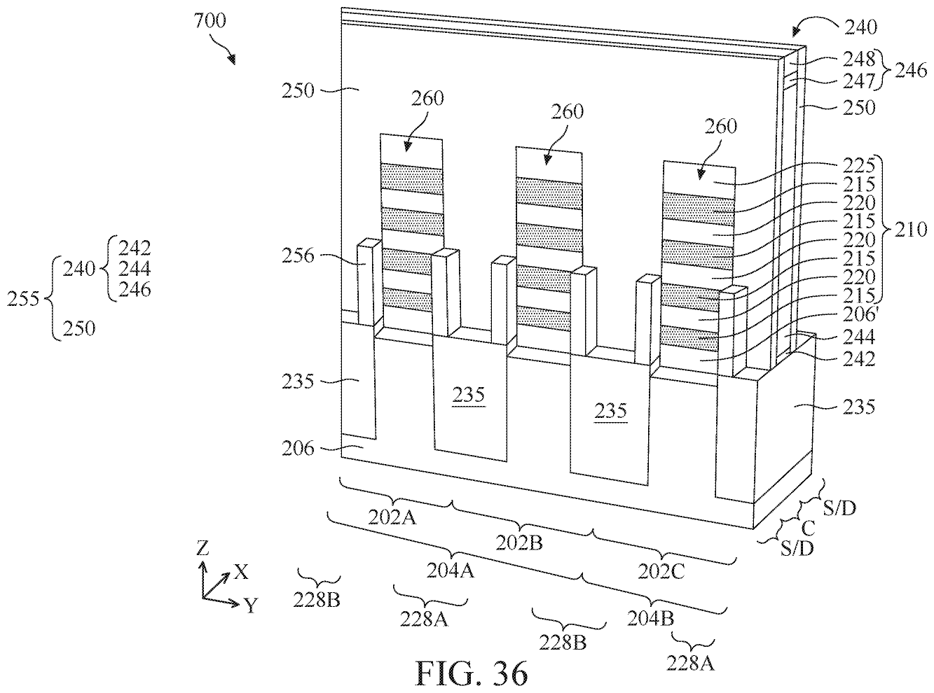

Turning to FIG. 35, dummy gate stack 240 is formed over portions of fins 208A-208C, such as described above with reference to FIG. 3. Dummy gate stack 240 includes dummy gate dielectric 242, dummy gate electrode 244, and hard mask 246 (including, for example, first mask layer 247 and second mask layer 248). Turning to FIG. 36, gate spacers 250 are formed along sidewalls of dummy gate stack 240, thereby forming gate structure 255, fin spacers 256 are formed along sidewalls of source/drain regions of fins 208A-208C, and portions of fins 208A-208C (i.e., source/drain regions thereof) are at least partially removed to form source/drain recesses (trenches) 260, such as described above with reference to FIG. 4.

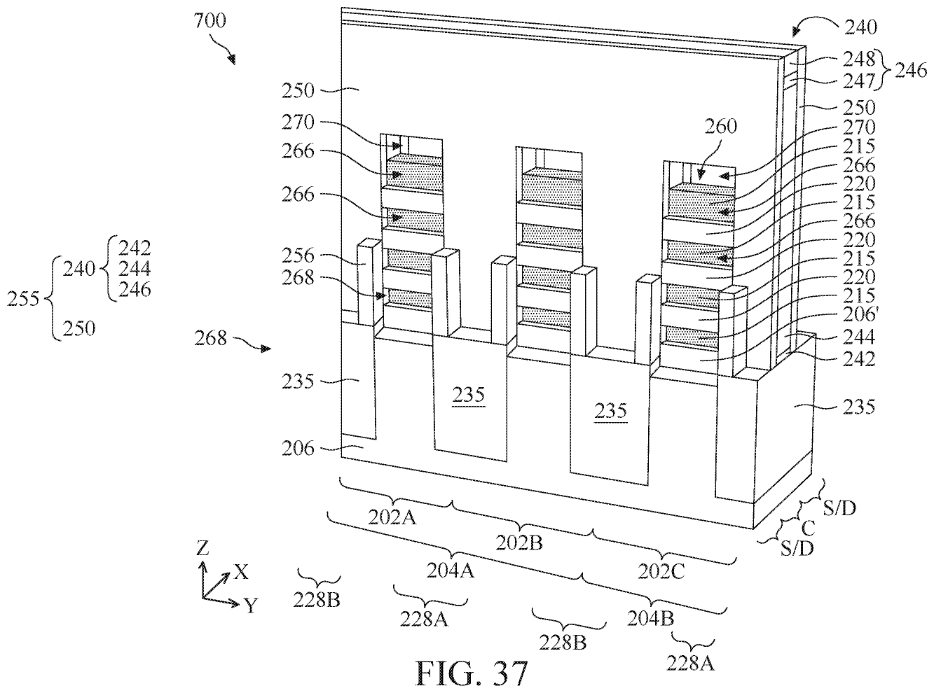

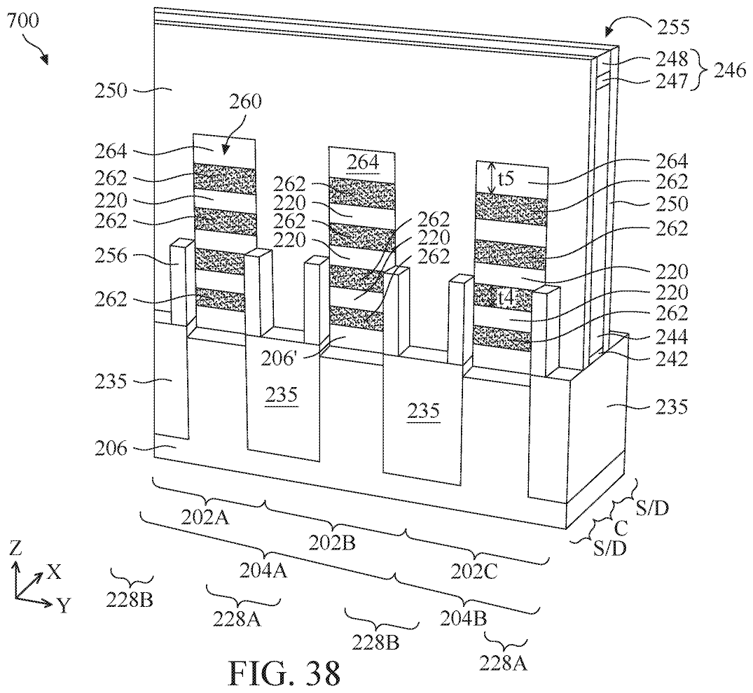

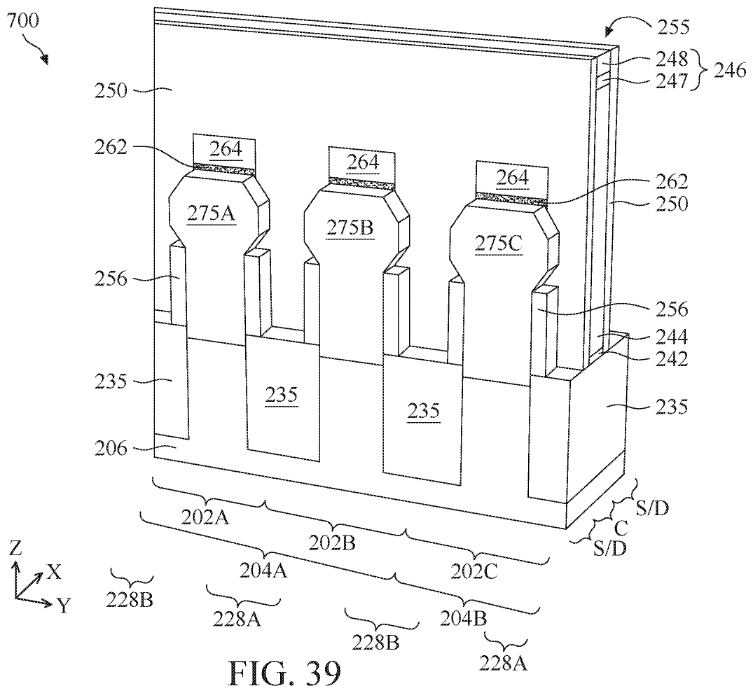

Turning to FIG. 37 and FIG. 38, processing includes forming inner spacers 262 under gate spacers 250 along sidewalls of semiconductor layers 215 and forming gate helmets 264 under gate structure 255, such as described above with reference to FIG. 5 and FIG. 6. Turning to FIG. 39, epitaxial source/drains 275A-275C are formed in source/drain recesses 260, such as described above with reference to FIG. 7. Turning to FIG. 40, dielectric layer 280 (e.g., including CESL 282 and ILD layer 284) is formed over multigate device 700, such as described above with reference to FIG. 8. Turning to FIGS. 41-51, a gate replacement process is performed to replace dummy gate stack 240 with gates in transistor regions 202A-202C and a channel release process is performed to form suspended channel layers in channel regions of transistor regions 202A-202C. The gates at least partially surround the suspended channel layers. For case of description and understanding, FIGS. 41-51 are taken (cut) through gate structure 255 along line G-G′ in FIG. 40 (and are thus referred to as gate cut perspective views). Referring to FIG. 41, a gate opening 285 is formed in gate structure 255 by removing dummy gate electrode 244, such as described above with reference to FIG. 9.

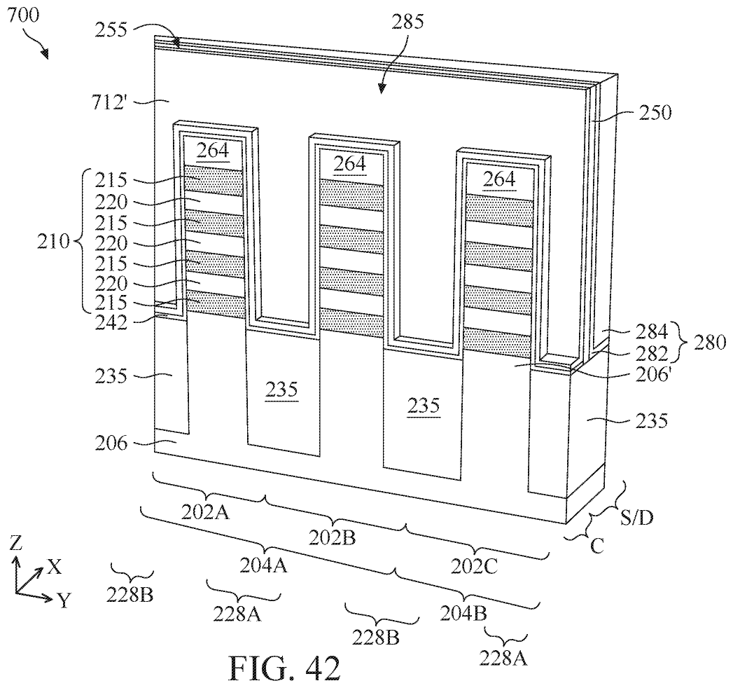

Referring to FIGS. 42-45, gate isolation walls 710 are formed in in-cell regions 228A over isolation features 235. Each gate isolation wall 710 includes an isolation liner 712 and a bulk isolation layer 714, and bulk isolation layer 714 is disposed over isolation liner 712. In FIG. 42, an isolation layer 712′ is formed over multigate device 700 and partially fills gate opening 285. Isolation layer 712′ covers dummy gate dielectric 242 and gate spacers 250. In in-cell regions 228A and boundary regions 228B, portions of isolation layer 712′ along sidewalls of fins 208A-208C form sidewalls of gate isolation walls 710, and portions of isolation layer 712′ along tops of isolation features 235 form bottoms of gate isolation walls 710. In some embodiments, an ALD process forms isolation layer 712′. In some embodiments, isolation layer 712′ has a substantially uniform thickness over various surfaces of multigate device 700. In some embodiments, isolation layer 712′ is formed by CVD, PVD, HDPCVD, MOCVD, RPCVD, PECVD, LPCVD, APCVD, SAVCD, other suitable methods, or a combination thereof. In the depicted embodiment, isolation layer 712′ includes a nitrogen-comprising dielectric material, such as a dielectric material that includes nitrogen in combination with silicon, carbon, oxygen, or a combination thereof. For example, isolation layer 712′ includes silicon nitride (SiN), silicon oxynitride (SiON), silicon carbonitride (SiCN), silicon oxycarbonitride (SiOCN), or a combination thereof. In some embodiments, isolation layer 712′ includes a carbon-comprising dielectric material, such as a dielectric material that includes carbon in combination with silicon, nitrogen, oxygen, or a combination thereof. For example, isolation layer 712′ includes silicon carbide (SiC), silicon oxycarbide (SiOC), or a combination thereof. In some embodiments, isolation layer 712′ includes n-type dopants and/or p-type dopants.

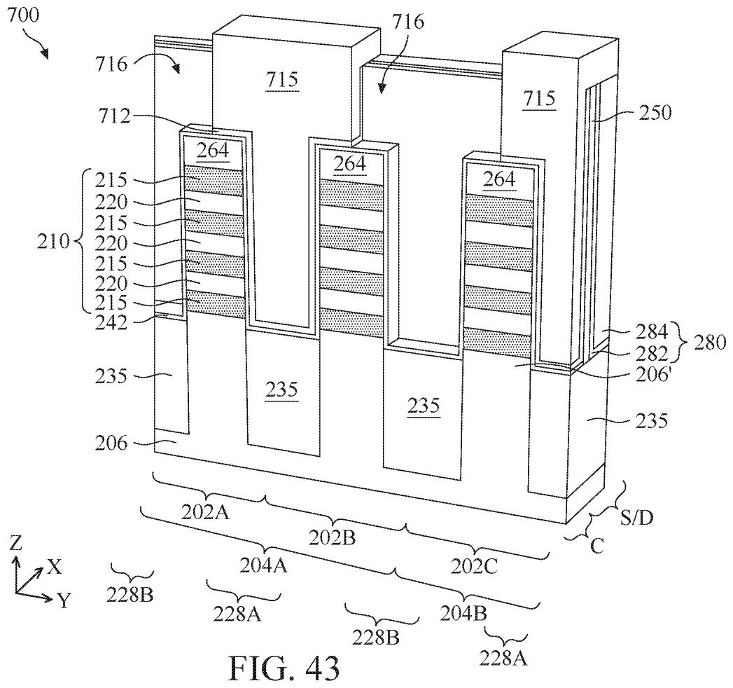

Referring to FIG. 43, isolation layer 712′ is removed from boundary regions 228B of multigate device 700. For example, a lithography process, such as those described herein, is performed to form a patterned mask layer 715 in gate opening 285 that covers isolation layer 712′ in in-cell regions 228A and exposes isolation layer 712′ in boundary regions 228B. In FIG. 43, patterned mask layer 715 has openings 296 therein that expose isolation layer 712′ in boundary region 228B between fin 208B and fin 208C (which overlaps an interface between transistor region 202B and transistor region 202C and an interface between device region 204A and device region 204B) and boundary region 228B adjacent to fin 208A (which may overlap an interface between transistor region 202A and an adjacent transistor region to the left of transistor region 202A). Patterned mask layer 715 includes a first mask portion and a second mask portion that respectively cover isolation layer 712′ in in-cell region 228A between fin 208A and fin 208B (which overlaps an interface between transistor region 202A and transistor region 202B) and in-cell region 228A adjacent to fin 208C (which may overlap an interface between transistor region 202C and an adjacent transistor region to the right of transistor region 202C). The first mask portion may fill a remainder of an opening (e.g., trench 230) between fin 208A and fin 208B, and the second mask portion may fill a remainder of an opening (e.g., trench 230) between fin 208C and an adjacent device feature/region, such as an adjacent fin to the right of fin 208C. Patterned mask layer 715 may further cover portions of isolation layer 712′ that are disposed over tops of fins 208A-208C. In the depicted embodiment, patterned mask layer 715 covers a portion of isolation layer 712′ over a top of fin 208A, a portion of isolation layer 712′ over a top of fin 208B, and a portion of isolation layer 712′ over a top of fin 208C.

An etching process is then performed to remove exposed portions of isolation layer 712′, thereby forming isolation liners 712 in in-cell regions 228A that extend over tops of fins 208A-208C. For example, a respective isolation liner 712 is disposed in in-cell region 228A between fin 208A and fin 208B and forms sidewalls and a bottom of gate isolation wall 710 between fin 208A and fin 208B, and a respective isolation liner 712 is disposed in in-cell region 228A between fin 208C and an adjacent device feature/region and forms sidewalls and a bottom of gate isolation wall 710 between fin 208C and the adjacent device feature/region. The etching process selectively removes isolation layer 712′ with respect to dummy gate dielectric 242, such that dummy gate dielectric 242 remains in boundary regions 228B. The etching process may also selectively remove isolation layer 712′ with respect to gate spacers 250, ILD layer 284, CESL 282, or a combination thereof. In other words, the etching process removes isolation layer 712′ with negligible removal of dummy gate dielectric 242, gate spacers 250, ILD layer 284, CESL 282, or a combination thereof. For example, an etchant may be selected for the etching process that removes a nitrogen-comprising and/or a carbon-comprising dielectric material (i.e., isolation layer 712′) at a higher rate than oxygen-comprising dielectric materials (i.e., dummy gate dielectric 242, gate spacers 250, ILD layer 284, CESL 282, etc.). The etching process is a dry etch, a wet etch, other suitable etch, or a combination thereof. In some embodiments, patterned mask layer 715 is configured such that isolation layer 712′ is removed from the tops of fins 208A-208C and isolation liners 712 do not extend over tops of fins 208-208C.

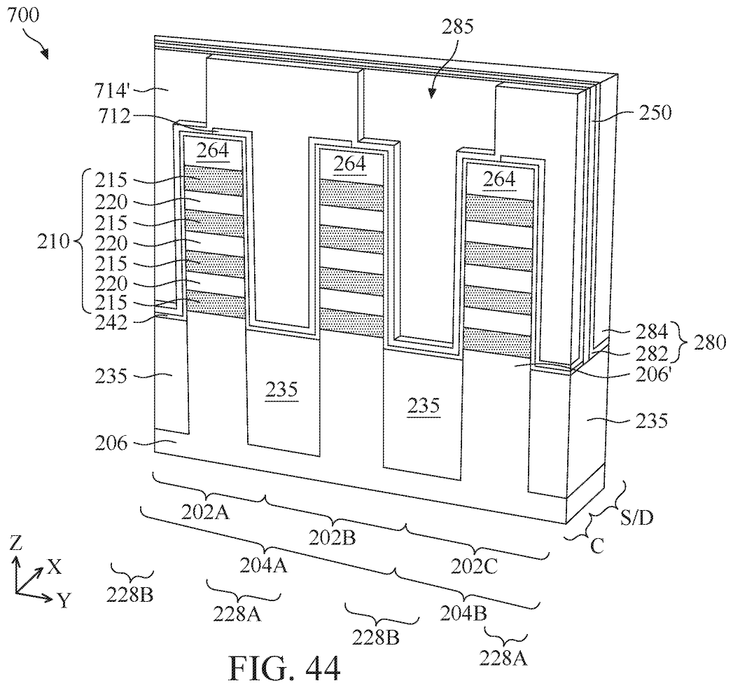

Referring to FIG. 44, patterned mask layer 715 is removed by a resist stripping process, an etching process, other suitable process, or a combination thereof. A bulk isolation material 714′ is then formed in gate opening 285 that fills remainders of openings between fins 208A-208C (e.g., trenches 230 therebetween) in in-cell regions 228A. For example, bulk isolation material 714′ may merge along the x-direction and/or the y-direction in in-cell regions 228A. Because boundary regions 228B are free of isolation liners 712, bulk isolation material 714′ may partially, instead of completely, fill openings between fins 208A-208C (e.g., trenches 230 therebetween) in boundary regions 228B. In the depicted embodiment, bulk isolation material 714′ includes a nitrogen-comprising dielectric material, such as a dielectric material that includes nitrogen in combination with silicon, carbon, oxygen, or a combination thereof. For example, bulk isolation material 714′ includes SiN, SiON, SiCN, SiOCN, or a combination thereof. In some embodiments, bulk isolation material 714′ includes a carbon-comprising dielectric material, such as a dielectric material that includes carbon in combination with silicon, nitrogen, oxygen, or a combination thereof. For example, bulk isolation material 714′ includes SiC, SiOC, or a combination thereof. A composition and/or a material of bulk isolation material 714′ may be different than a composition and/or a material of dummy gate dielectric 242 and/or gate spacers 250 to enable selective removal of bulk isolation material 714′ relative to dummy gate dielectric 242 and/or gate spacers 250. In some embodiments, a composition and/or a material of bulk isolation material 714′ is the same as a composition and/or a material of isolation liners 712. In some embodiments, a composition and/or a material of bulk isolation material 714′ is different than a composition and/or a material of isolation liners 712.

A deposition process is performed to form bulk isolation material 714′ in gate opening 285, such as CVD, PVD, ALD, HDPCVD, MOCVD, RPCVD, PECVD, LPCVD, APCVD, SAVCD, other suitable methods, or a combination thereof. The deposition process may be configured to form a dielectric material that fills portions of gate opening 285 in in-cell regions 228A while partially filling portions of gate opening 285 in boundary regions 228B. In some embodiments, where isolation liners 712 partially cover tops of fins 208A-208C, bulk isolation material 714′ may fill portions of gate opening 285 over portions of fins 208A-208C adjacent to in-cell regions 228A and partially fill portions of gate opening 285 over fins 208A-208C adjacent to boundary regions 228B, such as depicted. A planarization process (e.g., CMP) may be performed to remove bulk isolation material 714′ from over tops of gate spacers 250, CESL 282, ILD layer 284, or a combination thereof. Gate spacers 250, CESL 282, ILD layer 284, or a combination thereof may function as a planarization stop layer, and the planarization process may be performed until exposing gate spacers 250, CESL 282, ILD layer 284, etc.

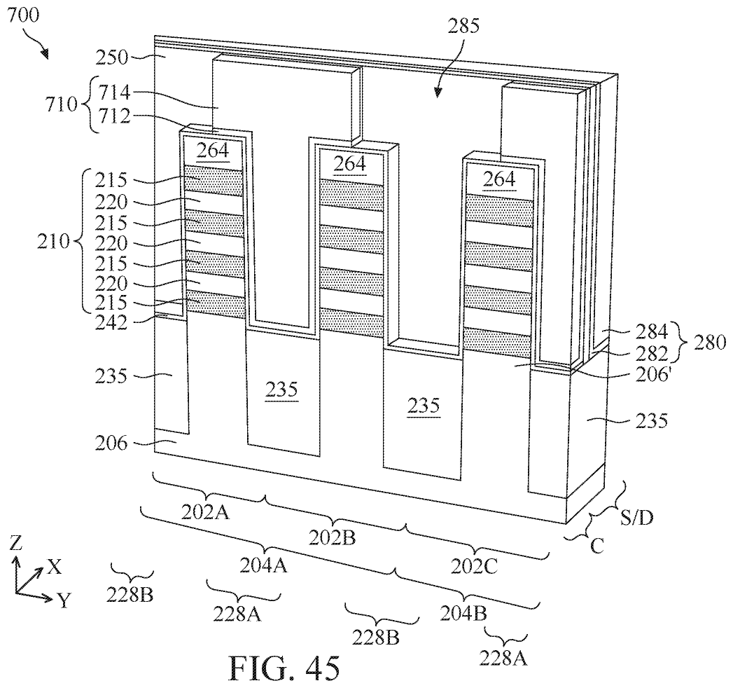

Referring to FIG. 45, bulk isolation material 714′ is removed from boundary regions 228B of multigate device 700, thereby forming bulk isolation layers 714 in in-cell regions 228A that extend over tops of fins 208A-208C. For example, a respective bulk isolation layer 714 is disposed over a respective isolation liner 712 in in-cell region 228A between fin 208A and fin 208B, and a respective bulk isolation layer 714 is disposed over a respective isolation liner 712 in in-cell region 228A between fin 208C and an adjacent device feature/region. In such embodiments, gate isolation walls 710 (each including a respective bulk isolation layer 714 wrapped by a respective isolation liner 712) are disposed in in-cell regions 228A and extend over tops of fins 208A-208C. Dummy gate dielectric 242 is disposed between gate isolation walls 710 (e.g., isolation liners 712 thereof) and fins 208A-208C, and dummy gate dielectric 242 is disposed between gate isolation walls 710 and isolation features 235.

In some embodiments, a lithography process and an etching process may be performed to remove bulk isolation material 714′ from boundary regions 228B. The lithography process may be similar to the lithography process performed when removing isolation layer 712′ as described above with reference to FIG. 43. For example, a patterned mask layer may be formed over multigate device 700 that covers bulk isolation material 714′ in in-cell regions 228A and exposes bulk isolation material 714′ in boundary regions 228B. The patterned mask layer may have openings therein that expose bulk isolation material 714′ in boundary region 228B between fin 208B and fin 208C and boundary region 228B adjacent to fin 208A. The patterned mask layer may include a first mask portion and a second mask portion that respectively cover bulk isolation material 714′ in in-cell region 228A between fin 208A and fin 208B and in-cell region 228A adjacent to fin 208C. The patterned mask layer may further cover portions of bulk isolation material 714′ that are disposed over tops of fins 208A-208C.

The etching process selectively removes exposed portions of bulk isolation material 714′ with respect to dummy gate dielectric 242, such that dummy gate dielectric 242 remains in boundary regions 228B. The etching process may also selectively remove bulk isolation material 714′ with respect to gate spacers 250, ILD layer 284, CESL 282, or a combination thereof. In other words, the etching process removes bulk isolation material 714′ with negligible removal of dummy gate dielectric 242, gate spacers 250, ILD layer 284, CESL 282, or a combination thereof. For example, an etchant may be selected for the etching process that removes a nitrogen-comprising and/or a carbon-comprising dielectric material (i.e., bulk isolation material 714′) at a higher rate than oxygen-comprising dielectric materials (i.e., dummy gate dielectric 242). The etching process is a dry etch, a wet etch, other suitable etch, or a combination thereof. In some embodiments, the patterned mask layer is configured such that bulk isolation material 714′ is removed from the tops of fins 208A-208C and bulk isolation layers 714 do not extend over tops of fins 208-208C. In some embodiments, the etching process (e.g., an etch back process) is performed without performing the lithography process.

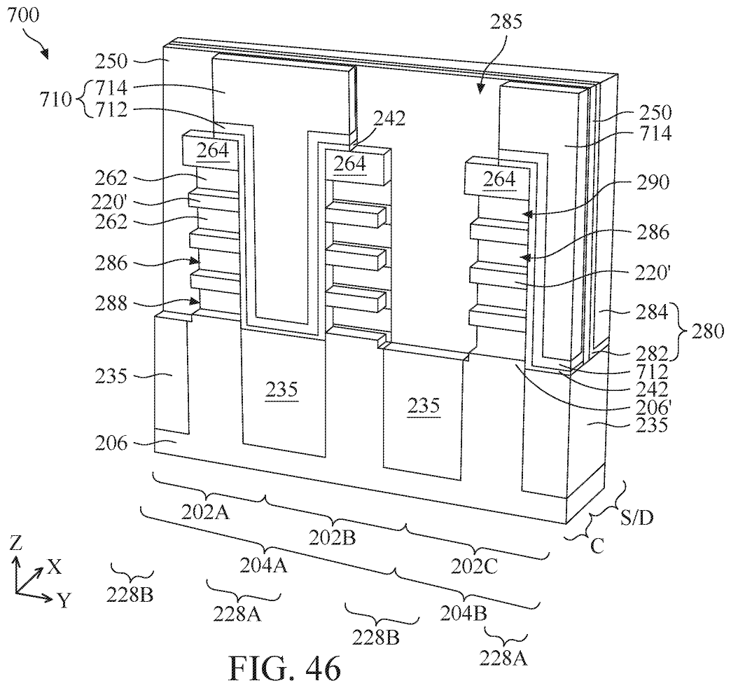

Referring to FIG. 46, processing includes removing dummy gate dielectric 242 and performing a channel release process to form suspended channel layers in channel regions of transistor regions 202A-202C. Because gate isolation walls 710 cover dummy gate dielectric 242 in in-cell regions 228A, dummy gate dielectric 242 is removed from boundary regions 228B and remains in in-cell regions 228A. In the depicted embodiment, because portions of dummy gate dielectric 242 remain, semiconductor layers 220 and gate helmets 264 each have a sidewall covered by dummy gate dielectric 242 and a sidewall free of dummy gate dielectric 242, and dummy gate dielectric 242 extends over tops of gate helmets 264. An etching process selectively removes dummy gate dielectric 242 with respect to semiconductor layer stacks 210, gate spacers 250, gate helmets 264, ILD layer 284, CESL 282, gate isolation walls 710, or a combination thereof. In other words, the etching process removes dummy gate dielectric 242 with negligible removal of semiconductor layer stacks 210, gate spacers 250, gate helmets 264, ILD layer 284, CESL 282, gate isolation walls 710, or a combination thereof. For example, an etchant removes dummy gate dielectric 242 at a higher rate than semiconductor layer stacks 210, gate isolation walls 710, gate spacers 250, gate helmets 264, ILD layer 284, CESL 282, or a combination thereof (i.e., the etchant has a high etch selectivity with respect to an interfacial oxide, such as silicon oxide). The etching process is a dry etch, a wet etch, other suitable etch, or a combination thereof. In some embodiments, the etch process includes multiple steps.

In FIG. 46, semiconductor layers 215 exposed by gate opening 285 are also selectively removed to form gaps/openings 286, gaps/openings 288, and gaps/openings 290, thereby suspending semiconductor layers 220 over mesas 206′ in channel regions of transistor regions 202A-202C. Gate opening 285 is thus extended between semiconductor layers 220, between semiconductor layers 220 and gate helmets 264, and between semiconductor layers 220 and mesas 206′. Gaps 286 are between semiconductor layers 220, gaps 288 are between semiconductor layers 220 and mesas 206′, and gaps 290 are between semiconductor layers 220 and gate helmets 264. In the depicted embodiment, each channel region has three suspended semiconductor layers 220, which are referred to hereafter as channel layers 220′. Channel layers 220′ are vertically stacked along the z-direction and provide three channels, respectively, through which current may flow between respective epitaxial source/drains 275A-275C.

In some embodiments, an etching process selectively removes semiconductor layers 215 with negligible removal of mesas 206′, semiconductor layers 220, dummy gate dielectric 242, gate helmets 264, inner spacers 262, gate spacers 250, dielectric layer 280, gate isolation walls 710, or a combination thereof. For example, an etchant is selected for the etch process that etches silicon germanium (i.e., semiconductor layers 215) at a higher rate than silicon (i.e., semiconductor layers 220 and mesas 206′) and dielectric materials (i.e., dummy gate dielectric 242, gate helmets 264, inner spacers 262, gate spacers 250, CESL 282, ILD layer 284, isolation liners 712′, bulk isolation layers 714, or a combination thereof) (i.e., the etchant has a high etch selectivity with respect to silicon germanium). The etching process is a dry etch, a wet etch, other suitable etch, or a combination thereof. In some embodiments, before performing the etching process, an oxidation process converts semiconductor layers 215 into silicon germanium oxide features, and the etching process removes the silicon germanium oxide features. In some embodiments, dummy gate dielectric 242 and semiconductor layers 215 are removed by different etching processes (e.g., a first etch for dummy gate dielectric 242 and a second etch for semiconductor layers 215). In some embodiments, a single etching process is performed to remove dummy gate dielectric 242 and semiconductor layers 215 (e.g., by using an etchant that may remove both dummy gate dielectric 242 and semiconductor layers 215).

An etching process may be performed to modify a profile of channel layers 220′ to provide target dimensions and/or target shapes thereof. For example, the etching process may provide channel layers 220′ with cylindrical-shaped profiles (e.g., nanowires), rectangular-shaped profiles (e.g., nanobars), sheet-shaped profiles (e.g., nanosheets (e.g., dimensions in the X-Y plane are sufficiently greater than dimensions in the X-Z plane and the Y-Z plane to form sheet-like structures)), or any other suitable shaped profile. In some embodiments, channel layers 220′ have nanometer-sized dimensions and may be referred to as “nanostructures,” alone or collectively. In some embodiments, channel layers 220′ have sub-nanometer dimensions and/or other suitable dimensions. In the depicted embodiment, channel layers 220′ have dimensions that are less than dimensions of inner spacers 262 and/or gate helmets 264. In some embodiments, widths (e.g., along the y-direction) of channel layers 220′ are less than widths (e.g., along the y-direction) of inner spacers 262 and/or gate helmets 264. In some embodiments, thicknesses (e.g., along the z-direction) of channel layers 220′ are less than thicknesses (e.g., along the z-direction) of inner spacers 262 and/or gate helmets 264.

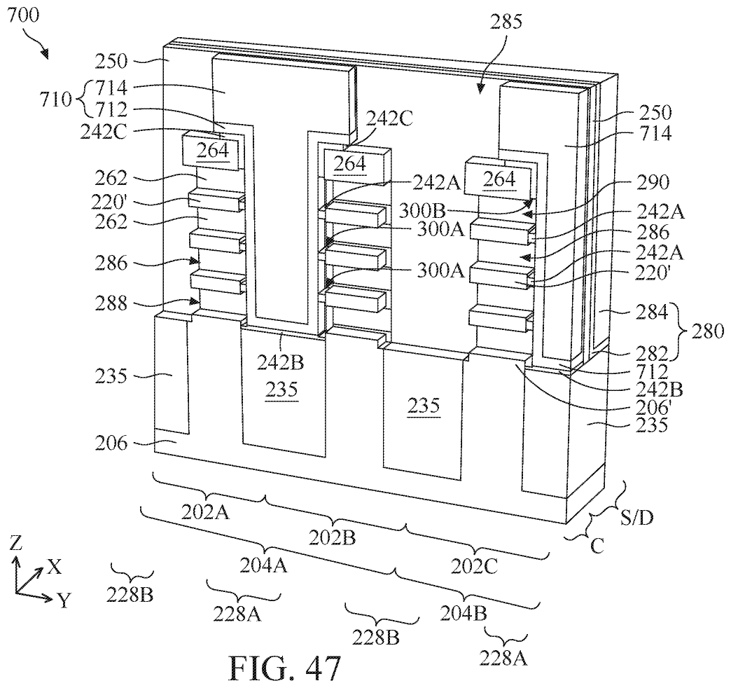

Referring to FIG. 47, a trimming process may be performed on dummy gate dielectric 242 remaining in in-cell regions 228A. For example, the trimming process may remove exposed portions of dummy gate dielectric 242, such as portions along sidewalls of gate isolation walls 710 that are not covered by other device features. In such example, after trimming, dummy gate dielectric portions 242A are between channel layers 220′ and gate isolation walls 710, dummy gate dielectric portions 242B are between isolation features 235 and gate isolation walls 710, and dummy gate dielectric portions 242C are between gate helmets 264 and gate isolation walls 710, such as depicted. In some embodiments, the trimming process recesses dummy gate dielectric portions 242A from tops and bottoms of channel layers 220′, such that dummy gate dielectric portions 242A partially cover gate isolation wall facing sidewalls of channel layers 220′ and gaps 300A are between such sidewalls of channel layers 220′ and gate isolation walls 710. In some embodiments, dummy gate dielectric portions 242A are not recessed from tops and bottoms of channel layers 220′, and dummy gate dielectric portions 242A cover an entirety of gate isolation wall facing sidewalls of channel layers 220′. In some embodiments, the trimming process recesses dummy gate dielectric portions 242C from bottoms of gate helmets 264 and sidewalls of gate isolation walls 710 that are disposed over tops of gate helmets 264, such that dummy gate dielectric portions 242C partially cover gate isolation wall facing sidewalls of gate helmets 264 and gaps 300B are between such sidewalls of gate helmets 264 and gate isolation walls 710. In some embodiments, dummy gate dielectric portions 242C are not recessed from bottoms of gate helmets 264 and/or from sidewalls of gate isolation walls 710 disposed over tops of gate helmets 264, and dummy gate dielectric portions 242C cover an entirety of gate isolation wall facing sidewalls of gate helmets 264 and/or gate isolation walls 710 do not overhang dummy gate dielectric portions 242C. The present disclosure contemplates the trimming process providing various configurations of dummy gate dielectric portions 242A, dummy gate dielectric portions 242B, dummy gate dielectric portions 242C, or a combination thereof.

The trimming process may be an etching process that selectively removes dummy gate dielectric 242 with respect to channel layers 220′, gate spacers 250, gate helmets 264, ILD layer 284, CESL 282, gate isolation walls 710, or a combination thereof. In other words, the etching process removes dummy gate dielectric 242 (e.g., a dielectric material including silicon and oxygen) with negligible removal of channel layers 220′, gate spacers 250, gate helmets 264, ILD layer 284, CESL 282, gate isolation walls 710, or a combination thereof (e.g., semiconductor materials and/or dielectric materials including silicon and nitrogen and/or carbon). For example, an etchant is selected for the etching process that removes dummy gate dielectric 242 at a higher rate than channel layers 220′, gate spacers 250, gate helmets 264, ILD layer 284, CESL 282, gate isolation walls 710, or a combination thereof (i.e., the etchant has a high etch selectivity with respect to an interfacial oxide, such as silicon oxide). The etching process is a dry etch, a wet etch, other suitable etch, or a combination thereof.

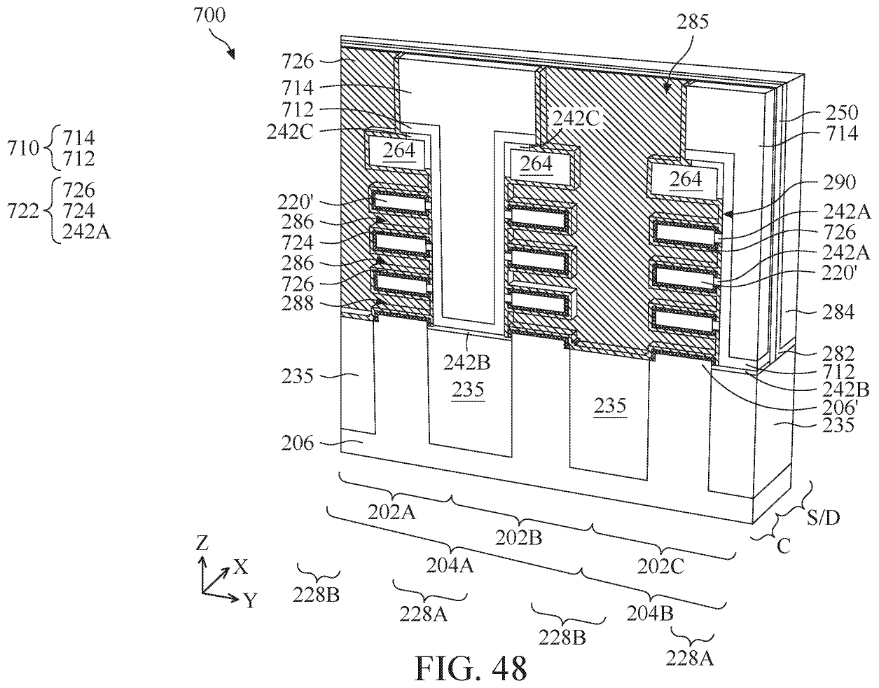

Referring to FIG. 48, a gate dielectric 722 is formed in and partially fills gate opening 285. Gate dielectric 722 partially fills gaps 286, gaps 288, and gaps 290, and gate dielectric 722 fills gaps 300A between channel layers 220′ and gate isolation walls 710 and gaps 300B between gate helmets 264 and gate isolation walls 710. Gate dielectric 722 includes a dielectric layer, such as an interfacial layer 724 and a high-k dielectric layer 726. In the depicted embodiment, gate dielectric 722 includes dummy gate dielectric portions 242A (i.e., remainders of the dummy gate dielectric). In some embodiments, gate dielectric 722 includes dummy gate dielectric portions 242C and/or dummy gate dielectric portions 242B. Gate dielectric 722 surrounds channel layers 220′, and gate dielectric 722 is disposed over mesas 206′, isolation features 235, gate spacers 250, gate helmets 264, and gate isolation walls 710. Interfacial layer 724 and high-k dielectric layer 726 are disposed on top surfaces, bottom surfaces, and sidewalls of channel layers 220′. In FIG. 48, since dummy gate dielectric portions 242A are formed along portions of gate isolation wall facing sidewalls of channel layers 220′, interfacial layer 724 and high-k dielectric layer 726 wrap channel layers 220′. For example, interfacial layer 724 and high-k dielectric layer 726 are disposed on tops, bottoms, and sidewalls of channel layers 220′ that face boundary regions 228B. Interfacial layer 724 and high-k dielectric layer 726 are also disposed on sidewalls of channel layers 220′ that face in-cell regions 228A. A thickness of dummy gate dielectric portions 242A may be greater than a thickness of interfacial layer 724 and/or a thickness of high-k dielectric layer 726. Further, interfacial layer 724 and high-k dielectric layer 726 wrap mesas 206′, high-k dielectric layer 726 is disposed on top surfaces of isolation features 235, high-k dielectric layer 726 is disposed on sidewalls of gate spacers 250, high-k dielectric layer 726 is disposed on sidewalls of gate isolation walls 710, and high-k dielectric layer 726 is disposed on top surfaces, bottom surfaces, and sidewalls of gate helmets 264 that face boundary regions 228B (e.g., high-k dielectric layer 726 wraps gate helmets 264).

Interfacial layer 724 includes a dielectric material, such as SiO₂, HfSiO, SiON, other silicon-comprising dielectric material, other suitable dielectric material, or a combination thereof. Interfacial layer 724 is formed by thermal oxidation, chemical oxidation, ALD, CVD, other suitable process, or a combination thereof. For example, interfacial layer 724 is formed by a chemical oxidation process that exposes channel layers 220′ and mesas 206′ to hydrofluoric acid. In another example, interfacial layer 724 is formed by a thermal oxidation process that exposes channel layers 220′ and mesas 206′ to an oxygen ambient and/or air ambient. In some embodiments, interfacial layer 724 forms on exposed semiconductor surfaces (e.g., channel layers 220′ and mesas 206′) but not exposed dielectric surfaces (e.g., gate helmets 264, gate spacers 250, gate isolation walls 710, isolation features 235, or a combination thereof). In such embodiments, such as depicted, interfacial layer 724 is between semiconductor surfaces and high-k dielectric layer 726 but not between dielectric surfaces and high-k dielectric layer 726. In some embodiments, interfacial layer 724 is formed after forming high-k dielectric layer 726. For example, multigate device 700 may be annealed in an oxygen ambient and/or nitrogen ambient (e.g., nitrous oxide) after forming high-k dielectric layer 726.

High-k dielectric layer 726 includes a high-k dielectric material, which refers to a dielectric material having a dielectric constant that is greater than that of silicon dioxide (k≈3.9). For example, high-k dielectric layer 726 includes HfO₂, HfSiO, HfSiO₄, HESION, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba,Sr)TiO₃ (BST), Si₃N₄, hafnium dioxide-alumina (HfO₂—Al₂O₃) alloy, other suitable high-k dielectric material, or a combination thereof. High-k dielectric layer 726 is formed by ALD, CVD, PVD, oxidation-based deposition process, other suitable process, or a combination thereof. For example, an ALD process conformally deposits high-k dielectric layer 726, such that a thickness of high-k dielectric layer 726 is substantially uniform (conformal) over various surfaces in gate opening 285.

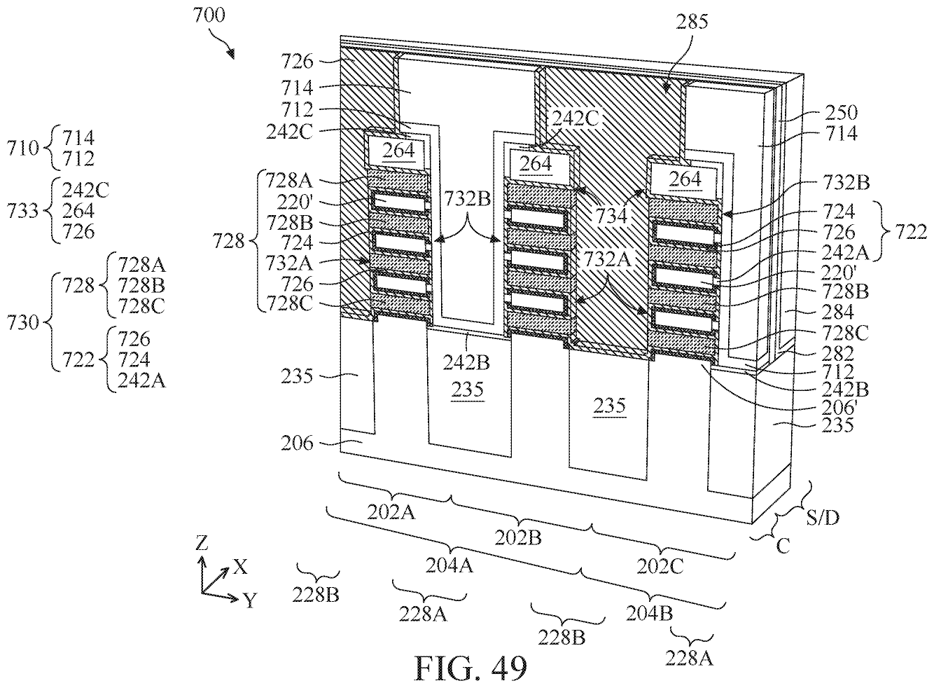

Referring to FIG. 49, gate electrodes 728 are formed over gate dielectric 722 in gate opening 285. Gate electrodes 728 partially fill gate opening 285, and gate electrodes 728 fill remainders of gaps 286, gaps 288, and gaps 290. For example, each gate electrode 728 includes a portion 728A that fills a remainder of a respective gap 290, portions 728B that fill remainders of respective gaps 286, and a portion 728C that fills a remainder of a respective gap 288. In such embodiments, gate electrodes 728 are disposed along top surfaces and bottom surfaces of channel layers 220′, bottom surfaces of gate helmets 264, and top surfaces of mesas 206′.

Gate electrodes 728 include an electrically conductive material, such as polysilicon, Al, Cu, Ti, Ta, W, Mo, Co, TaN, NiSi, CoSi, TiN, WN, TiAl, TiAlN, TaCN, TaC, TaSiN, other suitable electrically conductive material, or a combination thereof. Gate electrodes 728 may have a single layer structure or a multilayer structure. In some embodiments, portions 728A-728C each include a work function layer and a bulk (or fill) layer. The work function layer is an electrically conductive layer that is tuned to have a desired work function, such as an n-type work function or a p-type work function, and the bulk layer is an electrically conductive layer disposed over the work function layer. In some embodiments, the work function layer includes n-type work function materials, such as Ti, Ag, Mn, Zr, TaAl, TaAIC, TiAlN, TaC, TaCN, TaSiN, other suitable n-type work function material, or a combination thereof. In some embodiments, the work function layer includes a p-type work function material, such as Ru, Mo, Al, TiN, TaN, WN, ZrSi₂, MoSi₂, TaSi₂, NiSi₂, WN, other suitable p-type work function material, or a combination thereof. The bulk layer may include Al, W, Cu, Ti, Ta, alloys thereof, or a combination thereof. In some embodiments, portions 728A-728C include diffusion layers and/or barrier layers, such as a bulk layer disposed over a diffusion/barrier layer.

Forming gate electrodes 728 includes depositing a gate electrode material in gate opening 285 that fills remainders of gaps 286, gaps 288, and gaps 290 and etching back the gate electrode material, such that a remainder of the gate electrode material forms portions 728A-728C. The gate electrode material may partially or completely fill gate opening 285. In some embodiments, the etching back is an etching process that selectively removes the gate electrode material with negligible removal of high-k dielectric layer 726, gate isolation walls 710, CESL 282, ILD layer 284, or a combination thereof. For example, an etchant is selected for the etch process that removes metal materials (i.e., gate electrode material, which may form one or more layers of portions 728A-728C) at a higher rate than dielectric materials (i.e., high-k dielectric layer 726, gate isolation walls 710, CESL 282, ILD layer 284, or a combination thereof) (i.e., the etchant has a high etch selectivity with respect to metal materials). In some embodiments, after deposition, the gate electrode material is disposed along top surfaces, bottom surfaces, and sidewalls of channel layers 220′ and/or gate helmets 264 that do not face gate isolation walls 710 (i.e., the gate electrode material wraps channel layers 220′ and/or gate helmets 264), and the etching back removes the gate electrode material from sidewalls of channel layers 220′, sidewalls of gate helmets 264, and tops of gate helmets 264. In such embodiments, the etching back exposes high-k dielectric layer 726 along sidewalls of channel layers 220′ and/or sidewalls and/or top of gate helmets 264 that do not face gate isolation walls 710, such as sidewalls facing boundary regions 228B. In some embodiments, the etching process is configured to stop upon reaching high-k dielectric layer 726. In some embodiments, the etching process uses high-k dielectric layer 726 as an etch stop. To minimize and/or prevent removal of the gate electrode material that fills gaps 286, gaps 288, and gaps 290, the etching process may be an anisotropic etch having a vertical etch rate that is greater than a horizontal etch rate, such that the anisotropic etch removes material in substantially the vertical direction with negligible material removal in the horizontal direction. In some embodiments, the horizontal etch rate may be zero. The etching process is a dry etch, a wet etch, other suitable etch, or a combination thereof.

In FIG. 49, each of transistor regions 202A-202C has a respective gate stack 730. Each gate stack 730 includes a respective gate dielectric 722 and a respective gate electrode 728. In the depicted embodiment, high-k dielectric layer 726 spans boundary regions 228B, such that gate stacks 730 of transistor regions at boundary regions 228B (e.g., transistor region 202B and transistor region 202C and/or transistor region 202A and an adjacent transistor region to its left) may share high-k dielectric layer 726 (e.g., high-k dielectric layer 726 may extend uninterrupted from transistor region 202B to transistor region 202C), but have separate, respective interfacial layers 304 and separate, respective gate electrodes 728. Because the gate electrode material is etched back and gate isolation walls 710 are formed before removing dummy gate dielectric 242 and forming gate stacks 730, each gate stack 730 has a respective sidewall 732A and a respective sidewall 732B. Sidewall 732A is formed by both its respective gate dielectric 722 (e.g., high-k dielectric layer 726 thereof) and its respective gate electrode 728, and sidewall 732B is formed by its respective gate dielectric (e.g., high-k dielectric layer 726 and dummy gate dielectric portions 242A thereof). Sidewall 732A faces a respective boundary region 228B, and sidewall 732B faces a respective in-cell region 228A (i.e., its gate isolation wall facing sidewall).

Further, each gate helmet 264 is surrounded by a dielectric layer, such as a respective portion of high-k dielectric layer 726 and a respective dummy gate dielectric portion 242C. Gate helmets 264 and their respective surrounding dielectric layers are collectively referred to as gate helmet structures 733. In some embodiments, such as depicted, gate stacks 730 are disposed under gate helmet structures 733, and gate helmet structures 733 extend laterally (e.g., along the y-direction) beyond sidewalls 732A of gate stacks 730. For example, gate helmet structures 733 have overhangs 734, such that a distance (e.g., along the y-direction) is between sidewalls of gate helmet structures 733 and sidewalls 732A of gate stacks 730. In some embodiments, gate helmet structures 733 and gate stacks 730 may have substantially the same widths, such that sidewalls of gate helmet structures 733 are aligned with sidewalls 732A (e.g., along the z-direction).

Gate stacks 730 are configured to achieve desired functionality according to design requirements of multigate device 700, and gate stacks 730 may have different layers in transistor regions 202A-202C depending on configurations thereof. For example, a number, configuration, materials, or a combination thereof of layers of gate dielectrics 722 and/or gate electrodes 728 of a p-type transistor region may be different than a number, configuration, materials, or a combination thereof of layers of gate dielectrics 722 and/or gate electrodes 728 of an n-type transistor region. In another example, a number, configuration, materials, or a combination thereof of layers of gate dielectrics 722 and/or gate electrodes 728 of a first n-type transistor region may be different than a number, configuration, materials, or a combination thereof of layers of gate dielectrics 722 and/or gate electrodes 728 of a second n-type transistor region. In yet another example, a number, configuration, materials, or a combination thereof of layers of gate dielectrics 722 and/or gate electrodes 728 of a first p-type transistor region may be different than a number, configuration, materials, or a combination thereof of layers of gate dielectrics 722 and/or gate electrodes 728 of a second p-type transistor region. Gate stacks 730 may include numerous other layers, for example, capping layers, interface layers, diffusion layers, barrier layers, hard mask layers, or a combination thereof.

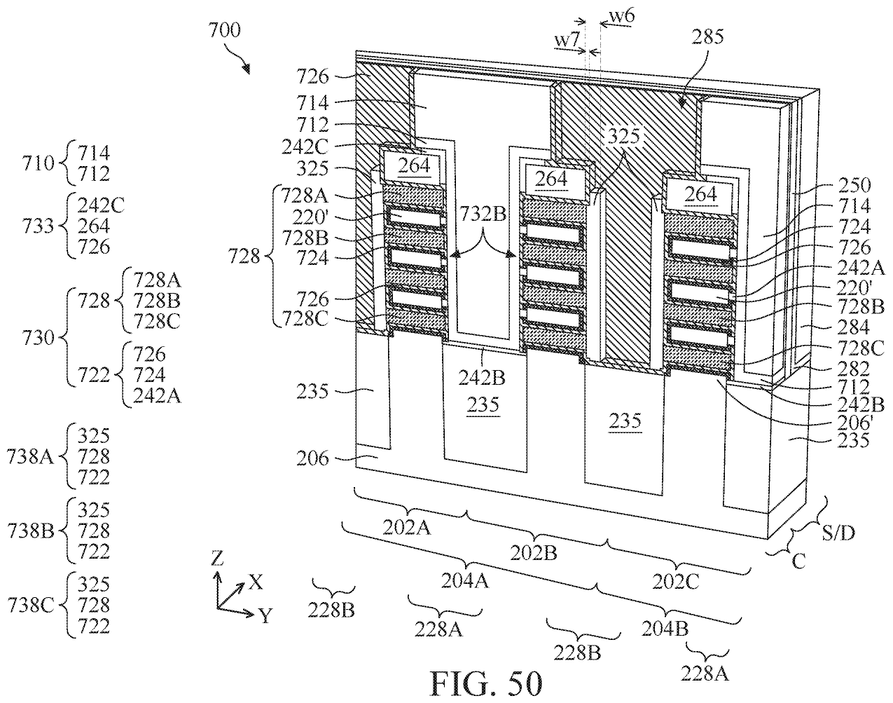

Turning to FIG. 50, gate endcaps 325 are formed in and partially fill gate opening 285. In such embodiments, a gate 738A is provided in transistor region 202A, a gate 738B is provided in transistor region 202B, and a gate 738C is provided in transistor region 202C. Each of gates 738A-738C includes a respective gate stack 730 (e.g., a respective gate dielectric 722 and a respective gate electrode 728) and a respective gate endcap 325 forming a sidewall thereof. Gates 738A-738C are also referred to as metal gates and/or high-k/metal gates.

In multigate device 700, gate endcaps 325 cover sidewalls 732A of gate stacks 730, which are formed by both high-k dielectric layer 726 and gate electrodes 728. For example, gate endcaps 325 are disposed on sidewalls of portions 728A-728C, and gate endcaps 325 physically and/or electrically connect one or more of portions 728A-728C. Gate endcaps 325 are disposed along sidewalls of channel layers 220′, and gate dielectric 722 is between channel layers 220′ and gate endcaps 325. Gate endcaps 325 may extend above gate electrodes 728 along the sidewalls of gate helmet structures 733, and gate endcaps 325 may wrap overhangs 734 of gate helmet structures 733. In FIG. 50, gate endcaps 325 extend along a bottom and sidewalls of gate helmets 264, such as portions forming overhangs 734 of gate helmet structures 733, and high-k dielectric layer 726 is between gate helmets 264 and gate endcaps 325. Gate endcaps 325 may extend below gate electrodes 728 along sidewalls of mesas 206′, such as depicted, and gate dielectric 722 may be between mesas 206′ and gate endcaps 325. In some embodiments, gate endcaps 325 do not extend above and/or below gate electrodes 728. In some embodiments, gate endcaps 325 do not extend above gate portions 728A of gate electrodes 728.

Gate endcaps 325 include tungsten, ruthenium, molybdenum, other electrically conductive material that may be selectively formed on gate electrodes 728, alloys thereof, or a combination thereof. For example, gate endcaps 325 are tungsten layers. In another example, gate endcaps 325 are ruthenium layers. In yet another example, gate endcaps 325 are molybdenum layers. Gate endcaps 325 have a width w6 (e.g., along the y-direction) along sidewalls 732A of gate stacks 730. In some embodiments, width w6 is about 4 nm to about 10 nm. Width w6 may be a total thickness of gate endcaps 325. In some embodiments, gate endcaps 325 have a width w7 (e.g., along the y-direction) along sidewalls of gate helmet structures 733. Width w7 is less than width w6. In some embodiments, a width of gate endcaps 325 along sidewalls of mesas 206′ is width w7. In some embodiments, a width of gate endcaps 325 along sidewalls of mesas 206′ is less than width w6 and different than width w7.

Gate endcaps 325 are formed by a selective deposition process, such as a deposition process that is configured to selectively grow gate endcap material from metal surfaces. The selective deposition process may limit (or prevent) growth of the gate endcap material from dielectric surfaces. For example, forming gate endcaps 325 includes performing selective CVD or selective ALD, where parameters of the selective CVD or selective ALD are tuned to selectively grow metal material (e.g., tungsten, ruthenium, molybdenum, or alloys thereof) from portions 728A-728C. The selective CVD or selective ALD may further be tuned to limit (or prevent) growth of metal material from high-k dielectric layer 726, gate spacers 250, dielectric layer 280, and gate isolation walls 710. In FIG. 50, the selective deposition process is performed until metal material grown from portions 728A-728C merges together to form gate endcaps 325 that extend continuously along sidewalls 732A of gate stacks 730, and gate endcaps 325 connect portions 728A-728C between channel layers 220′. Because gate isolation walls 710 cover sidewalls 732B of gate stacks 730 and/or sidewalls 732B of gate stacks 730 are dielectric sidewalls, gate endcaps 325 form on one sidewall, instead of both sidewalls, of gate stacks 730 in the depicted embodiment. The deposition parameters may include deposition precursors (e.g., metal precursors and/or reactants), deposition precursor flow rates, deposition temperature, deposition time, deposition pressure, source power, radio frequency (RF) bias voltage, RF bias power, other suitable deposition parameters, or a combination thereof. In some embodiments, a carrier gas is used to deliver the metal precursors and/or reactants. In some embodiments, multiple CVD cycles or ALD cycles are performed to form gate endcaps 325. In some embodiments, the selective deposition process includes multiple deposition/etch cycles, each of which may include depositing and etching back a metal material.

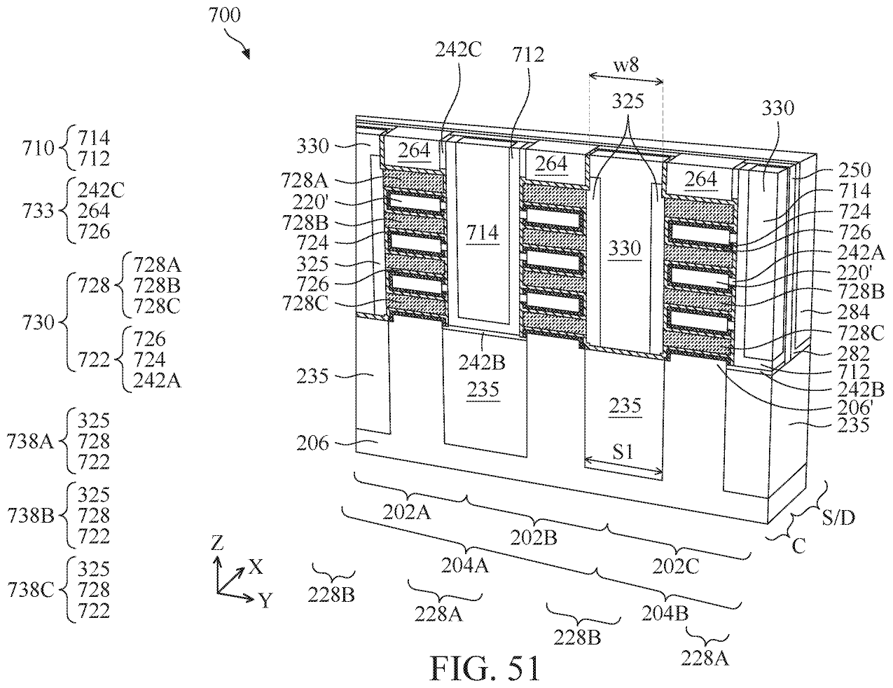

Turning to FIG. 51, processing includes a self-aligned metal gate isolation process (also referred to as a metal gate cut process), which includes forming gate isolation walls 330 in boundary regions 228B that fill a remainder of gate opening 285. For example, gate isolation walls 330 fill spaces between gates 738A-738C, and gate isolation walls 330 are disposed between gate endcaps 325 of adjacent gates 738A-738C (e.g., one of gate isolation walls 330 is between a respective gate endcap 325 of gate 738B and a respective gate endcap 325 of gate 738C). Gate isolation walls 330 may also fill spaces between gate helmets 264, such that gate isolation walls 330 are disposed between adjacent gate helmet structures 733. In the depicted embodiment, high-k dielectric layer 726 is disposed between gate isolation walls 330 and gate helmets 264, and high-k dielectric layer 726 is disposed between gate isolation walls 330 and isolation features 235. Gate isolation walls 330 may electrically isolate gates 738A-738C from one another. For example, gate 738B in transistor region 202B is separated and electrically isolated from gate 738C in transistor region 202C by a respective gate isolation wall 330, while being separated and electrically isolated from gate 738A in transistor region 202A by a respective gate isolation wall 710. Gate 738A in transistor region 202A may also be separated and electrically isolated from other active regions, such as a gate of an adjacent transistor region, by a respective gate isolation wall 330. Gate 738C in transistor region 202C may also be separated and electrically isolated from other active regions, such as a gate of an adjacent transistor region, by a respective gate isolation wall 710.

Gate isolation walls 330 include a dielectric material that includes silicon, oxygen, carbon, nitrogen, other suitable dielectric constituent, or a combination thereof. For example, gate isolation walls 330 include silicon nitride, silicon carbonitride, silicon oxycarbonitride, silicon oxycarbide, or a combination thereof. In the depicted embodiment, gate isolation walls 330 are silicon nitride walls. In some embodiments, where gate helmets 264 function as planarization stops during a planarization process, a composition of gate isolation walls 330 may be different than a composition of gate helmets 264. In the depicted embodiment, gate isolation walls 330 are formed of a single layer. In some embodiments, gate isolation walls 330 may have multilayer structures, such as a bulk dielectric over one or more dielectric liners.

Gate isolation walls 330 have a width w8 (e.g., along the y-direction). In some embodiments, width w8 is about 5 nm to about 600 nm. Gate isolation walls 330 may be formed by depositing a dielectric material (e.g., silicon nitride) over multigate device 700 that fills a remainder of gate opening 285 and performing a planarization process. The planarization process, such as CMP, is performed until reaching and exposing gate helmets 264, such that top surfaces of gate helmets 264 are free of high-k dielectric layer 726 and dummy gate dielectric portions 242C. In some embodiments, gate helmets 264 may function as a planarization stop layer. In some embodiments, the planarization process removes any of the dielectric material (e.g., high-k dielectric layer 726, gate isolation walls 710, ILD layer 284, CESL 282, gate spacers 250, or a combination thereof) disposed above and/or over top surfaces of gate helmets 264, and remainders of the dielectric material form gate isolation walls 330. In some embodiments, the planarization process reduces thicknesses of gate helmets 264. Because gates 738A-738C are fabricated to include etched back gate electrodes 728 and gate endcaps 325 and spacing between adjacent gate helmet structures 733 is greater than spacing between adjacent gates 738A-738C, gate isolation walls 330 may have T-shaped profiles, such as depicted in FIG. 51. In such embodiments, a width of gate isolation walls 330 between gate helmet structures 733 is greater than a width of gate isolation walls 330 between gate endcaps 325. The dielectric material is formed by CVD, FCVD, HDPCVD, MOCVD, RPCVD, PECVD, APCVD, SAVCD, other suitable deposition process, or a combination thereof.

The metal gate cut process is referred to as “self-aligned” because gate isolation walls 330 are aligned between gates at boundary regions 228B (e.g., gate 738B and gate 738C and/or gate 738A and an adjacent gate to its left) without having to perform a lithography process after forming gates 738A-738C. The self-aligned placement of gate isolation walls 330 provides electrical isolation between devices of adjacent active regions, such as transistors formed at boundary regions 228B. The self-aligned placement of gate isolation walls 330 also allows for higher packing density without negatively impacting operation of closely spaced devices in a high-density IC. For example, a spacing S1 between active regions adjacent to boundary regions 228B (e.g., between mesa 206′/channel layers 220′/gate 738B in transistor region 202B and mesa 206′/channel layers 220′/gate 738C in transistor region 202C) and/or adjacent active regions of device region 204A and device region 204B may be smaller than (e.g., about 10 nm to about 15 nm less than) spacings needed therebetween when implementing non-self-aligned metal gate cut techniques, such as those that use a lithography process to form gate isolation structures between gates of adjacent device regions. Spacing S1 is further reduced by providing gates 738A-738C with gate endcaps 325 on one side, instead of both sides. In some embodiments, spacing S1 is about 5 nm to about 600 nm. Smaller spacings between active regions are possible because the described self-aligned metal gate cut technique does not suffer from overlay issues associated with non-self-aligned metal gate cut techniques. Smaller spacings between active regions may thus be implemented without risking unintentional damage to channel layers 220′ and/or gates 738A-738C, such as damage that may arise from process variations inherent in non-self-aligned metal gate cut techniques. Different embodiments may have different advantages, and no particular advantage is necessarily required of any embodiment.

Turning to FIG. 52 and FIGS. 53A-53C, processing may include forming dielectric layer 340, similar to dielectric layer 280 over multigate device 700 and forming device-level contacts (e.g., gate contact 350A and gate contact 350B) in dielectric layer 340, such as described above with reference to FIG. 15 and FIGS. 16A-16C. Gate contact 350A is disposed on tops of respective gate stacks 730 (e.g., portions 728A and high-k dielectric layer 726 thereof) of gate 738A and gate 738B, and gate contact 350A is disposed between gate helmets 264 overlying gate 738A and gate 738B. Gate contact 350A is further disposed on a top of a respective gate isolation wall 710 between gate 738A and gate 738B, and the respective gate isolation wall 710 provides in-cell region gate isolation. Gate contact 350B is disposed on top of a respective gate stack 730 (e.g., portion 728A and high-k dielectric layer 726 thereof) of gate 738C, and gate contact 350B is disposed adjacent to gate helmet 264 overlying gate 738C. Gate contact 350B is further disposed on a top of a respective gate isolation wall 710 between gate 738C and an adjacent gate, and the respective gate isolation wall 710 provides in-cell region gate isolation. Gate contact 350A may physically and/or electrically connect gate 738A and gate 738B, and gate contact 350B may physically and/or electrically connect gate 738C and a gate of an adjacent transistor region. Source/drain contacts 355 are disposed on respective epitaxial source/drains 275B and between respective portions of CESL 282.

In some embodiments, gate contact 350A and/or gate contact 350B are barrier-frec. For example, gate contact 350A and/or gate contact 350B may have metal plugs that physically contact gate electrodes 728, high-k dielectric layers 726, gate isolation walls 710, gate helmets 264, dielectric layer 340, other adjacent dielectric layers, or a combination thereof. In some embodiments, gate contact 350A and/or gate contact 350B include a metal plug disposed over a diffusion/barrier layer. In some embodiments, forming gate contacts 350 may include forming a patterned mask layer over dielectric layer 340, where the patterned mask layer has a first opening and a second opening. The first opening overlaps a portion of gate 738A, a portion of gate 738B, and gate isolation wall 710 therebetween, and the second opening overlaps a portion of gate 738C and gate isolation wall 710 adjacent thereto. An etching process may be performed that uses the patterned mask layer as an etch mask to form a first gate contact opening and a second gate contact opening. The first gate contact opening exposes the portion of gate 738A, the portion of gate 738B, and gate isolation wall 710 therebetween, and the second gate contact opening exposes the portion of gate 738C and gate isolation wall 710 adjacent thereto. The etching process selectively removes dielectric material (e.g., dielectric layer 340, gate helmets 264, high-k dielectric layer 726, gate isolation walls 710, or a combination thereof) exposed by the first opening and the second opening of the patterned mask layer with negligible removal of metal materials (e.g., gate electrodes 728). In some embodiments, the etching process is configured to stop upon reaching and/or exposing gate electrodes 728. The etching process is a dry etch, a wet etch, other suitable etch, or a combination thereof. One or more deposition processes may then be performed to form a gate contact material (e.g., one or more electrically conductive layers) over dielectric layer 340 that fills the first gate contact opening and the second gate contact opening. A planarization process may be performed to remove excess gate contact material, such as gate contact material over a top surface of dielectric layer 340. A remainder of contact material that fills the first gate contact opening and the second gate contact opening may provide gate contact 350A and gate contact 350B, respectively.

In FIG. 52 and FIGS. 53A-53C, multigate device 700 includes transistors. For example, a transistor in transistor region 202A includes respective channel layers 220′, epitaxial source/drains 275A, and gate 738A, a transistor in transistor region 202B includes respective channel layers 220′, epitaxial source/drains 275B, and gate 738B, and a transistor in transistor region 202C includes respective channel layers 220′, epitaxial source/drains 275C, and gate 738C. Gate contact 350A electrically connects gates of the transistors in transistor region 202A and transistor region 202B, such as gate 738A and gate 738B. Gate contact 350B may electrically connect the gate of the transistor in transistor region 202C, such as gate 738C, to a gate of another transistor in an adjacent transistor region. In the depicted embodiment, transistors are separated and/or isolated by two types of gate isolation walls-gate isolation walls 710 (which are formed in in-cell regions 228A between electrically connected gates of transistors) and gate isolation walls 330 (which are formed in boundary regions 228B between electrically isolated gates of transistors). For example, in transistor region 202B, gate 738B of the transistor is separated from gate 738A (which is electrically connected to gate 738B by gate contact 350A) by gate isolation wall 710, and gate 738B is separated from gate 738C (which is not electrically connected to gate 738B) by gate isolation wall 330. In other words, gates of adjacent transistors in a same cell, such as a same logic cell or a same memory cell, may be separated and/or isolated by gate isolation walls 710 in in-cell regions 228A, and gates of adjacent transistors in different cells, such as different logic cells or different memory cells, may be separated and/or isolated by gate isolation walls 330 in boundary regions 228B.

Each gate (e.g., gate 738B) is disposed between respective epitaxial source/drains (e.g., epitaxial source/drains 275B) along the x-direction, and inner spacers 262 are disposed between each gate and its respective epitaxial source/drains. Further, each gate (e.g., gate 738B) engages respective channel layers (e.g., channel layer 220′ in transistor region 202B), and the respective channel layers extend between respective epitaxial source/drains (e.g., epitaxial source/drains 275B) along the x-direction. Each gate (e.g., gate 738B) surrounds its respective channel layers. In the Y-Z plane, each gate has a gate dielectric (e.g., gate dielectric 722 of gate 738B) that surrounds its respective channel layers, a gate electrode (e.g., gate electrode 728 of gate 738B) disposed along tops and bottoms of its respective channel layers, and a gate endcap (e.g., gate endcap 325 of gate 738B) along sidewalls of its respective channel layers, sidewalls of its respective gate electrode, and sidewalls of its respective gate dielectric. In the X-Z plane, each gate has a high-k dielectric layer of the gate dielectric (e.g., high-k dielectric layer 726 of gate 738B) that surrounds its respective gate electrode and an interfacial layer (e.g., interfacial layer 724 of gate 738B) disposed between the high-k dielectric layer and its respective channel layers. Further, each gate (e.g., gate 738B) has a gate helmet (e.g., gate helmet 264) disposed thereover, where the gate helmet is disposed over a top portion (e.g., portion 728A of gate 738B) of a respective gate electrode. A portion of its gate dielectric (e.g., high-k dielectric layer 726 of gate 738B) wraps a corner of the gate helmet, is disposed between the gate helmet and the top portion of the respective gate electrode, is disposed between the gate helmet and the respective gate endcap, and is disposed between the gate helmet and a respective gate isolation wall 330.

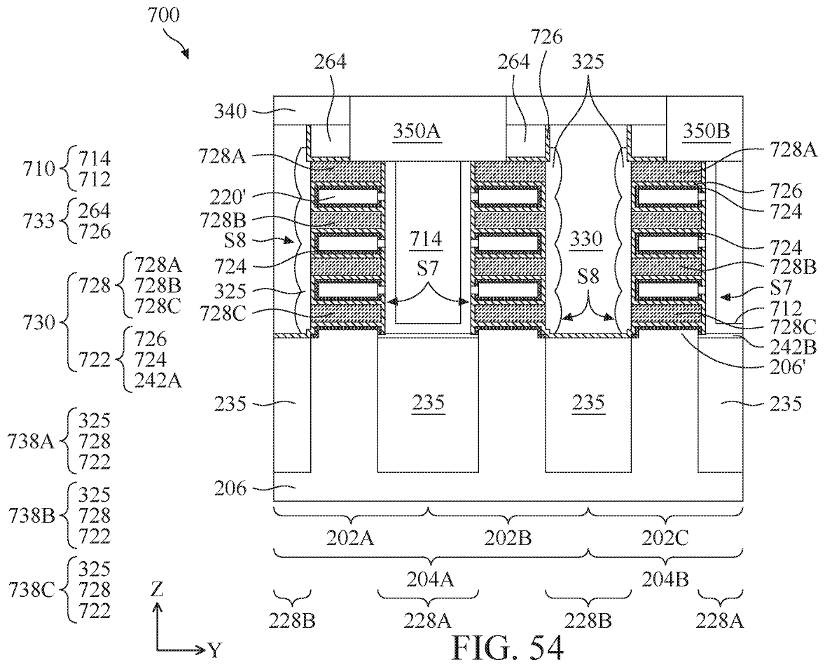

Each of gates 738A-738C has a sidewall S7 and a sidewall S8. Sidewall S7 is formed by a respective gate dielectric 722 (e.g., high-k dielectric layer 726 and respective dummy gate dielectric portions 242A), and sidewall S8 is formed by a respective gate endcap 325. In such embodiments, sidewalls 732A of gate stacks 730 are separated from respective gate isolation walls 330 by respective gate endcaps 325, and sidewalls 732B of gate stacks 730 are not separated from and physically contact respective gate isolation walls 710. Gate contact 350A and gate contact 350B extend through gate helmets 264, extend over sidewalls S7 of gates 738A-738C, physically contact high-k dielectric layer 726, physically contact portions 728A, and physically contact gate isolation walls 710. Further, gate isolation walls 710 are disposed between a respective pair of sidewalls S7, and gate isolation walls 330 are disposed between a respective pair of sidewalls S8. In the depicted embodiment, sidewalls S8 are substantially linear, and gate endcaps 325 have rectangular profiles/shapes. In some embodiments, such as depicted in FIG. 54, sidewalls S8 are wavy, and gate endcaps 325 have scalloped profiles/shapes. In such embodiments, gate endcaps 325 have curved segments that interface with gate isolation walls 330. Different sidewall profiles, such as wavy sidewalls, may occur because of deposition/growth variations of selective deposition processes.

In the depicted embodiment, gates 738A-738C have pi-gate (Π-gate) portions formed by portions of high-k dielectric layers 306 that are between channel layers 220′ and wrap portions 728A-728C. For example, gates 738A-738C have two Π-gate portions formed by respective portions of high-k dielectric layer 726 that wrap respective portions 728B thereof and a Π-gate portion formed by a respective portion of high-k dielectric layer 726 that wraps portion 728C thereof. For example, each Π-gate portion of high-k dielectric layer 726 is disposed on a top, a bottom, and a sidewall of a respective portion 728B or a respective portion 728C (e.g., a sidewall thereof facing gate isolation wall 710). Each Π-gate portion of high-k dielectric layer 726 further vertically extends beyond the top and the bottom of the respective portion 728B or the respective portion 728C to dummy gate dielectric portions 242A, such that each Π-gate portion of high-k dielectric layer 726 overlaps sidewalls of channel layers 220′. Π-gate portions of high-k dielectric layer 726 may laterally extend a distance d3 (e.g., along the y-direction) from sidewalls of channel layers 220′ and vertically extend a distance d4 (e.g., along the z-direction) along sidewalls of channel layers 220′. Distance d3 is between sidewalls of channel layers 220′ and surfaces of Π-gate portions of high-k dielectric layer 726 that form sidewalls S7. Distance d3 may also be considered between sidewalls of channel layers 220′ and sidewalls of gate isolation walls 710. Distance d4 is between tops (or bottoms) of channel layers 220′ and ends of Π-gate portions of high-k dielectric layer 726, which interface with dummy gate dielectric portions 242A. Distance d4 may also be considered between tops (or bottoms) of channel layers 220′ and dummy gate dielectric portions 242A. In some embodiments, distance d3 is about 0.1 nm to about 5 nm. In some embodiments, distance d4 is about 0.1 nm to about 2.5 nm. The trimming process of dummy gate dielectric 242 (in FIG. 335) may be tuned to achieve desired lateral extension and/or desired vertical extension of Π-gate portions of high-k dielectric layer 726 relative to channel layers 220′. Π-gate portions may improve short channel effect (SCE) control of transistors in transistor regions 202A-202C and/or of multigate device 700.

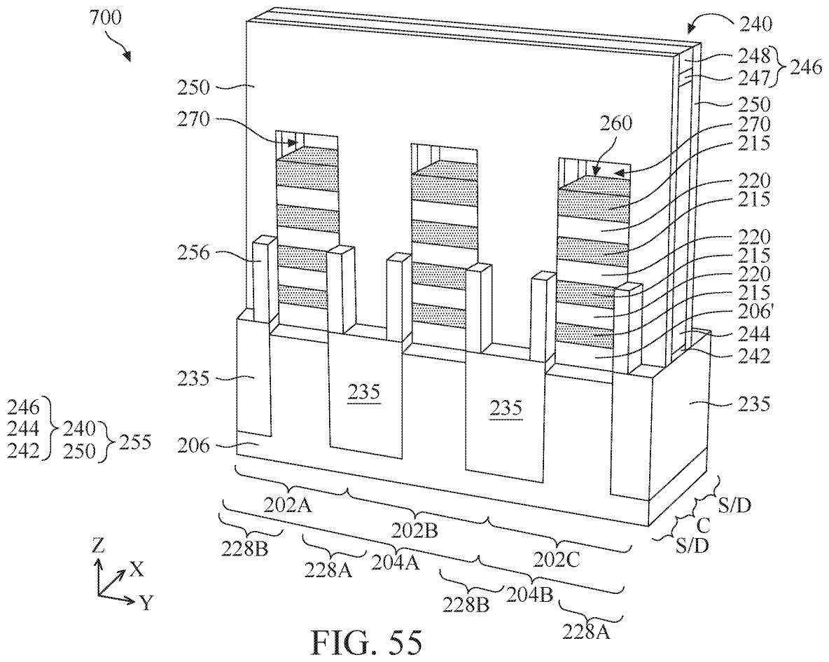

In FIGS. 34-52 and FIGS. 53A-53C, gate helmets 264 are formed at the same time as inner spacers 262. For example, gate helmets 264 and inner spacers 262 are formed by selectively etching semiconductor layers 225 and semiconductor layers 215 to form gaps 266, gaps 268, and gaps 270 (FIG. 37); depositing one or more dielectric layers to fill gaps 266, gaps 268, and gaps 270 (FIG. 38); and selectively etching the one or more dielectric layers, such that remainders of the one or more dielectric layers form gate helmets 264 and inner spacers 262 (FIG. 38). In some embodiments, gate helmets 264 may be formed before or after inner spacers 262. For example, instead of forming gate helmets 264 and inner spacers 262 as depicted and described with reference to FIG. 37 and FIG. 38, gate helmets 264 may be formed before inner spacers 262 as depicted and described with reference to FIGS. 55-58.

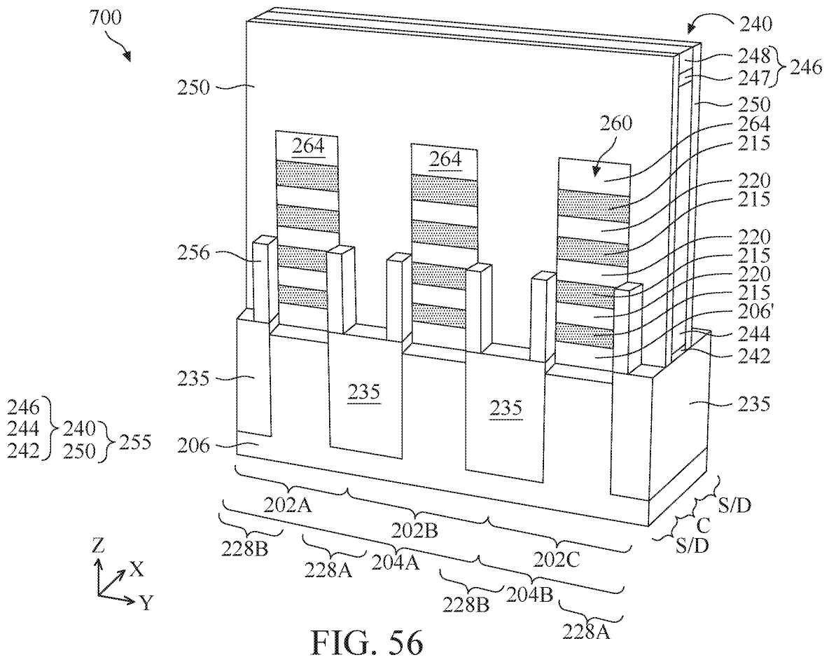

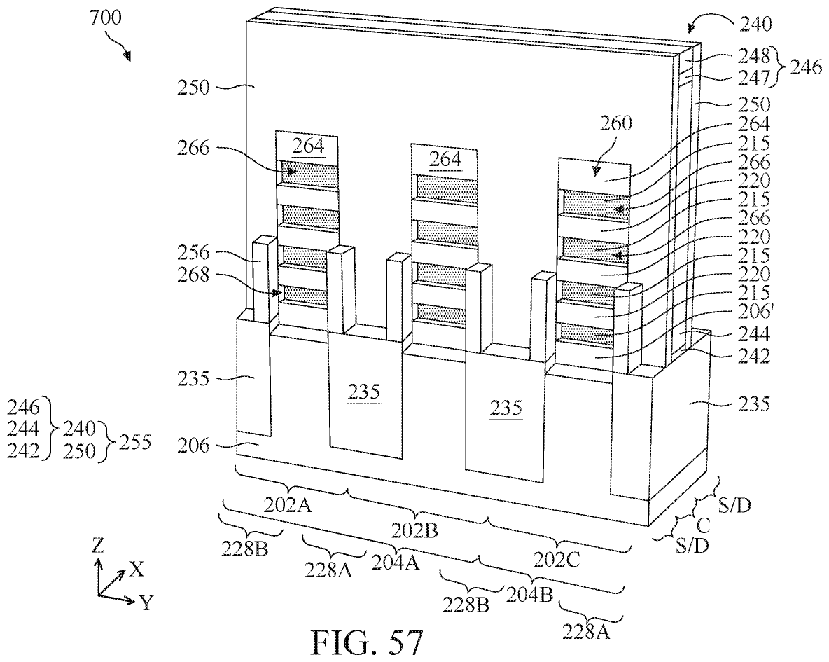

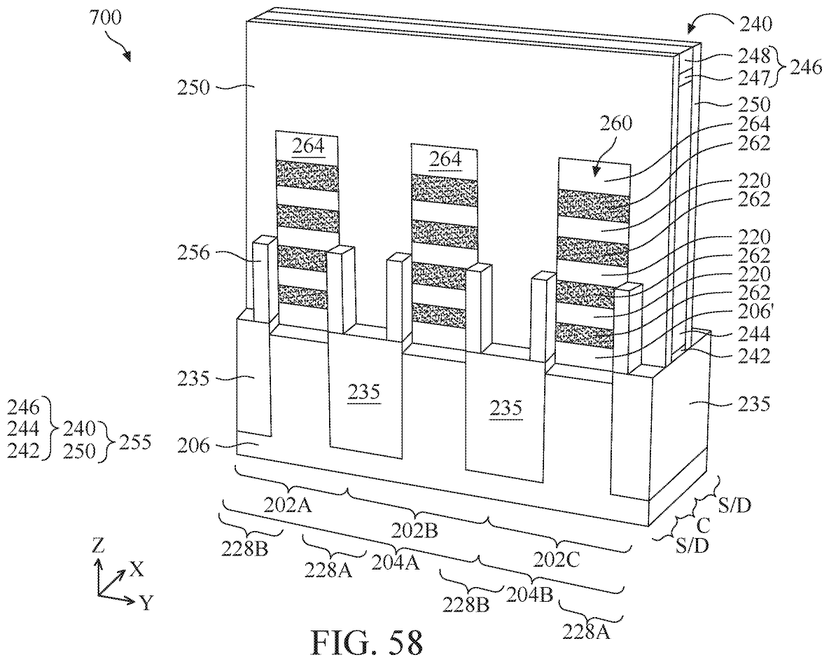

FIGS. 55-58 are fragmentary perspective views of multigate device 700 at various fabrication stages associated with forming gate helmets 264 and inner spacers 262 according to various aspects of the present disclosure. In such embodiments, multigate device 700 has undergone processing associated with FIGS. 34-36 (FIG. 55), multigate device 700 is processed to form gate helmets 264 (FIG. 55 and FIG. 56), multigate device 700 is processed to form inner spacers 262 (FIG. 57 and FIG. 58), and multigate device 700 may undergo processing associated with FIGS. 39-52 after forming gate helmets 264 and inner spacers 262. Processing may include selectively etching semiconductor layers 225 to form gaps 270 (FIG. 55); depositing one or more dielectric layers over multigate device 700 that fill gaps 270 (FIG. 56); and selectively etching the one or more dielectric layers, such that remainders of the one or more dielectric layers form gate helmets 264 (FIG. 56). Processing may then include selectively etching semiconductor layers 215 to form gaps 266 and gaps 268 (FIG. 57); depositing one or more dielectric layers over multigate device 700 that fill gaps 266 and gaps 268 (FIG. 58); and selectively etching the one or more dielectric layers, such that remainders of the one or more dielectric layers form inner spacers 262 (FIG. 58). In some embodiments, a composition of gate helmets 264 is different than a composition of inner spacers 262. In some embodiments, processing associated with FIG. 55 and FIG. 56 may be performed after processing associated with FIG. 57 and FIG. 58 to form gate helmets 264 after inner spacers 262. In such embodiments, multigate device 700 includes semiconductor layers 225 when forming inner spacers 262 and inner spacers 262 when forming gate helmets 264. FIGS. 55-58 have been simplified for the sake of clarity to better understand the inventive concepts of the present disclosure. Additional features may be added in multigate device 700 in FIGS. 55-58, and some of the features described below may be replaced, modified, or eliminated in other embodiments of multigate device 700 in FIGS. 55-58.

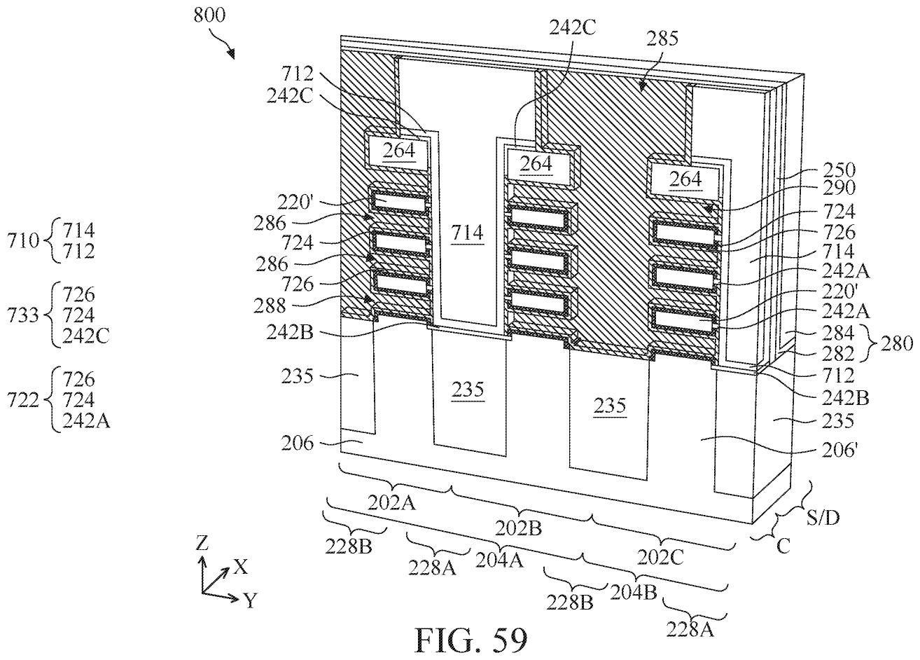

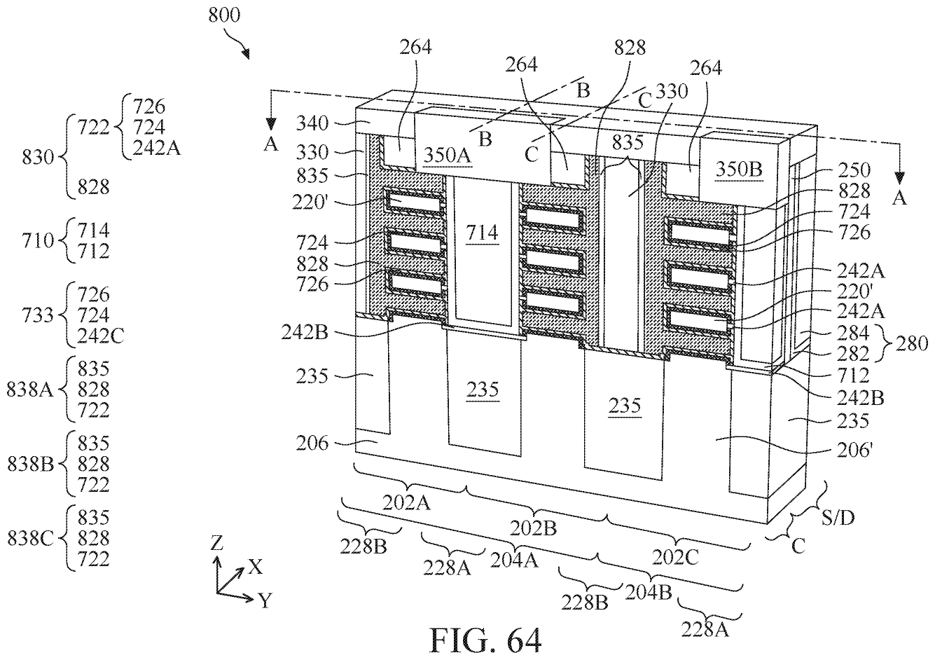

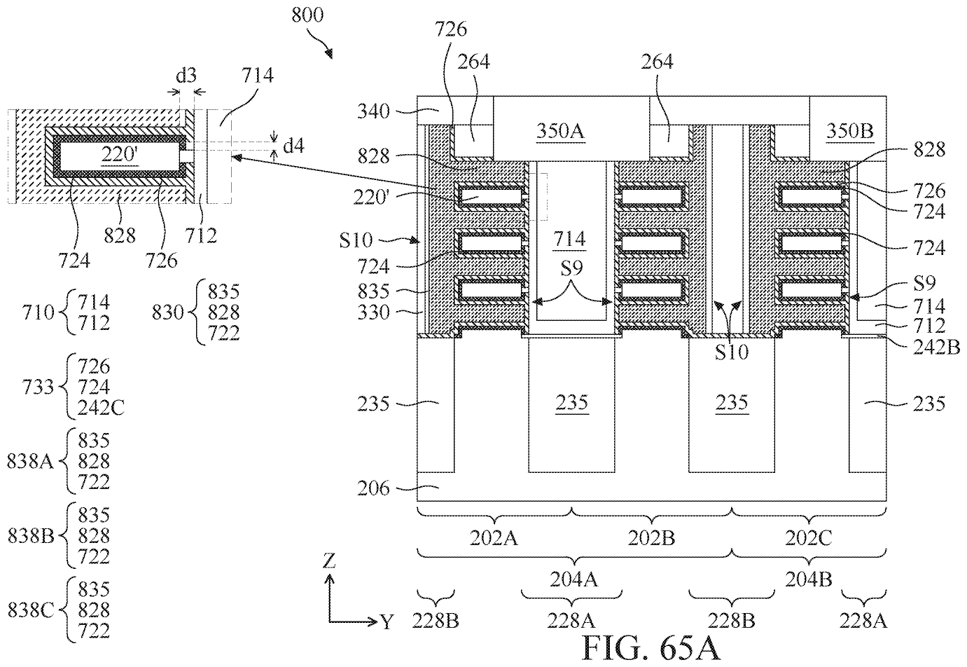

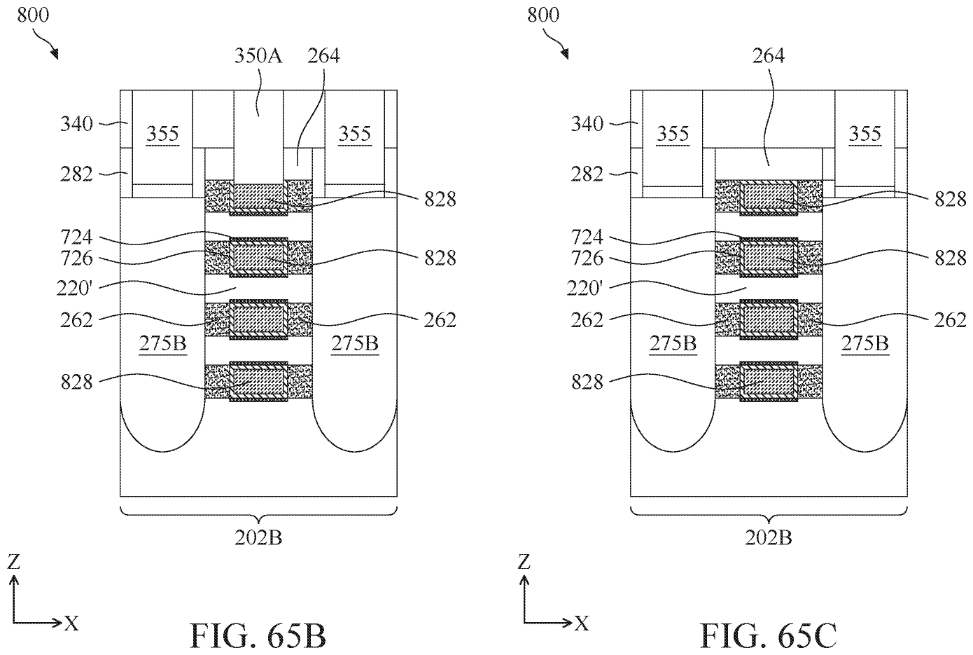

In FIGS. 34-52 and FIGS. 53A-53C, gate electrodes 728 are disposed on tops and bottoms of channel layers 220′, but not along sidewalls of channel layers 220′, and gate electrodes 728 include discrete portions 728A-728C that are electrically connected by gate endcaps 325. In some embodiments, processing may be configured to provide gate electrodes that wrap channel layers 220′, such as where the gate electrodes are disposed on tops, bottoms, and a side of channel layers 220′, such as depicted and described with reference to FIGS. 59-64. FIGS. 59-64 are fragmentary perspective views of a multigate device 800 at various fabrication stages, such as those associated with method 600 of FIG. 33, according to various aspects of the present disclosure. FIG. 65A, FIG. 65B, and FIG. 65C are cross-sectional views of multigate device 800 along line A-A, line B-B, and line C-C, respectively, of FIG. 64 (e.g., a y-cut view and x-cut views), in portion or entirety, according to various aspects of the present disclosure. FIGS. 59-64 and FIGS. 65A-65C have been simplified for the sake of clarity to better understand the inventive concepts of the present disclosure. Additional features may be added in multigate device 800, and some of the features described below may be replaced, modified, or eliminated in other embodiments of multigate device 800.

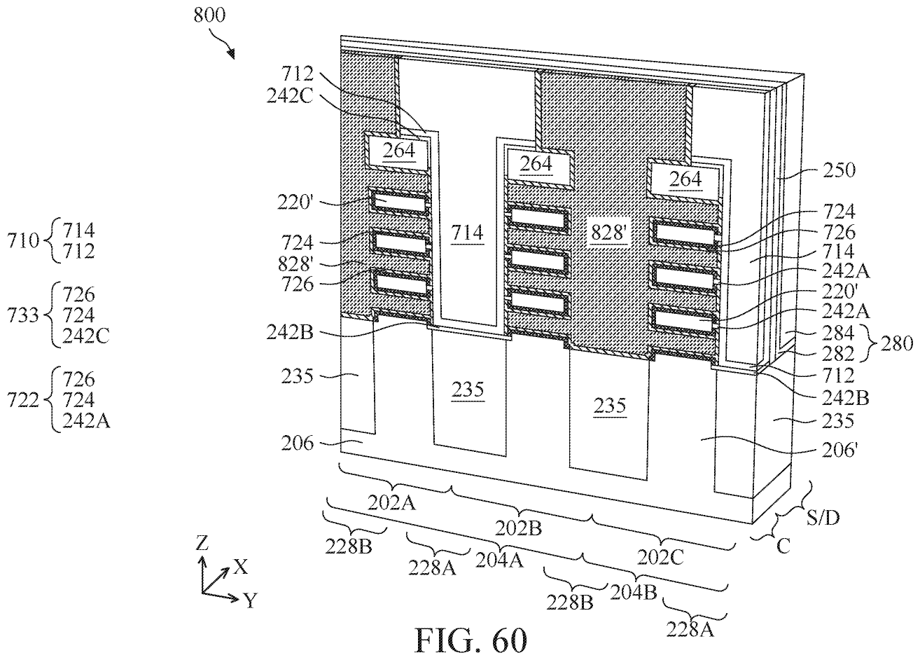

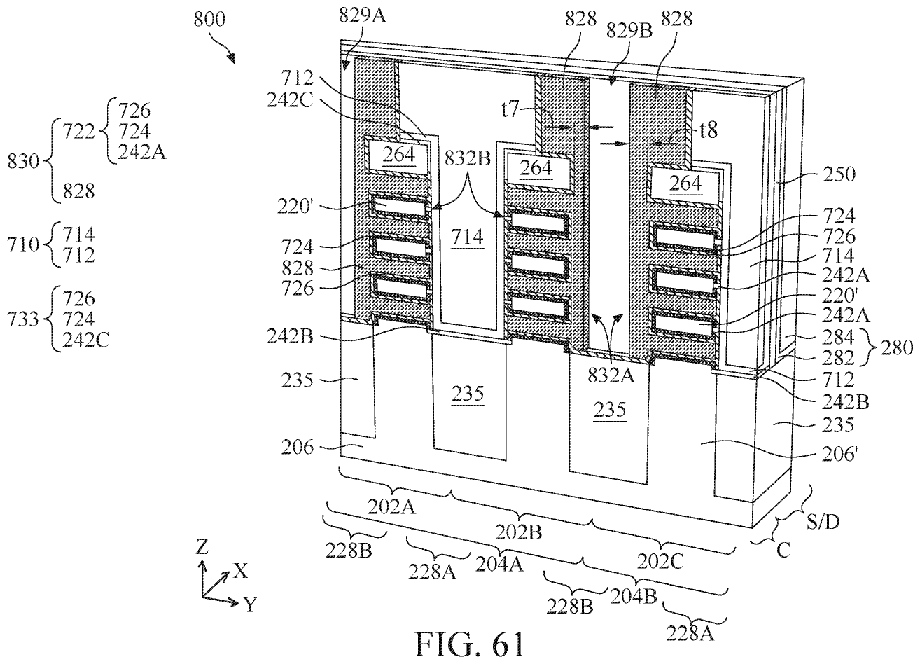

Fabrication of multigate device 800 is similar in many respects to fabrication of multigate device 700. For example, in FIG. 59, multigate device 800 has undergone processing associated with FIGS. 34-48 to form gate isolation walls 710 and gate dielectric 722 (including dummy gate dielectric portions 242A, interfacial layer 724, and high-k dielectric layer 726) partially filling gate opening 285. In FIGS. 60-63, instead of forming gate electrodes 728 that partially fill gate opening 285, processing includes forming gate electrode layers 828′ that fill a remainder of gate opening 285 (FIG. 60) and performing a gate cut process to form gate cut openings (e.g., a gate cut opening 829A and a gate cut opening 829B) that extend through gate electrode layers 828′ in boundary regions 228B to form respective gate electrodes 828 in transistor regions 202A-202C (FIG. 61). In FIG. 60, forming gate electrode layers 828′ may include depositing a gate electrode material over multigate device 800 that fills a remainder of gate opening 285 (including remainders of gaps 286, gaps 288, and gaps 290) and performing a planarization process. The planarization process (e.g., CMP) removes any of the gate electrode material from over tops of gate isolation walls 710, dielectric layer 280, gate spacers 250, or a combination thereof. To disconnect gate electrodes 828 of different transistor regions within a device region (e.g., of transistor region 202A and transistor region 202B in device region 204A), the planarization process may be performed until reaching and exposing gate isolation walls 710. In some embodiments, gate isolation walls 710 function as a planarization stop layer.

In FIG. 61, the gate cute process may include a lithography process and an etching process. In some embodiments, the lithography process includes forming a patterned mask layer over multigate device 800 that partially exposes gate electrode layers 828′, partially covers gate electrode layers 828′, and covers gate isolation walls 710. For example, the patterned mask layer may have openings therein that expose portions of gate electrode layers 828′ in boundary regions 228B that are located proximate to interfaces of transistor regions (e.g., proximate an interface between transistor region 202B and transistor region 202C). In some embodiments, the etching process includes removing exposed portions of gate electrode layers 828′ to form gate cut opening 829A and gate cut opening 829B in boundary regions 228B and proximate to interfaces between transistor regions. The etching process may use the patterned mask layer as an etch mask, such that gate cut opening 829A and gate cut opening 829B correspond with a first opening and a second opening, respectively, in the patterned mask layer. The etching process may selectively remove metal materials (e.g., gate electrode layers 828′) with negligible removal of dielectric materials (e.g., gate dielectric 722, such as high-k dielectric layer 726 thereof). The etching process is a dry etch, a wet etch, other suitable etch, or a combination thereof.

In such embodiments, each of transistor regions 202A-202C has a respective gate stack 830. Each gate stack 830 includes a respective gate dielectric 722 and a respective gate electrode 828. In the depicted embodiment, high-k dielectric layer 726 spans boundary regions 228B, such that gate stacks 830 of transistor regions at boundary regions 228B (e.g., transistor region 202B and transistor region 202C and/or transistor region 202A and an adjacent transistor region to its left) may share high-k dielectric layer 726 (e.g., high-k dielectric layer 726 may extend uninterrupted from transistor region 202B to transistor region 202C), but have separate, respective interfacial layers 304 and separate, respective gate electrodes 828. Because multigate device 800 is fabricated by implementing a gate cut process to disconnect gates at boundary regions 228B (instead of a deposition and etch back process as described with respect to fabricating multigate device 700) and gate isolation walls 710 are formed before removing dummy gate dielectric 242 and forming gate stacks 830, each gate stack 830 has a respective sidewall 832A and a respective sidewall 832B. Sidewall 832A faces a respective boundary region 228B, and sidewall 832B faces a respective in-cell region 228A (i.e., its gate isolation wall facing sidewall). Sidewall 832A is formed by a respective gate electrode 828, instead of both a respective gate dielectric (e.g., high-k dielectric layer thereof) and a respective gate electrode. Sidewall 832B is formed by a respective gate dielectric (e.g., high-k dielectric layer 726 and dummy gate dielectric portions 242A thereof).

Further, in multigate device 800, gate electrodes 828 wrap channel layers 220′, such that gate electrodes 828 are disposed along top surfaces, bottom surfaces, and a sidewall surface of channel layers 220′. For example, each gate electrode 828 has a first portion disposed between a respective gate helmet 264 and a respective top channel layer 220′ (filling a remainder of gap 290), second portions disposed between respective channel layers 220′ (filling remainders of gaps 286), a third portion disposed between a respective bottom channel layer 220′ and a respective mesa 206′ (filling a remainder of gap 288), and a sidewall portion that extends along sidewalls of channel layers 220′. The sidewall portion extends from the third portion to the second portions to the first portion, such that the third portion, the second portions, and the first portion are connected by the sidewall portion of gate electrode 828, instead of a gate endcap. In some embodiments, the sidewall portion may extend below a top surface of respective mesa 206′, such as depicted. In some embodiments, the sidewall portion may extend above a top surface of respective gate helmet 264, such as depicted. In some embodiments, a portion of each gate electrode 828 is disposed above a top surface of a respective gate helmet 264 and adjacent to a respective gate isolation wall 710, such that gate electrode 828 wraps gate helmet 264.

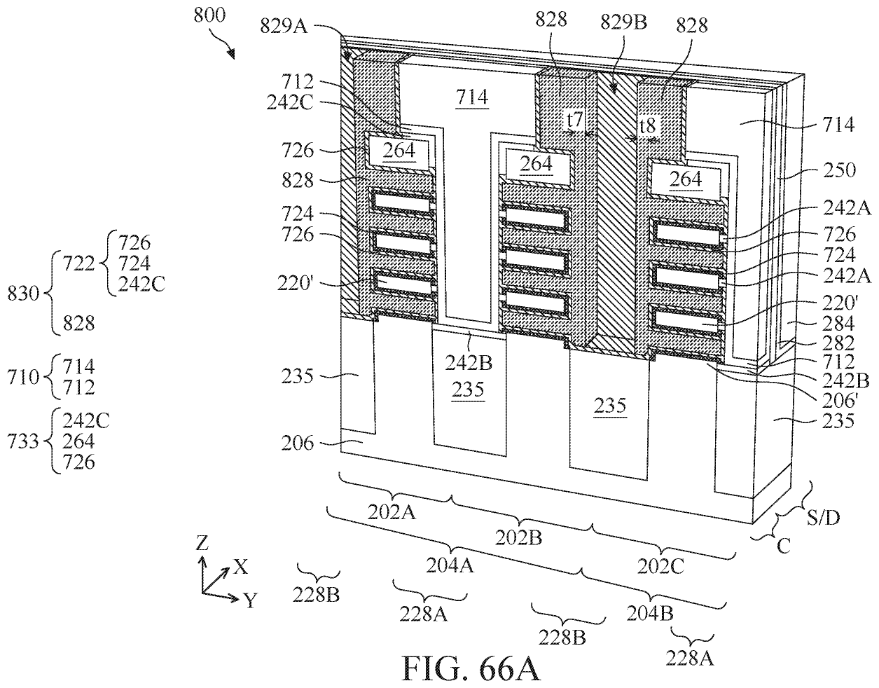

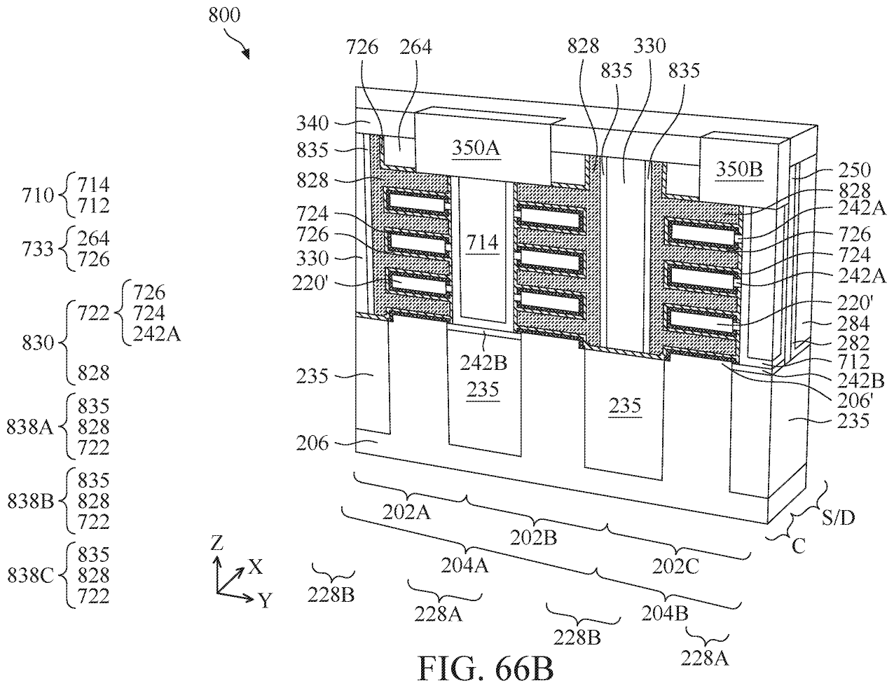

Overlay shift/variations during the lithography processes used to form the patterned mask layer may result in the openings in the patterned mask layer, and thus gate cut opening 829A and/or gate opening 829B, being shifted left or right of an interface between the transistor regions in boundary regions 228B. This results in sidewall portions of gate electrodes 828 (which may also be referred to as gate electrode end caps) having different thicknesses along sidewalls of channel layers 220′. For example, in FIG. 61, a sidewall portion of gate electrode 828 in transistor region 202B has a thickness t7, a sidewall portion of gate electrode 828 in transistor region 202C has a thickness t8, and thickness t7 is less than thickness t8, which may result from a leftward shift of gate cut opening 829B. In some embodiments, thickness t7 is about 1 nm to about 20 nm. In some embodiments, thickness t8 is about 1 nm to about 20 nm. In some embodiments, thickness t7 is greater than thickness t8, which may result from a rightward shift of gate cut opening 829B. In some embodiments, such as depicted in FIG. 66A, thickness t7 is about the same as thickness t8, which may result from minimal shift of gate cute opening 829B, such as where gate cut opening 829B is located in a middle of boundary region 228B (e.g., gate cute opening 829 is center aligned with isolation feature 235 in boundary region 228B and/or with an interface between transistor region 202B and transistor region 202C).

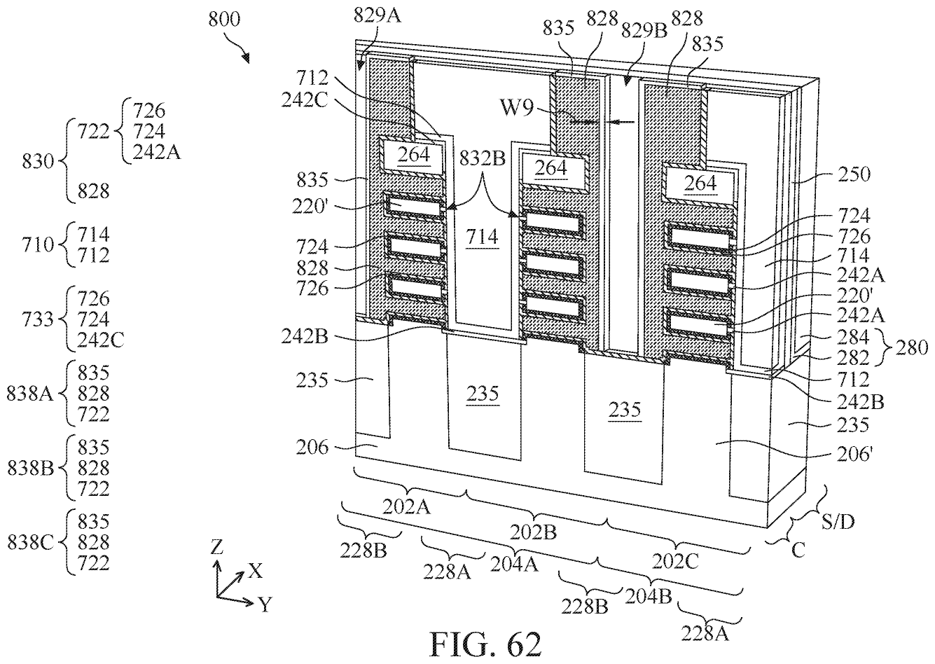

In FIG. 62, fabrication of multigate device 800 may include forming gate endcaps 835 on exposed sidewalls 832A of gate stacks 830. Gate endcaps 835 partially fill the gate cut openings (e.g., gate cut opening 829A and gate cut opening 829B). In such embodiments, a gate 838A is provided in transistor region 202A, a gate 838B is provided in transistor region 202B, and a gate 838C is provided in transistor region 202C. Each of gates 838A-838C includes a respective gate stack 830 (e.g., a respective gate dielectric 722 and a respective gate electrode 828) and a respective gate endcap 835 forming a sidewall thereof. Gate endcaps 835 are similar to gate endcaps 325, and gate endcaps 835 may include materials and/or configurations similar to and be formed in a manner similar to that described above with reference to FIG. 50. For example, gate end caps 835 may include tungsten, ruthenium, molybdenum, alloys thereof, or a combination thereof, and gate electrodes 828 may include titanium (e.g., TiN, TiAl, TiAIC, or a combination thereof). In some embodiments, gate electrodes 828 are work function layers.

Gate endcaps 835 cover sidewalls 832A of gate stacks 830, which are formed by gate electrodes 828. In multigate device 800, because gate electrodes 828 wrap channel layers 220′ and gate helmets 264, gate endcaps 835 are disposed along sidewalls of channel layers 220′, disposed along sidewalls of gate helmets 264, and separated from channel layers 220′ and gate helmets 264 by gate dielectrics 722 and gate electrodes 828. Further, gate endcaps 835 may extend below top surfaces of mesas 206′ and along sidewalls thereof, gate endcaps 835 may extend above top surfaces of gate helmets 264 and along sidewalls thereof, and gate dielectrics 722 and gate electrodes 828 may be between mesas 206′ and gate endcaps 835. In some embodiments, gate endcaps 835 do not extend below top surfaces of mesas 206′. In some embodiments, gate endcaps 835 do not extend above top surfaces of gate helmets 264.

Gate endcaps 835 have a width w9 (e.g., along the y-direction) along sidewalls 832A of gate stacks 830. In some embodiments, width w9 is about 2 nm to about 5 nm. Because gate electrodes 828 wrap channel layers 220′ and are formed by a gate cut process, gate helmet structures 733 may not overhang gate electrodes 828, and width w9 may be substantially uniform along a length of gate endcaps 835 (e.g., along the z-direction). In some embodiments, width w9 may vary along the length of gate endcaps 835.

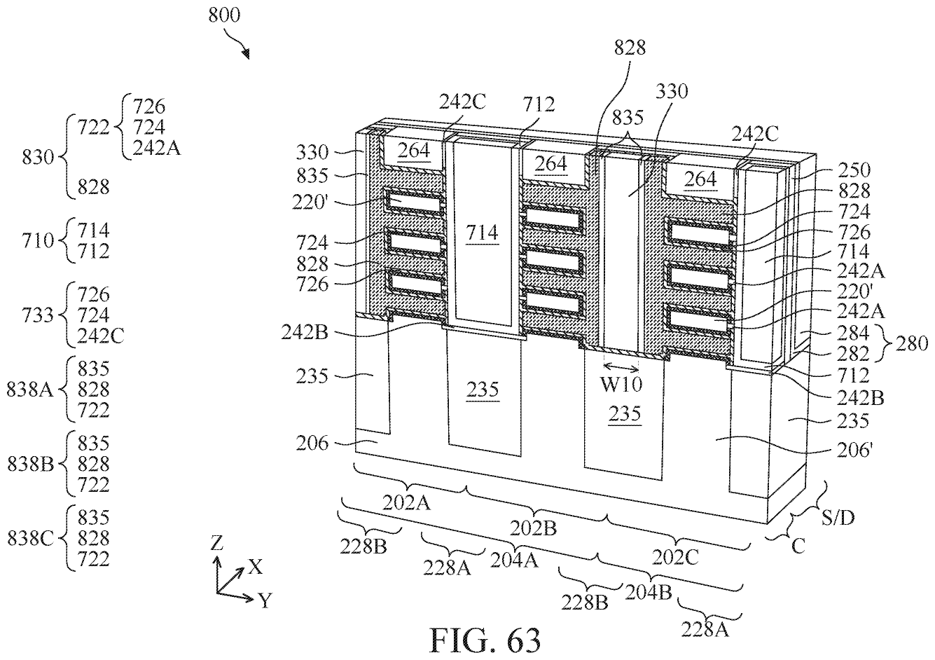

In FIG. 63, fabrication of multigate device 800 may include forming gate isolation walls 330 between gates 838A-838C that fill a remainder of the gate cut openings (e.g., gate cut opening 829A and gate cut opening 829B). Gate isolation walls 330 fill spaces between gates 838A-838C, and gate isolation walls 330 are disposed between gate endcaps 835 of adjacent gates 838A-838C (e.g., one of gate isolation walls 330 is between a respective gate endcap 835 of gate 838B and a respective gate endcap 835 of gate 838C). Gate isolation walls 330 may fill spaces between adjacent gate helmets 264. In the depicted embodiment, both gate electrode 828 and high-k dielectric layer 726 are disposed between gate isolation walls 330 and gate helmets 264, and gate isolation walls 330 have a width w10 (e.g., along the y-direction) that is less than width w8. In some embodiments, width w10 is about 5 nm to about 600 nm. Because gates 838A-838C are fabricated using a gate cut process, gate isolation walls 330 may have rectangular-shaped profiles, such as depicted in FIG. 63. In such embodiments, width w10 of gate isolation walls 330 is substantially uniform along its height (e.g., along the z-direction).

Gate isolation walls 330 may be formed in a manner similar to that described above with reference to FIG. 51. For example, gate isolation walls 330 may be formed by depositing a dielectric material (e.g., silicon nitride) over multigate device 800 that fills a remainder of the gate cut openings (e.g., gate cut opening 829A and gate cut opening 829B) and performing a planarization process. The planarization process, such as CMP, is performed until reaching and exposing gate helmets 264, such that top surfaces of gate helmets 264 are free of gate electrodes 828, high-k dielectric layer 726, and dummy gate dielectric portions 242C. In some embodiments, gate helmets 264 may function as a planarization stop layer. In some embodiments, the planarization process removes any of the dielectric material (e.g., high-k dielectric layer 726, gate isolation walls 710, ILD layer 284, CESL 282, gate spacers 250, or a combination thereof) disposed above and/or over top surfaces of gate helmets 264, and remainders of the dielectric material form gate isolation walls 330.

In FIG. 64 and FIGS. 65A-65C, fabrication of multigate device 800 may include forming gate contacts, such as gate contact 350A and gate contact 350B, to gates 838A-838C in a manner similar to that described above with reference to FIG. 52 and FIGS. 53A-53C. In the depicted embodiment, each of gates 838A-838C has a sidewall S9 formed by its respective gate stack 830 (e.g., gate dielectric 722 thereof) and a sidewall S10 formed by a respective gate endcap 835. In such embodiments, sidewall 832B of each gate stack 830 physically contacts a respective gate isolation wall 710, and sidewall 832A of each gate stack 830 is separated from a respective gate isolation wall 330 by a respective gate endcap 835. In the depicted embodiment, sidewalls S10 are substantially linear, and gate endcaps 835 have rectangular profiles/shapes. In some embodiments, sidewalls S10 are wavy, such as depicted and described with reference to FIG. 54, and gate endcaps 835 have scalloped profiles/shapes.

Gate isolation walls 330 may electrically isolate gates 838A-838C from one another. For example, gate 838B in transistor region 202B is separated and electrically isolated from gate 838C in transistor region 202C by a respective gate isolation wall 330, while being separated and electrically isolated from gate 838A in transistor region 202A by a respective gate isolation wall 710. Gate 838A in transistor region 202A may also be separated and electrically isolated from other active regions, such as a gate of an adjacent transistor region, by a respective gate isolation wall 330. Gate 838C in transistor region 202C may also be separated and electrically isolated from other active regions, such as a gate of an adjacent transistor region, by a respective gate isolation wall 710. In the depicted embodiment, gate isolation walls 330 are positioned leftward in boundary regions 228B, and thicknesses of gate electrode endcap portions adjacent to left sidewalls of gate isolation walls 330 are less than thicknesses of gate electrode endcap portions adjacent to right sidewalls of gate isolation walls 330. In some embodiments, such as depicted in FIG. 66B, gate isolation walls 330 are positioned in a middle/center of boundary regions 228B, and thicknesses of gate electrode endcap portions adjacent to left sidewalls of gate isolation walls 330 are about the same as thicknesses of gate electrode endcap portions adjacent to right sidewalls of gate isolation walls 330. In some embodiments, gate isolation walls 330 are positioned rightward in boundary regions 228B, and thicknesses of gate electrode endcap portions adjacent to left sidewalls of gate isolation walls 330 are greater than thicknesses of gate electrode endcap portions adjacent to right sidewalls of gate isolation walls 330.

In multigate device 800, gate contact 350A and gate contact 350B extend over sidewalls S9 of gates 838A-838C (i.e., sidewalls 832B of gate stacks 830 that physically contact gate isolation walls 710) and may not extend over and/or physically contact gate endcaps 835. Further, gate electrodes 828 may extend above bottoms of gate contact 350A and gate contact 350B, such as sidewall portions of gate electrodes 828 that extend along sidewalls of gate helmets 264. Gate contact 350A is disposed on tops of gate electrodes 828 of gate 838A and gate 838B, gate contact 350A is disposed on top of gate isolation wall 710 between gate 838A and gate 838B, gate contact 350A is disposed between gate helmets 264 overlying tops of gate electrodes 828 of gate 838A and gate 838B, and high-k dielectric layer 726 is disposed between gate helmets 264 and the tops of gate electrodes 828. Gate contact 350B is disposed on top of gate electrode 828 of gate 838C and an adjacent gate (e.g., in a transistor region adjacent to transistor region 202C), gate contact 350B is disposed on top of gate isolation wall 710 between gate 838C and the adjacent gate, gate contact 350B is disposed between gate helmets 264 overlying tops of gate electrodes 828 of gate 838C and the adjacent gate, and high-k dielectric layer 726 is disposed between gate helmets 264 and the tops of gate electrodes 828.

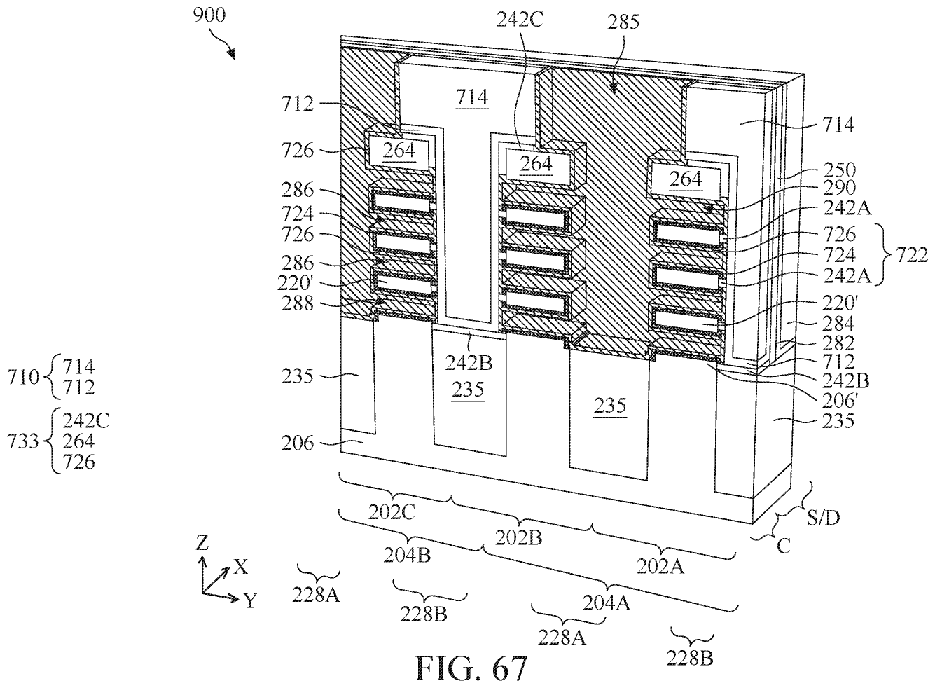

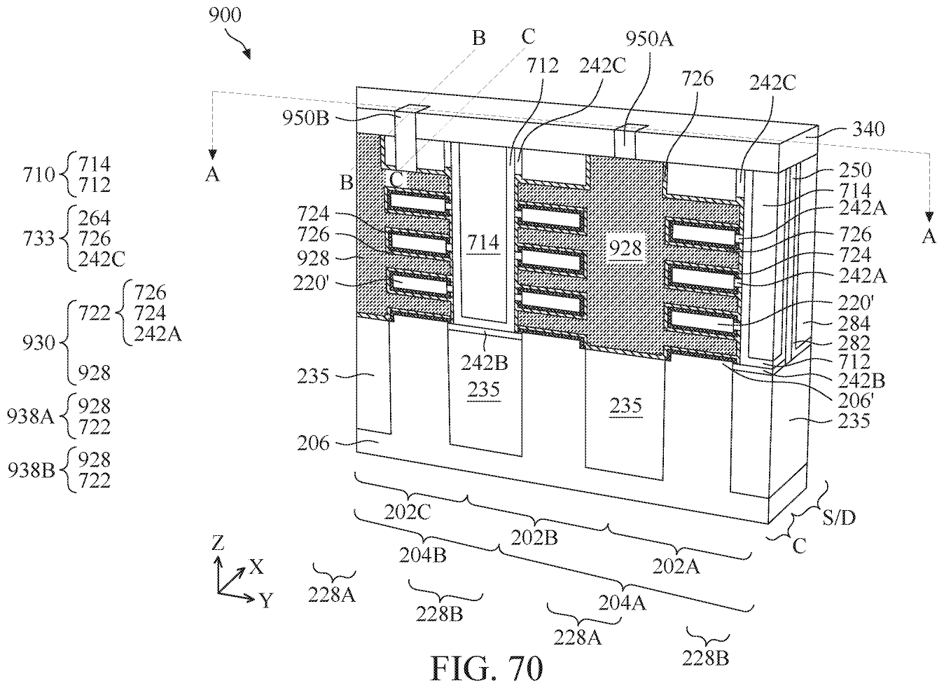

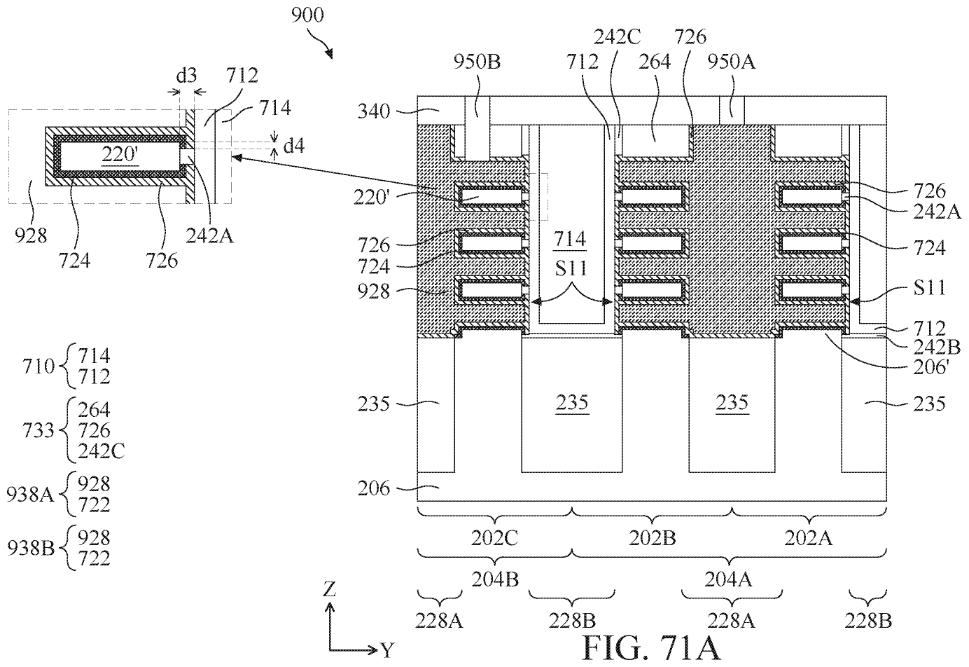

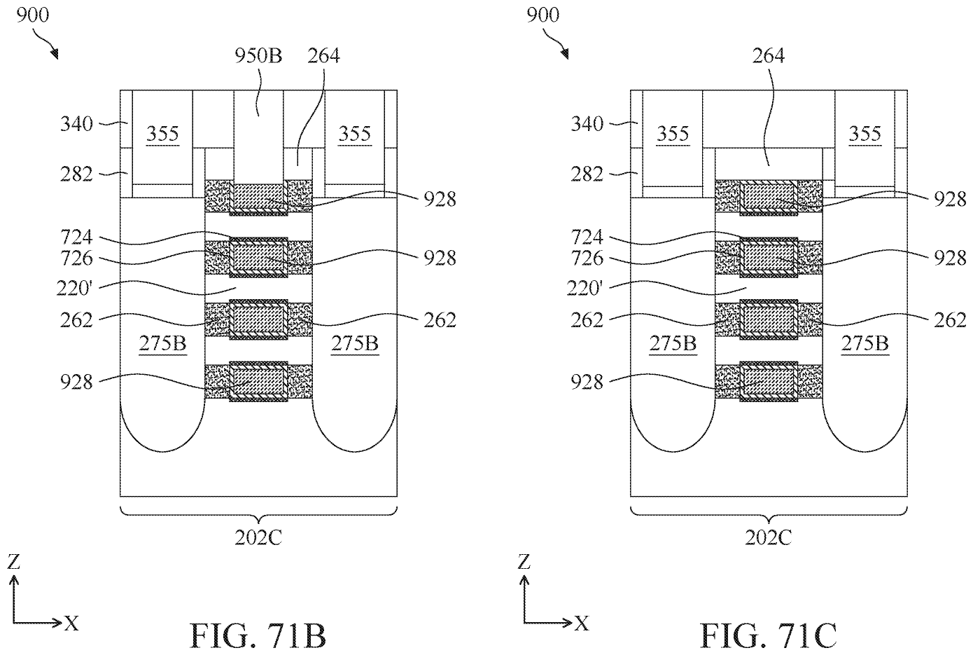

In multigate device 700 and multigate device 800, as described above, transistors are separated and/or isolated by gate isolation walls 710 (e.g., in in-cell regions 228A between electrically connected gates of transistors) and gate isolation walls 330 (e.g., in boundary regions 228B between electrically isolated gates of transistors). In such embodiments, the transistors are provided with separate gate electrodes. In some embodiments, processing may be configured to separate and/or isolate transistors with one type of gate isolation wall (e.g., gate isolation walls 710 in boundary regions 228B) and provide common gate electrodes and/or common gate dielectrics for adjacent transistors in a same cell, such as depicted and described with reference to FIGS. 67-70. In such embodiments, no gate isolation walls are provided in in-cell regions 228A. FIGS. 67-70 are fragmentary perspective views of a multigate device 900 at various fabrication stages, such as those associated with method 600 of FIG. 33, according to various aspects of the present disclosure. FIG. 71A, FIG. 71B, and FIG. 71C are cross-sectional views of multigate device 900 along line A-A, line B-B, and line C-C, respectively, of FIG. 70 (e.g., a y-cut view and x-cut views), in portion or entirety, according to various aspects of the present disclosure. FIGS. 67-70 and FIGS. 71A-70C have been simplified for the sake of clarity to better understand the inventive concepts of the present disclosure. Additional features may be added in multigate device 900, and some of the features described below may be replaced, modified, or eliminated in other embodiments of multigate device 900.

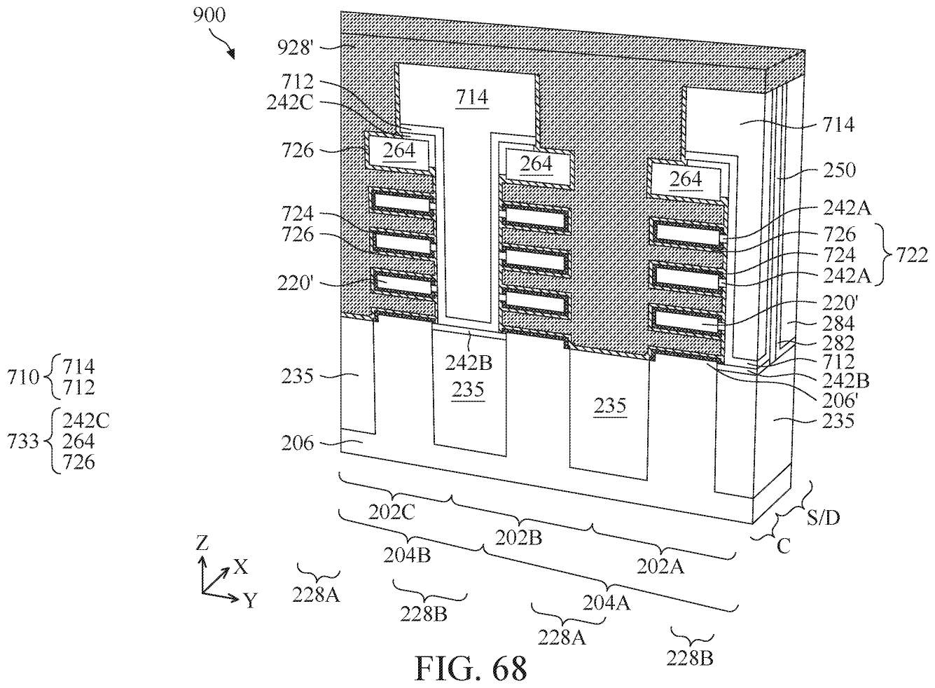

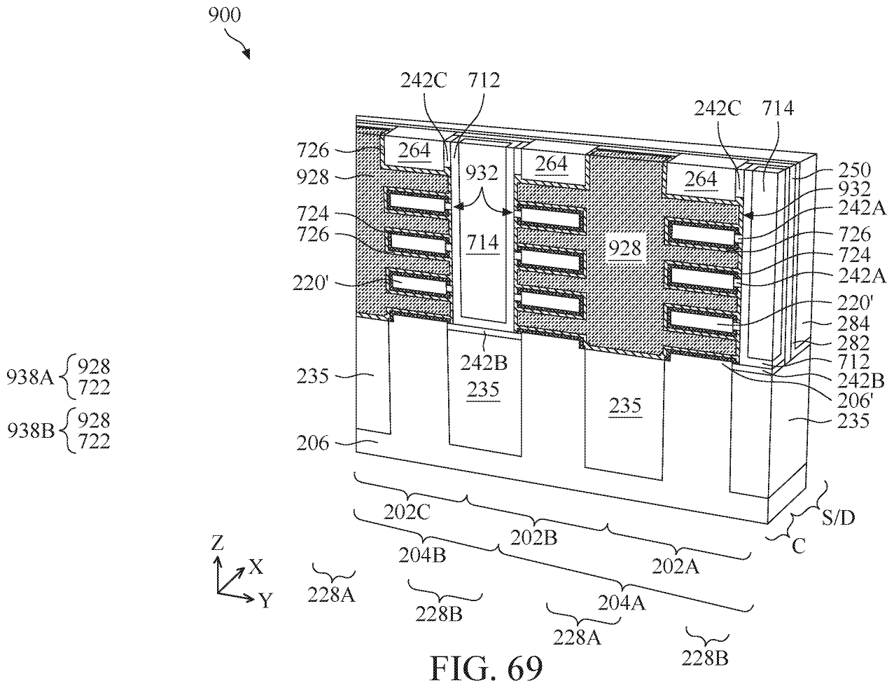

Fabrication of multigate device 900 is similar in many respects to fabrication of multigate device 700 and/or multigate device 800. For example, in FIG. 67, multigate device 900 has undergone processing similar to that associated with FIGS. 34-48 to form gate isolation walls 710 and gate dielectric 722 (including dummy gate dielectric portions 242A, interfacial layer 724, and high-k dielectric layer 726) partially filling gate opening 285. However, in multigate device 900, gate isolation walls 710 are formed in boundary regions 228B, instead of in in-cell regions 228A like in multigate device 700 and multigate device 800. In FIG. 67 and FIG. 68, instead of forming gate electrodes 728 that partially fill gate opening 285, processing includes forming gate electrodes 928 that fill a remainder of gate opening 285. Forming gate electrodes 928 may include depositing a gate electrode layer 928′ over multigate device 900 that fills a remainder of gate opening 285 (including remainders of gaps 286, gaps 288, and gaps 290) (FIG. 68) and performing a planarization process (FIG. 69). The planarization process (e.g., CMP) removes any of gate electrode layer 928′ from over tops of gate isolation walls 710, dielectric layer 280, gate helmets 264, gate spacers 250, or a combination thereof. To disconnect gate electrodes 928 of transistors adjacent to boundary regions 228B (e.g., of transistor region 202C in device region 204B and transistor region 202B in device region 204A), the planarization process may be performed until reaching and exposing gate isolation walls 710 and/or gate helmets 264. In some embodiments, gate isolation walls 710 function as a planarization stop layer. In some embodiments, gate helmets 264 function as a planarization stop layer.

In multigate device 900, a gate 938A is provided in device region 204A, and a gate 938B is provided in device region 204B. In such embodiments, gate 938A is a common gate to a transistor region 202A and transistor region 202B, and gate 938A forms a portion of a transistor of transistor region 202A and a transistor of transistor region 202B. Further, gate 938B is a common gate to transistor region 202C and a transistor region adjacent thereto (e.g., to the left), and gate 938B forms a portion of a transistor of transistor region 202C and a transistor of the transistor region adjacent thereto. Gate 938A and gate 938B each include a respective gate stack 930, and each gate stack 930 includes a respective gate dielectric 722 and a respective gate electrode 928. In the depicted embodiment, high-k dielectric layers 726 and gate electrodes 928 span in-cell regions 228A, such that gate stacks 930 of transistors adjacent to in-cell regions 228A (e.g., transistors of transistor region 202A and transistor region 202B and/or transistors of transistor region 202C and an adjacent transistor region to its left) may share high-k dielectric layers 726 and gate electrodes 928 (e.g., each may extend uninterrupted, and have separate, respective interfacial layers 304. Because gate isolation walls 710 are formed in boundary regions 228B, gate isolation walls 710 are formed before removing dummy gate dielectric 242 and forming gate stacks 930, and gate isolation walls 330 are not formed in in-cell regions 228A, each gate stack 930 has sidewalls 932 that face respective boundary regions 228B (i.e., gate isolation wall facing sidewalls). Sidewalls 932 are formed by a respective gate dielectric (e.g., high-k dielectric layer 726 and dummy gate dielectric portions 242A thereof), and sidewalls 932 physically contact gate isolation walls 710. In multigate device 900, gate stacks 930 may not have sidewalls in in-cell regions 228A, and gates (e.g., gate 938A and gate 938B) do not have gate endcaps, such as gate endcaps 325 and/or gate endcaps 835. In such embodiments, gates of adjacent transistors in different cells, such as different logic cells or different memory cells, and/or belonging to different devices and/or different device regions, may be separated and/or isolated by gate isolation walls 710 in boundary regions 228B, while adjacent transistors in a same cell, such as a same logic cell or a same memory cell, and/or belonging to same device region and/or same device, may share a gate (e.g., common gate electrode).

Further, in multigate device 900, gate electrodes 928 wrap channel layers 220′, such that gate electrodes 928 are disposed along top surfaces, bottom surfaces, and a sidewall surface of channel layers 220′. For example, each gate electrode 928 has a first portion disposed between a respective gate helmet 264 and a respective top channel layer 220′ (filling a remainder of gap 290), second portions disposed between respective channel layers 220′ (filling remainders of gaps 286), and a third portion disposed between a respective bottom channel layer 220′ and a respective mesa 206′ (filling a remainder of gap 288). Each gate electrode 928 also has a middle portion that fills a remainder of in-cell region 228A above isolation feature 235 and between channel layers 220′ of adjacent transistors, such as between channel layers 220′ of transistors in the same device region. For example, for gate 938A, the middle portion of gate electrode 928 is between channel layers 220′ of the transistor of transistor region 202A and channel layers 220′ of the transistor of transistor region 202B, and transistor region 202A and transistor region 202B are both in device region 204A. The middle portion extends along sidewalls of channel layers 220′ from the third portion to the second portions to the first portion, such that the third portion, the second portions, and the first portion are connected by the middle portion of gate electrode 928, instead of a gate endcap. In some embodiments, the middle portion may extend below a top surface of respective mesas 206′, such as depicted. In some embodiments, the middle portion may extend along sidewalls and be between respective gate helmets 264, such as depicted.

In FIG. 70 and FIGS. 71A-71C, instead of forming gate contact 350A and/or gate contact 350B, fabrication of multigate device 900 may include forming gate vias in dielectric layer 340, such as a gate via 950A and a gate via 950B to gate 938A and gate 938B, respectively. Gate via 950A extends through dielectric layer 340 and is disposed on a top of the middle portion of gate electrode 928 of gate 938A. Gate via 950A is disposed between gate helmets 264 in transistor region 202A and transistor region 202B, and gate via 950A does not extend below tops of gate helmets 264. Gate via 950B extends through dielectric layer 340 and gate helmet 264 in transistor region 202C, and gate via 950B is disposed on a top of the first portion of gate 938B. Gate via 950B also extends through a portion of high-k dielectric layer 726 that wraps gate helmet 264 in transistor region 202C. Gate via 950A and gate via 950B may physically and/or electrically connect gate 938A and gate 938B, respectively, to a metallization layer of a multilayer interconnect MLI formed thereover, such as described herein. Further, in the depicted embodiment, gate 938A and gate 938B have sidewalls S11 formed by their respective gate stacks 930, such as by gate dielectrics 722 thereof. In such embodiments, sidewalls 932 of each gate stack 930 physically contact respective gate isolation walls 710, and gate via 350A and gate via 350B do not extend over sidewalls S11 of gate 938A and gate 938, respectively.

Gate via 950A and gate via 950B include tungsten, ruthenium, cobalt, copper, aluminum, iridium, palladium, platinum, nickel, low resistivity metal constituent, alloys thereof, or a combination thereof. In the depicted embodiment, gate via 950A and gate via 950B include tungsten, ruthenium, cobalt, alloys thereof, or a combination thereof. For example, gate via 950A and/or gate via 950B may be tungsten contacts, ruthenium contacts, or cobalt contacts. In some embodiments, gate via 950A and/or gate via 950B are barrier-free. For example, gate via 950A and/or gate via 950B may have metal plugs that physically contact gate electrodes 928, high-k dielectric layers 726, gate helmets 264, dielectric layer 340, other adjacent dielectric layers, or a combination thereof. In some embodiments, gate via 950A and/or gate via 950B include a metal plug disposed over a diffusion/barrier layer. The diffusion/barrier layer may include a material that promotes adhesion between the metal plug and adjacent dielectric material (e.g., dielectric layer 340, gate helmets 264, etc.) and/or a material that prevents diffusion of metal constituents from the metal plug into the adjacent dielectric material. In some embodiments, the diffusion/barrier layer includes tantalum, tantalum nitride, tantalum aluminum nitride, tantalum silicon nitride, tantalum carbide, titanium, titanium nitride, titanium silicon nitride, titanium aluminum nitride, titanium carbide, tungsten, tungsten nitride, tungsten carbide, molybdenum nitride, cobalt, cobalt nitride, ruthenium, palladium, other suitable material, or a combination thereof. In some embodiments, the diffusion/barrier layer may have a multilayer structure, such as a first sublayer and a second sublayer.

In some embodiments, forming gate vias may include forming a patterned mask layer over dielectric layer 340, where the patterned mask layer has a first opening and a second opening. The first opening overlaps a portion of gate 938A, such as the middle portion thereof, and the second opening overlaps a portion of gate 938B, such as the first portion thereof. An etching process may be performed that uses the patterned mask layer as an etch mask to form a first gate via opening and a second gate via opening. The first gate via opening extends through dielectric layer 340 to expose the middle portion of gate 938A, which is between respective gate helmets 264, and the second gate via opening extends through dielectric layer 340, a respective gate helmet 264, and a respective high-k dielectric layer 726 to expose the first portion of gate 938B. The etching process selectively removes dielectric material (e.g., dielectric layer 340, gate helmets 264, high-k dielectric layer 726, or a combination thereof) exposed by the first opening and/or the second opening of the patterned mask layer with negligible removal of metal materials (e.g., gate electrodes 928). In some embodiments, the etching process is configured to stop upon reaching and/or exposing gate electrodes 928. The etching process is a dry etch, a wet etch, other suitable etch, or a combination thereof. One or more deposition processes (e.g., CVD, ALD, PVD, etc.) may then be performed to form a gate via material (e.g., one or more electrically conductive layers) over dielectric layer 340 that fills the first gate via opening and the second gate via opening. A planarization process (e.g., CMP) may be performed to remove excess gate via material, such as gate via material over a top surface of dielectric layer 340. A remainder of gate via material that fills the first gate via opening and the second gate via opening may provide gate via 950A and gate via 950B, respectively.

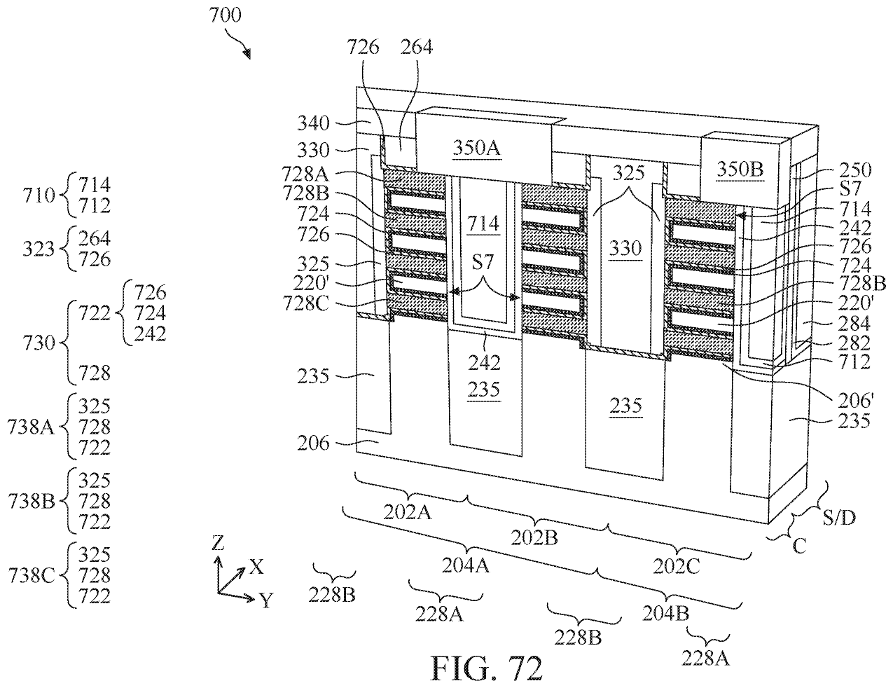

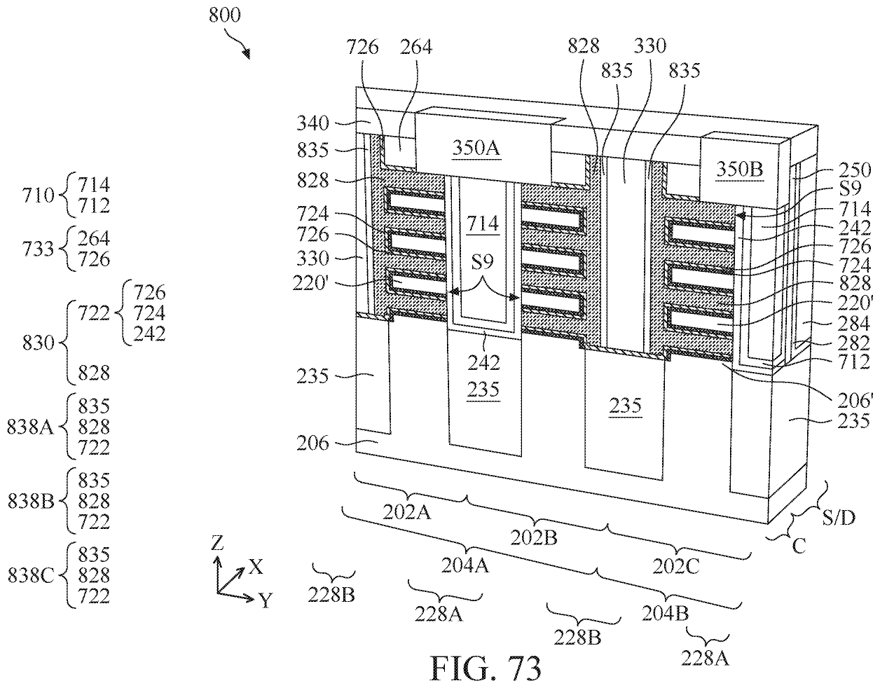

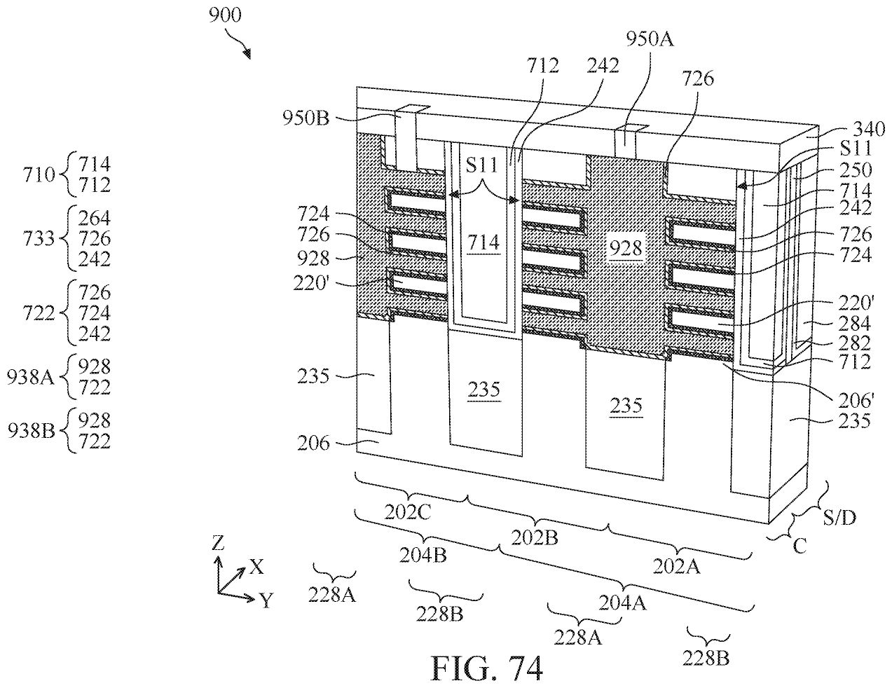

In the embodiments described above, processing includes performing a trim process, such as described above with reference to FIG. 47, which provides gates 738A-738C, gates 838A-838C, gate 938A, and gate 938B with Π-gate portions formed by portions of high-k dielectric layers 726 that wrap gate electrode portions. In some embodiments, the trim process is omitted from processing and dummy gate dielectric 242 is not trimmed as described in FIG. 47. FIGS. 72-74 are fragmentary perspective views of multigate device 700, multigate device 800, and multigate device 900, respectively, when fabricated by process flows that omit the trimming process, according to various aspects of the present disclosure. In FIGS. 72-74, gate dielectrics 722 include dummy gate dielectric 242, instead of dummy gate dielectric portions 242A. Dummy gate dielectric 242 wraps gate isolation walls 710. For example, dummy gate dielectric 242 is between sidewalls of gate isolation walls 710 and channel layers 220′, between sidewalls of gate isolation walls 710 and gate electrodes (e.g., gate electrodes 728, gate electrodes 828, or gate electrodes 928), and between a bottom of gate isolation walls 710 and isolation features 235. In such embodiments, high-k dielectric layer 726 wraps channel layers 220′ and may not be disposed along both sidewalls of channel layers 220′. Further, sidewalls S7 of gates 738A-738C of multigate device 700 (FIG. 72), sidewalls S9 of gates 838A-838C of multigate device 800 (FIG. 41), and sidewalls S11 and sidewalls S6 of gate 938A and gate 938B of multigate device 900 (FIG. 42) are formed by dummy gate dielectric 242, instead of being formed by both high-k dielectric layer 726 and dummy gate dielectric portions 242A. FIGS. 72-74 have been simplified for the sake of clarity to better understand the inventive concepts of the present disclosure. Additional features may be added in the multigate devices of FIGS. 72-74, and some of the features described below may be replaced, modified, or eliminated in other embodiments of the multigate devices of FIGS. 72-74.

In some embodiments, device region 204A and/or device region 204B is a core region (often referred to as a logic region), a memory region (such as a static random-access memory (SRAM) region), an analog region, a peripheral region (often referred to as an input/output (I/O) region), a dummy region, other suitable region, or a combination thereof. Device region 204A and/or device region 204B may include various passive and active electronic devices, such as resistors, capacitors, inductors, diodes, p-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable devices, or a combination thereof. Multigate device 200 may be included in a microprocessor, a memory, other IC device, or a combination thereof. In some embodiments, multigate device 200 is a portion of an IC chip, a system on chip (SoC), or portion thereof.

From the foregoing description, it may be seen that multigate devices described in the present disclosure offer advantages over conventional multigate devices. It is understood, however, that other embodiments may offer additional advantages, and not all advantages are necessarily disclosed herein, and that no particular advantage is required for all embodiments. One advantage of the fabrication processes described herein is that, since gate helmets (e.g., gate hard masks) are formed after forming a dummy gate and before forming a metal gate, gate helmets may protect underlying channel layers during a gate replacement process. Another advantage is that fabrication processes described herein reduce a size and/or a footprint of metal gates of transistors, compared to transistors fabricated using conventional metal gate isolation and cut techniques, thereby allowing for higher packing density of transistors and increasing IC pattern density. Reduced sizes and/or footprints of the metal gates arise because the disclosed self-aligned metal gate isolation and cut techniques provide transistors with separate gate electrode structures separated by gate isolation walls and connect the gate electrode structures of the transistors with gate contacts that span the gate isolation walls, instead of providing transistors with a shared gate electrode structure that spans spacing (e.g., spacing S) between the transistor regions and is connected to a gate via. Another advantage from the reduced sizes and/or footprints is a reduction in parasitic capacitance. For example, smaller metal gates reduce parasitic capacitance (Cgd) between the metal gates and source/drains, thereby improving speed and performance of transistors. Furthermore, as described above, the disclosed self-aligned metal gate isolation and cut techniques described herein do not have to account for lithography process variations, allowing for smaller spacings between active regions of transistors, and thus further increasing packing density of transistors and IC pattern density.

The present disclosure provides for many different embodiments. An exemplary semiconductor structure includes a semiconductor layer, a first isolation feature, a second isolation feature, a first gate isolation wall, a second gate isolation wall, a first gate, a second gate, a gate endcap, and a gate helmet. The first gate isolation wall is disposed over the first isolation feature, and the second gate isolation wall is disposed over the second isolation feature. The first gate is disposed between the first gate isolation wall and the second gate isolation wall. The first gate includes a gate stack that surrounds the semiconductor layer. The gate stack has a gate dielectric and a gate electrode. A first sidewall of the gate stack is formed by the gate dielectric and the gate electrode, and the gate endcap is disposed on the first sidewall. The gate helmet is disposed over the gate stack, and a portion of the gate dielectric is disposed between the gate electrode and the gate helmet. The gate contact is disposed on the first gate, and the gate contact extends over the first gate isolation wall and connects the first gate to the second gate.

In some embodiments, the gate contact extends over the first sidewall and physically contacts the gate endcap. In some embodiments, the gate contact extends over a second sidewall of the gate stack. In some embodiments, the first gate isolation wall physically contacts the second sidewall. In some embodiments, the gate endcap is a first gate endcap, a second gate endcap is disposed on the second sidewall, and the second gate endcap is between the first gate isolation wall and the second sidewall. In some embodiments, the gate endcap provides the first gate with a gate sidewall having a scalloped profile.

In some embodiments, the first sidewall has a gate dielectric portion disposed between a first gate electrode portion and a second gate electrode portion, the gate dielectric portion is formed by the gate dielectric, and the first gate electrode portion and the second gate electrode portion are each formed by the gate electrode. In some embodiments, the gate endcap may be disposed on the gate dielectric portion, the first gate electrode portion, and the second gate electrode portion, and the gate endcap may connect the first gate electrode portion and the second gate electrode portion. In some embodiments, the gate endcap has a first gate endcap segment disposed on the first gate electrode portion and a second gate endcap segment disposed on the second gate electrode portion. In some embodiments, the first gate endcap segment and the second gate endcap segment extend over the gate dielectric portion.

Another exemplary semiconductor structure includes a first gate stack, a second gate stack, a first gate helmet, a second gate helmet, a gate isolation wall, and a gate contact. The first gate stack is disposed on a first semiconductor layer, and the second gate stack is disposed on a second semiconductor layer. The first gate stack has a first gate dielectric and a first gate electrode, and the second gate stack has a second gate dielectric and a second gate electrode. The first gate stack has first sidewalls formed by both the first gate dielectric and the first gate electrode, and the second gate stack has second sidewalls of the second gate stack are formed by both the second gate dielectric and the second gate electrode. The first gate helmet is disposed on the first gate stack, and the second gate helmet is disposed on the second gate stack. The gate isolation wall is disposed between the first gate stack and the second gate stack. The gate contact is disposed on and connected to the first gate stack and the second gate stack. The gate contact is further disposed on the gate isolation wall, and the gate contact is disposed between the first gate helmet and the second gate helmet.

In some embodiments, a first gate endcap is disposed on a first one of the first sidewalls of the first gate stack, and a second gate endcap is disposed on a first one of the second sidewalls of the second gate stack. The first gate endcap connects a first portion of the first gate electrode and a second portion of the first gate electrode. The second gate endcap connects a first portion of the second gate electrode and a second portion of the second gate electrode. In some embodiments, the first gate endcap extends above the first gate electrode and the second gate endcap extends above the second gate electrode. In some embodiments, the first gate endcap extends over the first gate helmet and the second gate endcap extends over the second gate helmet. In some embodiments, each of the first gate endcap and the second gate endcap has a surface having a wavy profile. In some embodiments, the gate isolation wall is disposed between and physically contacts a second one of the first sidewalls of the first gate stack and a second one of the second sidewalls of the second gate stack.

In some embodiments, a third gate endcap is disposed on a second one of the first sidewalls of the first gate stack and a fourth gate endcap is disposed on a second one of the second sidewalls of the second gate stack. The gate isolation wall is disposed between the third gate endcap and the fourth gate endcap, and the gate contact is disposed on the third gate endcap and the fourth gate endcap. In some embodiments, the third gate endcap connects the first portion of the first gate electrode and the second portion of the first gate electrode, and the fourth gate endcap connects the first portion of the second gate electrode and the second portion of the second gate electrode. In some embodiments, each of the third gate endcap and the fourth gate endcap are segmented, the third gate endcap does not connect the first portion of the first gate electrode and the second portion of the first gate electrode, and the fourth gate endcap does not connect the first portion of the second gate electrode and the second portion of the second gate electrode. In some embodiments, the gate isolation wall physically contacts the second one of the first sidewalls of the first gate stack and the second one of the second sidewalls of the second gate stack.

An exemplary method includes forming a gate dielectric in a gate opening. The gate dielectric surrounds a first semiconductor layer, a second semiconductor layer, a first gate helmet over the first semiconductor layer, and a second gate helmet over the second semiconductor layer. The gate dielectric partially fills a first gap between the first semiconductor layer and the first gate helmet and a second gap between the second semiconductor layer and the second gate helmet. The method further includes depositing and etching back a gate electrode material to form a first gate electrode and a second gate electrode in the gate opening. The first gate electrode fills a remainder of the first gap between the first semiconductor layer and the first gate helmet, and the second gate electrode fills a remainder of the second gap between the second semiconductor layer and the second gate helmet. The first gate electrode and a first portion of the gate dielectric form a first gate stack having a first sidewall, and the second gate electrode and a second portion of the gate dielectric form a second gate stack having a second sidewall. The method further includes selectively depositing a first gate endcap on the first sidewall of the first gate stack and a second gate endcap on the second sidewall of the second gate stack. The method further includes forming a gate isolation wall in the gate opening that fills a remaining space between the first gate stack and the second gate stack. The method further includes forming a gate contact on the first gate electrode and the second gate electrode. The gate contact is disposed on the gate isolation wall, and the gate contact is disposed between the first gate helmet and the second gate helmet.

In some embodiments, the selectively depositing is tuned to form a first gate endcap segment on a first portion of the first gate electrode and a second gate endcap segment on a second portion of the first gate electrode. In some embodiments, the selectively depositing is tuned to merge the first gate endcap segment and the second gate endcap segment.

An exemplary semiconductor structure includes a semiconductor layer, a first gate, a first isolation feature and a second isolation feature, a first gate isolation wall, and a second gate isolation wall. The first gate isolation wall is disposed over the first isolation feature, and the second gate isolation wall is disposed over the second gate isolation wall. The first gate is disposed between the first gate isolation wall and the second gate isolation wall. The first gate includes a gate stack that surrounds the semiconductor layer. The gate stack has a gate dielectric and a gate electrode. The gate stack has a first sidewall and a second sidewall. The first sidewall is formed by the gate dielectric, the second sidewall is formed by the gate electrode, and the first sidewall physically contacts the first gate isolation wall. The semiconductor structure further includes a gate endcap, a gate helmet, and a gate contact. The gate helmet is disposed on the second sidewall of the gate stack and between the gate stack and the second gate isolation wall. The gate helmet is disposed over the gate stack, and a portion of the gate dielectric is disposed between the gate electrode and the gate helmet. The gate contact is disposed on the first gate, and the gate contact extends over the first gate isolation wall and connects the first gate to a second gate.

In some embodiments, the first sidewall of the gate stack is formed by a dummy gate dielectric layer portion of the gate dielectric. In some embodiments, the gate dielectric includes a high-k dielectric layer, and the high-k dielectric layer forms a pi-gate portion of the gate stack. In some embodiments, the first sidewall of the gate stack is formed by a high-k dielectric layer and a dummy gate dielectric layer portion of the gate dielectric, and the dummy gate dielectric layer portion is disposed between a sidewall of the semiconductor layer and the first gate isolation wall. In some embodiments, the gate electrode wraps the semiconductor layer, and the gate electrode is disposed between the gate endcap and the gate dielectric. In some embodiments, the first gate isolation wall has a first configuration, the second gate isolation wall has a second configuration, and the second configuration is different than the first configuration.

In some embodiments, the second sidewall of the gate stack is formed by both the gate electrode and the gate dielectric. In some embodiments, the second sidewall of the gate stack is formed by a high-k dielectric layer of the gate dielectric. In some embodiments, the first sidewall has a gate dielectric portion disposed between a first gate electrode portion and a second gate electrode portion, the gate dielectric portion is formed by the gate dielectric, and the first gate electrode portion and the second gate electrode portion are each formed by the gate electrode. In such embodiments, the gate endcap is disposed on the gate dielectric portion, the first gate electrode portion, and the second gate electrode portion, and the gate endcap connects the first gate electrode portion and the second gate electrode portion. In some embodiments, the first sidewall has a gate dielectric portion disposed between a first gate electrode portion and a second gate electrode portion, the gate dielectric portion is formed by the gate dielectric, and the first gate electrode portion and the second gate electrode portion are each formed by the gate electrode, and the gate endcap has a first gate endcap segment disposed on the first gate electrode portion and a second gate endcap segment disposed on the second gate electrode portion.

An exemplary semiconductor structure includes a first gate stack and a second gate stack. The first gate stack is disposed on a first semiconductor layer, and the second gate stack is disposed on a second semiconductor layer. The first gate stack has a first gate dielectric and a first gate electrode. The second gate stack has a second gate dielectric and a second gate electrode. The first gate stack has a first sidewall and a second sidewall, the first sidewall is formed by the first gate dielectric, and the second sidewall is formed by the first gate electrode. The second gate stack has a third sidewall and a fourth sidewall, the third sidewall is formed by the second gate dielectric, and the fourth sidewall is formed by the second gate electrode.

The semiconductor structure further includes a first gate helmet and a second gate helmet. The first gate helmet is disposed on the first gate stack, and the second gate helmet is disposed on the second gate stack. The semiconductor structure further includes a first gate isolation wall and a second gate isolation wall. The first gate isolation wall is disposed between the first gate stack and the second gate stack, the first sidewall of the first gate stack and the third sidewall of the second gate stack physically contact the first gate isolation wall, and the second gate stack is disposed between the first gate isolation wall and the second gate isolation wall. In some embodiments, the first gate isolation wall is in an in-cell region (e.g., an isolation region between electrically connected active regions) and the second gate isolation wall is in a boundary region (e.g., an isolation region between electrically disconnected active regions). The semiconductor structure further includes a gate contact disposed on and connected to the first gate stack and the second gate stack. The gate contact is disposed on the first gate isolation wall, and the gate contact is disposed between the first gate helmet and the second gate helmet.

In some embodiments, the semiconductor structure further includes a first gate endcap disposed on the second sidewall of the first gate stack and a second gate endcap disposed on the fourth sidewall of the second gate stack. The second gate endcap is disposed between the fourth sidewall of the second gate stack and the second gate isolation wall. In some embodiments, the first gate endcap connects a first portion of the first gate electrode and a second portion of the first gate electrode, and the second gate endcap connects a first portion of the second gate electrode and a second portion of the second gate electrode. In some embodiments, the second sidewall of the first gate stack is formed by both the first gate electrode and the first gate dielectric, the fourth sidewall of the second gate stack is formed by both the second gate electrode and the second gate dielectric, the first gate endcap physically contacts the first gate dielectric, and the second gate endcap physically contacts the second gate dielectric. In some embodiments, the first gate electrode is disposed between the first gate endcap and the first gate dielectric, and the second gate electrode is disposed between the second gate endcap and the second gate dielectric. In some embodiments, the first gate electrode is disposed between the first gate endcap and the first gate helmet, and the second gate electrode is disposed between the second gate endcap and the second gate helmet.

An exemplary method includes removing a dummy gate electrode layer to form a gate opening that exposes a dummy gate dielectric layer. The method further includes forming a first gate isolation wall in the gate opening in a first isolation region. The first isolation region is between a first active region and a second active region. The method further includes forming a gate dielectric in the gate opening. The gate dielectric surrounds a first semiconductor layer, a second semiconductor layer, a first gate helmet over the first semiconductor layer, and a second gate helmet over the second semiconductor layer. The first semiconductor layer and the first gate helmet are disposed in the first active region, and the second semiconductor layer and the second gate helmet are disposed in the second active region. The gate dielectric partially fills a first gap between the first semiconductor layer and the first gate helmet and a second gap between the second semiconductor layer and the second gate helmet.

The method further includes forming a first gate electrode and a second gate electrode in the gate opening. The first gate electrode fills a remainder of the first gap between the first semiconductor layer and the first gate helmet, and the second gate electrode fills a remainder of the second gap between the second semiconductor layer and the second gate helmet. The first gate electrode and a first portion of the gate dielectric form a first gate stack having a first sidewall and a second sidewall. The first sidewall is formed by the first portion of the gate dielectric and the second sidewall is formed by the first gate electrode. The second gate electrode and a second portion of the gate dielectric form a second gate stack having a third sidewall and a fourth sidewall. The third sidewall is formed by the second portion of the gate dielectric, and the fourth sidewall is formed by the second gate electrode.

The method further includes selectively depositing a first gate endcap on the second sidewall of the first gate stack and a second gate endcap on the fourth sidewall of the second gate stack. The method further includes forming a second gate isolation wall in the gate opening in a second isolation region. The second active region is between the first isolation region and the second isolation region, and the second gate isolation wall fills a remainder of the gate opening. The method may further include forming a gate contact on the first gate electrode and the second gate electrode. The gate contact is disposed on the first gate isolation wall, and the gate contact is disposed between the first gate helmet and the second gate helmet.

In some embodiments, forming the first gate electrode and the second gate electrode in the gate opening includes depositing and etching back a gate electrode material, such that the first gate electrode and the second gate electrode partially fill the gate opening. In some embodiments, forming the first gate electrode and the second gate electrode in the gate opening includes depositing and planarizing a gate electrode material, such that the first gate electrode and the second gate electrode fill the remainder of the gate opening. In such embodiments, the method further includes selectively depositing the second gate endcap after forming a gate cut opening in the second gate electrode. The second gate endcap partially fills the gate cut opening and the second gate isolation wall is formed in and fills a remainder of the gate cut opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
a semiconductor layer;
a first isolation feature and a second isolation feature;
a first gate isolation wall and a second gate isolation wall, wherein the first gate isolation wall is disposed over the first isolation feature and the second gate isolation wall is disposed over the second isolation feature;
a first gate disposed between the first gate isolation wall and the second gate isolation wall, wherein the first gate includes:
a gate stack that surrounds the semiconductor layer, wherein the gate stack has a gate dielectric and a gate electrode,
the gate stack has a first sidewall and a second sidewall, wherein the first sidewall is formed by the gate dielectric and the gate electrode, and
a gate endcap disposed on the first sidewall;
a gate helmet disposed over the gate stack, wherein a portion of the gate dielectric is disposed between the gate electrode and the gate helmet; and
a gate contact disposed on the first gate, wherein the gate contact extends over the first gate isolation wall and connects the first gate to a second gate.

2. The semiconductor structure of claim 1, wherein the gate contact extends over the first sidewall and physically contacts the gate endcap.

3. The semiconductor structure of claim 1, wherein:
the first sidewall has a gate dielectric portion disposed between a first gate electrode portion and a second gate electrode portion, the gate dielectric portion is formed by the gate dielectric, and the first gate electrode portion and the second gate electrode portion are each formed by the gate electrode; and
the gate endcap is disposed on the gate dielectric portion, the first gate electrode portion, and the second gate electrode portion, wherein the gate endcap connects the first gate electrode portion and the second gate electrode portion.

4. The semiconductor structure of claim 1, wherein:
the first sidewall has a gate dielectric portion disposed between a first gate electrode portion and a second gate electrode portion, the gate dielectric portion is formed by the gate dielectric, and the first gate electrode portion and the second gate electrode portion are each formed by the gate electrode; and
the gate endcap has a first gate endcap segment disposed on the first gate electrode portion and a second gate endcap segment disposed on the second gate electrode portion.

5. The semiconductor structure of claim 4, wherein the first gate endcap segment and the second gate endcap segment extend over the gate dielectric portion.

6. The semiconductor structure of claim 1, wherein the gate contact extends over the second sidewall and the first gate isolation wall physically contacts the second sidewall.

7. The semiconductor structure of claim 1, wherein the gate endcap provides the first gate with a gate sidewall having a scalloped profile.

8. A semiconductor structure comprising:
a semiconductor layer;
a first isolation feature and a second isolation feature;
a first gate isolation wall and a second gate isolation wall, wherein the first gate isolation wall is disposed over the first isolation feature and the second gate isolation wall is disposed over the second gate isolation wall;
a first gate disposed between the first gate isolation wall and the second gate isolation wall, wherein the first gate includes:
a gate stack that surrounds the semiconductor layer, wherein the gate stack has a gate dielectric and a gate electrode,
the gate stack has a first sidewall and a second sidewall, wherein the first sidewall of the gate stack is formed by the gate dielectric, the second sidewall of the gate stack is formed by the gate electrode, and the first sidewall of the gate stack physically contacts the first gate isolation wall, and
a gate endcap disposed on the second sidewall of the gate stack, wherein the gate endcap is between the gate stack and the second gate isolation wall;
a gate helmet disposed over the gate stack, wherein a portion of the gate dielectric is disposed between the gate electrode and the gate helmet; and
a gate contact disposed on the first gate, wherein the gate contact extends over the first gate isolation wall and connects the first gate to a second gate.

9. The semiconductor structure of claim 8, wherein the second sidewall of the gate stack is formed by both the gate electrode and the gate dielectric.

10. The semiconductor structure of claim 9, wherein the second sidewall of the gate stack is formed by a high-k dielectric layer of the gate dielectric.

11. The semiconductor structure of claim 9, wherein:
the first sidewall has a gate dielectric portion disposed between a first gate electrode portion and a second gate electrode portion, the gate dielectric portion is formed by the gate dielectric, and the first gate electrode portion and the second gate electrode portion are each formed by the gate electrode; and
the gate endcap is disposed on the gate dielectric portion, the first gate electrode portion, and the second gate electrode portion, wherein the gate endcap connects the first gate electrode portion and the second gate electrode portion.

12. The semiconductor structure of claim 9, wherein:
the first sidewall has a gate dielectric portion disposed between a first gate electrode portion and a second gate electrode portion, the gate dielectric portion is formed by the gate dielectric, and the first gate electrode portion and the second gate electrode portion are each formed by the gate electrode; and
the gate endcap has a first gate endcap segment disposed on the first gate electrode portion and a second gate endcap segment disposed on the second gate electrode portion.

13. The semiconductor structure of claim 8, wherein:
the gate electrode wraps the semiconductor layer; and
the gate electrode is disposed between the gate endcap and the gate dielectric.

14. The semiconductor structure of claim 8, wherein:
the first gate isolation wall has a first configuration; and
the second gate isolation wall has a second configuration, wherein the second configuration is different than the first configuration.

15. The semiconductor structure of claim 8, wherein the first sidewall of the gate stack is formed by a high-k dielectric layer and a dummy gate dielectric layer portion of the gate dielectric, wherein the dummy gate dielectric layer portion is disposed between a sidewall of the semiconductor layer and the first gate isolation wall.

16. The semiconductor structure of claim 8, wherein the first sidewall of the gate stack is formed by a dummy gate dielectric layer portion of the gate dielectric.

17. The semiconductor structure of claim 8, wherein:
the gate dielectric includes a high-k dielectric layer; and
the high-k dielectric layer forms a pi-gate portion of the gate stack.

18. A method comprising:
forming a gate dielectric in a gate opening, wherein:
the gate dielectric surrounds a first semiconductor layer, a second semiconductor layer, a first gate helmet over the first semiconductor layer, and a second gate helmet over the second semiconductor layer, and
the gate dielectric partially fills a first gap between the first semiconductor layer and the first gate helmet and a second gap between the second semiconductor layer and the second gate helmet;
depositing and etching back a gate electrode material to form a first gate electrode and a second gate electrode in the gate opening, wherein:
the first gate electrode fills a remainder of the first gap between the first semiconductor layer and the first gate helmet and the second gate electrode fills a remainder of the second gap between the second semiconductor layer and the second gate helmet, and
the first gate electrode and a first portion of the gate dielectric form a first gate stack having a first sidewall and the second gate electrode and a second portion of the gate dielectric form a second gate stack having a second sidewall;
selectively depositing a first gate endcap on the first sidewall of the first gate stack and a second gate endcap on the second sidewall of the second gate stack;
forming a gate isolation wall in the gate opening that fills a remaining space between the first gate stack and the second gate stack; and
forming a gate contact on the first gate electrode and the second gate electrode, wherein the gate contact is disposed on the gate isolation wall and the gate contact is disposed between the first gate helmet and the second gate helmet.

19. The method of claim 18, wherein the selectively depositing is tuned to form a first gate endcap segment on a first portion of the first gate electrode and a second gate endcap segment on a second portion of the first gate electrode.

20. The method of claim 19, wherein the selectively depositing is tuned to merge the first gate endcap segment and the second gate endcap segment.
